(19) United States
(12) Patent Application Publication
(10) Pub. No.: US 2026/0250573 A1
(43) Pub. Date: Aug. 27, 2026

(54) PHOSPHOR, METHOD FOR PRODUCING A PHOSPHOR, USE OF A PHOSPHOR AND OPTOELECTRONIC COMPONENT

(71) Applicant: ams-Osram International GmbH, Regensburg (DE)

(72) Inventors: Markus SEIBALD, Kaufering (DE); Christiane STOLL, Schwabmuenchen (DE); Stefan LANGE, Augsburg (DE); Frauke PHILIPP, Augsburg (DE); Sonja TRAGL, Augsburg (DE); Mark VORSTHOVE, Augsburg (DE); Max Kilian RIESSBECK, Innsbruck (AT); Gunter HEYMANN, Hall in Tirol (AT); Hubert HUPPERTZ, lnnsbruck (AT); Klaus WURST, Zirl (AT)

(21) Appl. No.: 19/156,897

(22) PCT Filed: Jul. 1, 2024
(86) PCT No.: PCT/EP2024/068470

§ 371 Date: Aug. 15, 2025

(30) Foreign Application Priority Data
Jul. 6, 2023 (DE) 10 2023 117 837.7
Nov. 23, 2023 (DE) 10 2023 132 659.7

(51) Int. Cl. C09K 11/77; H10H 20/851

(52) U.S. Cl. CPC C09K 11/77747; C09K 11/77348; C09K 11/7774; H10H 20/8512

(57) ABSTRACT

A phosphor has the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, wherein 0≤x≤4, 0≤c≤1, 0≤z≤4, 0≤a≤8, 0≤b≤4, 0≤2x+a≤8, 0≤z+b≤4, −4≤−z+b−c≤4. A method for producing the phosphor, a use of the phosphor, with the molecular formula, are described. Further, an optoelectronic component having a radiation-emitting semiconductor chip and a conversion element is described. The conversion element includes the phosphor with the molecular formula.

### CROSS-REFERENCE TO RELATED APPLICATIONS

This application is a US National Stage, filed under 35 U.S.C. § 371, of International Application PCT/EP2024/068470, filed Jul. 1, 2024 and further claims priority to German Application 10 2023 117 837.7, filed on Jul. 6, 2023, and to German Application 10 2023 132 659.7, filed on Nov. 23, 2023, the entire content of the above-listed applications are incorporated herein by reference.

### FIELD

A phosphor, a method for producing a phosphor, a use of a phosphor and an optoelectronic component are described.

### SUMMARY

Inter alia, various embodiments relate to an improved phosphor. Furthermore, various embodiments relate to an efficient method for producing a phosphor. Various embodiments relate to a use and an efficient optoelectronic component in each case with the phosphor.

A phosphor is specified. The phosphor can be uncharged to the outside. This means that there can be a complete charge balance between positive and negative charges in the phosphor. On the other hand, it is also possible that the phosphor formally does not have a complete charge balance to a small extent.

With the compositions or molecular formulae indicated, it is possible that the phosphor comprises further elements, for example in the form of impurities. Taken together, the impurities comprise at most 1 per mill, in particular at most 100 ppm (parts per million), for example at most 10 ppm. In particular, these impurities are present in the phosphor in a proportion of at most 5 mol %, in particular at most 1 mol %, for example at most 0.1 mol %.

Phosphors are described here and in the following using compositions or molecular formulae. The elements listed in the compositions or molecular formulae are present in charged form. Here and in the following, with reference to the compositions or molecular formulae of the phosphors, elements and/or atoms therefore mean ions in the form of cations and anions, even if this is not explicitly stated. This also applies to element symbols if these are mentioned without a charge number for the sake of clarity.

According to at least one embodiment, the phosphor comprises an element or a combination of elements selected from the group of monovalent elements.

The term “valency” in relation to a specific element refers to how many elements with a single opposite charge are required in a chemical compound in order to achieve a charge balance. The term “valency” therefore includes the charge number of the element.

Elements with a valency of one are referred to as monovalent elements. Monovalent elements often have a single positive charge in chemical compounds and have a charge number of +1. A charge balance in a chemical compound can take place, for example, via another element that has a single negative charge. Monovalent elements are generally selected from the group formed from alkali elements and elements of the subgroups.

According to at least one embodiment, the phosphor comprises an element or a combination of elements selected from the group of trivalent elements.

Elements with a valency of three are referred to as trivalent elements. Trivalent elements often have a triple positive charge in chemical compounds and have a charge number of +3. A charge balance in a chemical compound can take place, for example, via three other elements, each of which has a single negative charge, or another element that has a triple negative charge. Trivalent elements are generally selected from the group formed from elements of the subgroups, in particular the rare earth elements, and by elements of the 3rd main group. Here and in the following, the rare earth elements are understood to be the following elements: Sc, Y, La, Ce, Pr, Nd, Pm, Sm, Eu, Gd, Tb, Dy, Ho, Er, Tm, Yb, Lu.

According to at least one embodiment, the phosphor comprises an element or a combination of elements selected from the group of tetravalent elements.

Elements with a valence of four are referred to as tetravalent elements. Tetravalent elements are often positively charged four times in chemical compounds and have a charge number of +4. A charge balance in a chemical compound can, for example, take place via four other elements, each of which has a single negative charge, or two other elements, each of which has a double negative charge. Tetravalent elements are generally selected from the group formed from elements of the 4th main group and elements of the subgroups.

According to at least one embodiment, the phosphor comprises oxygen and/or nitrogen. In particular, the oxygen has a double negative charge. In particular, the nitrogen has a triple negative charge. Oxygen and/or nitrogen are used, for example, for charge balance for the monovalent elements, the trivalent elements and the tetravalent elements.

According to at least one embodiment, the phosphor comprises an activator element E. It is also possible that the phosphor comprises a combination of activator elements. In general, the phosphor comprises a host structure into which foreign elements are introduced as an activator element. The activator element can absorb electromagnetic radiation of an excitation wavelength. At the same time, it is possible that the electronic structure of the activator element is changed by the host structure. After absorption of the electromagnetic radiation of the excitation wavelength, an electronic transition is excited in the phosphor, for example in the activator element or the host structure. By emitting electromagnetic radiation with an emission spectrum, the phosphor returns to its ground state.

According to at least one embodiment, the phosphor comprises an element or a combination of elements selected from the group of monovalent elements, an element or a combination of elements selected from the group of trivalent elements, an element or a combination of elements selected from the group of tetravalent elements, oxygen and/or nitrogen, and an activator element E.

According to at least one embodiment, the phosphor comprises an element or a combination of elements selected from the group of divalent elements.

Elements with a valency of two are referred to as divalent elements. Divalent elements often have a double positive charge in chemical compounds and have a charge number of +2. A charge balance in a chemical compound can take place, for example, via two other elements, each of which has a single negative charge, or another element that has a double negative charge. Divalent elements are presently generally selected from the group formed by alkaline earth elements and elements of the subgroups.

According to at least one embodiment, the phosphor comprises an element or a combination of elements selected from the group of pentavalent elements.

Elements with a valency of five are referred to as pentavalent elements. In chemical compounds, pentavalent elements are often five times positively charged in chemical compounds and have a charge number of +5. A charge balance in a chemical compound can take place, for example, via five other elements, each of which has a single negative charge, or a further element that has a double negative charge and a further element that has a triple negative charge. Presently, pentavalent elements are generally selected from the group formed by elements of the 5th main group and by elements of the subgroups.

According to at least one embodiment, the phosphor comprises the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E. All statements made with the phosphor described by its molecular formula also apply to the phosphor described only by its composition, and vice versa. The square brackets indicate in particular that MA, MD, ME, MG, N and O form a scaffold in the host structure of the phosphor. For example, MA, MD, ME and MG are scaffold formers. Li, MB, MF, MC and E, for example, are arranged between structural building blocks that form the scaffold, for example in gaps or channels.

According to at least one embodiment of the phosphor, 0≤x≤4 applies. According to at least one embodiment of the phosphor, 0≤c≤1 applies. According to at least one embodiment of the phosphor, 0≤z≤4 applies. According to at least one embodiment of the phosphor, 0≤a≤8 applies. According to at least one embodiment of the phosphor, 0≤b≤4 applies.

According to at least one embodiment of the phosphor, 0≤2x+a≤8 applies. According to at least one embodiment of the phosphor, 0≤z+b≤4 applies. According to at least one embodiment of the phosphor, −4≤−z+b−c≤4 applies.

According to at least one embodiment of the phosphor, MB is an element or a combination of elements selected from the group of divalent elements.

According to at least one embodiment of the phosphor, MC is an element or a combination of elements selected from the group of trivalent elements. In particular, MC is an element or a combination of elements selected from the group of rare earth elements. For example, the rare earth elements in the phosphor comprise the charge number+3.

According to at least one embodiment of the phosphor, MA is Li and/or Na.

According to at least one embodiment of the phosphor, MD is an element or a combination of elements selected from the group of tetravalent elements.

According to at least one embodiment of the phosphor, ME is an element or a combination of elements selected from the group of trivalent elements. In particular, ME and MC are different. However, it is also possible that ME and MC are the same.

According to at least one embodiment of the phosphor, MF is an element or a combination of elements selected from the group of monovalent elements. In particular, MF and MA are different. However, it is also possible that MF and MA are the same.

According to at least one embodiment of the phosphor, MG is an element or a combination of elements selected from the group of pentavalent elements.

According to at least one embodiment of the phosphor, E is an activator element. It is also possible that E is a combination of activator elements.

According to at least one embodiment, the phosphor comprises the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E wherein 0≤x≤4, 0≤c≤1, 0≤z≤4, 0≤a≤8, 0≤b≤4, 0≤2x+a≤8, 0≤z+b≤4, −4≤−z+b−c≤4, MB is an element or a combination of elements selected from the group of divalent elements, MC is an element or a combination of elements selected from the group of trivalent elements, MA is Li and/or Na, MD is an element or a combination of elements selected from the group of tetravalent elements, ME is an element or a combination of elements selected from the group of trivalent elements, MF is an element or a combination of elements selected from the group of monovalent elements, MG is an element or a combination of elements selected from the group of pentavalent elements, and E is the activator element.

It has become apparent that the phosphor described herein is advantageously hydrolytically stable despite the presence of Li. Furthermore, emission properties of the phosphor can be influenced by the choice of components and the exact composition. It is therefore advantageously possible to adapt the phosphor to desired applications.

According to at least one embodiment of the phosphor, MB is an element or a combination of elements selected from the following group: Be, Mg, Ca, Sr, Ba, Zn.

According to at least one embodiment of the phosphor, MC is an element or a combination of elements selected from the following group: Sc, Y, La, Ce, Pr, Nd, Pm, Sm, Eu, Gd, Tb, Dy, Ho, Er, Tm, Yb, Lu. In other words, MC is an element or a combination of elements selected from the group of rare earth elements. In particular, the sizes of the elements Ce, Pr, Nd, Pm, Sm, Eu, Gd, Tb, Dy, Ho, Er, Tm, Yb, and Y are between the sizes of Lu and La. Therefore, Ce, Pr, Nd, Pm, Sm, Eu, Gd, Tb, Dy, Ho, Er, Tm, Yb and Y can occupy equivalent positions to Lu and La in the host structure. Here, the size corresponds in particular to an ionic radius.

According to at least one embodiment of the phosphor, MC is an element or a combination of elements selected from the following group: Gd, Dy, Ho, Pr, Nd, Y, Tb, Er, Tm, Yb, Sm, Lu.

In particular, MC contributes to emission properties of the phosphor. In other words, at least a part of the electromagnetic radiation emitted by the phosphor can be attributed to electronic transitions in MC. For example, the electronic transitions are f→f transitions. The f→f transitions can be excited directly or by means of a sensitizer. For example, 4f→4f transitions can be excited in Ho³⁺, Pr³⁺, Tb³⁺, Er³⁺, Tm³⁺, Sm³⁺, and Nd³⁺.

According to at least one embodiment of the phosphor, MD is an element or a combination of elements selected from the following group: Si, Ge, Sn, Pb, Ti, Zr, Hf.

According to at least one embodiment of the phosphor, ME is an element or a combination of elements selected from the following group: B, Al, Ga, In, Sc, Cr.

According to at least one embodiment of the phosphor, MF is an element or a combination of elements selected from the following group: Na, K, Rb, Cs, Au, Cu, Pt, Ag.

According to at least one embodiment of the phosphor, MG is an element or a combination of elements selected from the following group: V, Nb, Ta, P, As, Sb.

According to at least one embodiment of the phosphor, E is an element or a combination of elements selected from the following group: Eu, Ce, Pr, Nd, Sm, Tb, Dy, Ho, Er, Tm, Yb, Mn, Cr, Ni, Bi, Cu, Ag, Ti, U. In particular, E is Ce and/or Eu. For example, the phosphor comprises more than one activator element E.

In particular, Eu is present in the form Eu²⁺ or Eu³⁺. In particular, Ce is present in the form Ce³⁺. In particular, Pr is present in the form Pr³⁺. In particular, Nd is present in the form Nd³⁺. In particular, Sm is present in the form Sm³⁺. In particular, Tb is present in the form Tb³⁺. In particular, Dy is present in the form Dy³⁺. In particular, Ho is present in the form Ho³⁺. In particular, Er is present in the form Er³⁺. In particular, Tm is present in the form Tm³⁺. In particular, Yb is present in the form Yb³⁺ or Yb²⁺. In particular, Mn is present in the form Mn²⁺ or Mn⁴⁺. In particular, Cr is present in the form Cr³⁺. In particular, nickel is present in the form Ni²⁺. In particular, Bi is present in the form Bi³⁺. In particular, Cu is present in the form Cu⁺ or Cu²⁺. In particular, Ag is present in the form Ag⁺. In particular, Ti is present in the form Ti³⁺ or Ti⁴⁺. In particular, U is present in the form U⁶⁺.

For example, d-d transitions are excited in Mn²⁺, Mn⁴⁺ and Cr³⁺. In Eu²⁺ and Ce³⁺, for example, f→d transitions or d→f transitions are excited. For example, a 5d→4f transition takes place in Ce³⁺.

For phosphors comprising Ce³⁺ as activator element, only slight quenching effects are observed even at high irradiance levels. For example, a phosphor with the molecular formula Y₃Al₅O₁₂:Ce³⁺ comprises a clearly pronounced intensity quenching only above an irradiance of 1 W/mm², in particular only above an irradiance of 10 W/mm². This fact is attributed to an excited state of Ce³⁺ comprising a short lifetime. A typical lifetime of the excited state of Ce³⁺ is, for example, less than 100 nanoseconds.

According to at least one embodiment of the phosphor, the activator element acts as a sensitizer. If the activator element acts as a sensitizer, at least a part of the energy absorbed by the activator element, which is made available to the activator element, for example when excited with electromagnetic radiation, is transferred to another component in the phosphor, for example MC. This results, for example, in a red shift of the electromagnetic radiation emitted by the phosphor and/or additional emission peaks. For example, the activator element transfers at least 1%, at least 10%, at least 50%, at least 75% or at least 90% of the absorbed energy. For example, Ce³⁺ as activator element E can also act as a sensitizer for MC and/or E equal to Nd, Ho, Tb, Tm, Er, Sm, and Pr. In MC and/or E equal to Nd, Ho, Tb, Tm, Er, Sm, and Pr, for example, f→f transitions are excited after the energy transfer.

In particular, the emission spectrum of the phosphor with a sensitizer as activator element can comprise a plurality of emission peaks. The individual emission peaks can then be assigned in particular to the activator element and the other component of the phosphor, for example MC. It is also possible that the individual emission peaks can be assigned to different activator elements if the activator element E comprises a combination of elements.

According to at least one embodiment, the activator element E comprises a proportion of between 0.01 mol % and 10 mol % inclusive, in particular a proportion of between 0.1 mol % and 5 mol % inclusive, based on the sums of MC and MB. It is also possible that the activator element E comprises a proportion of at most 15 mol % relative to the sum of MC and MB, in particular if MC is Nd, Yb, Lu, Er or Tm.

According to at least one embodiment, x=0 applies.

According to at least one embodiment, c=0 applies.

According to at least one embodiment, a=0 applies.

According to at least one embodiment, b=0 applies.

According to at least one embodiment, z=0 applies.

According to at least one embodiment, the phosphor comprises the molecular formula Li₈MC[MAMD₄N₄O₈]:E. In particular, the phosphor comprises the molecular formula Li₈MC[LiSi₄N₄O₈]:E or Li₉MCSi₄N₄O₈:E. In the case of the molecular formula Li₉MCSi₄N₄O₈:E, the individual components are sorted according to their type, whereas the molecular formula Li₈MC[LiSi₄N₄O₈]:E indicates a host structure of the compound.

For example, the square brackets indicate that Li, Si, N and o form a scaffold in the host structure of the phosphor. Here and in the following, scaffold is understood to mean an anionic substructure of the host structure of the phosphor.

The scaffold may comprise a three-dimensional structure and/or a layer structure. In particular, MC is selected from the group formed by the rare earth elements, for example Gd, Y, Pr, Nd, Ho, Tb, Tm, Er, Lu, Yb, Sm, and Dy, and combinations thereof.

According to at least one embodiment of the phosphor, a molar ratio of MC to the sum of MA, MD, ME, and MG is less than 3:5. In other words, a ratio of MC to the scaffold formers is less than 3:5 (MC:scaffold formers). In particular, a ratio of rare earth elements to the scaffold formers in the present phosphor is thus less than 3:5. For example, the phosphor with the molecular formula Li₈MC[LiSi₄N₄O]:E comprises a ratio of MC to the scaffold formers of 1:5.

Garnets RE₃(Al,Ga)O₁₂:E, where RE is a rare earth element, comprise a ratio of rare earth elements to scaffold formers of 3:5. Rare earth elements are particularly expensive compared to scaffold formers. Thus a less expensive phosphor can advantageously be provided with the present phosphor.

According to at least one embodiment of the phosphor, a mass fraction of MC with respect to the total mass of the phosphor is less than 59%, in particular less than 45%, for example between and including 20% and 33%. In particular, a mass fraction of rare earth elements in the phosphor with respect to the total mass of the phosphor is less than 59%. For example, the phosphor with MC equal to Gd or Dy comprises a mass fraction of MC of 31% with respect to the total mass of the phosphor. The phosphor with MC equal to Ho or Tm may comprise a mass fraction of MC of 32% with respect to the total mass of the phosphor. The phosphor with MC equal to Pr, for example, comprises a mass fraction of MC of 28% with respect to the total mass of the phosphor, and the phosphor with MC equal to Y comprises a mass fraction of MC of 20% with respect to the total mass of the phosphor. The phosphor with MC equal to Tb comprises a mass fraction of MC of 30.7% with respect to the total mass of the phosphor. The phosphor with MC equal to Lu or Yb comprises a mass fraction of MC of 33% with respect to the total mass of the phosphor. The phosphor with MC equal to Sm comprises a mass fraction of MC of 30% with respect to the total mass of the phosphor.

Garnets RE₃Al₅O₁₂:E, wherein RE is a rare earth element, comprise a mass fraction of rare earth elements of at least 45% with respect to the total mass of the phosphor. For example, Gd₃Al₅O₁₂:E comprises a mass fraction of rare earth elements of 59% with respect to the total mass of the phosphor. Dy₃Al₅O₁₂:E and possible Ho₃Al₅O₁₂:E, for example, comprise a mass fraction of rare earth elements with respect to the total mass of the phosphor of at least or about 60%, Lu₃Al₅O₁₂:E even of about 62%. Pr₃Al₅O₁₂:E comprises a mass fraction of rare earth elements of 56% with respect to the total mass of the phosphor. Y₃Al₅O₁₂:E comprises a mass fraction of rare earth elements of 45% with respect to the total mass of the phosphor. A possible Tm₃Al₅O₁₂ and Yb₃Al₅O₁₂ comprise a mass fraction of rare earth elements of 61% with respect to the total mass of the phosphor, a possible Tb₃Al₅O₁₂ comprises a mass fraction of 59.3%. A possible Sm₃Al₅O₁₂ comprises a mass fraction of rare earth elements of 58% with respect to the total mass of the phosphor.

According to at least one embodiment, the phosphor emits electromagnetic radiation with an emission spectrum after excitation with electromagnetic radiation of the excitation wavelength. In particular, the excitation wavelength comprises smaller wavelengths than the electromagnetic radiation emitted by the phosphor.

The emission spectrum is the distribution of the electromagnetic radiation emitted by the phosphor after excitation with electromagnetic radiation of the excitation wavelength. For example, the emission spectrum is shown in the form of a diagram in which a spectral intensity or a spectral radiant flux per wavelength interval (“spectral intensity/spectral radiant flux”) of the electromagnetic radiation emitted by the phosphor is shown as a function of the wavelength A. In other words, the emission spectrum can be represented as a curve in an x/y diagram, with the wavelength being plotted on the x-axis and the spectral intensity or spectral radiant flux being plotted on the y-axis.

According to at least one embodiment, the phosphor is excited with electromagnetic radiation in the ultraviolet to blue range of the electromagnetic spectrum. In particular, the phosphor is excited with electromagnetic radiation in the range of between and including 300 nanometers and 550 nanometers, in particular in the range of between and including 400 nanometers and 500 nanometers.

According to at least one embodiment, the phosphor is excited with electromagnetic radiation in the visible range of the electromagnetic spectrum. In particular, the phosphor is excited with electromagnetic radiation in the range of between and including 380 nanometers and 830 nanometers.

In particular, f→f transitions can be excited directly with electromagnetic radiation of the visible range of the electromagnetic spectrum, for example with electromagnetic radiation of the red range of the electromagnetic spectrum, for example with a wavelength of around 635 nm. By directly exciting the f→f transitions, efficiency losses due to energy transfer from the sensitizer to the element MC can be reduced.

According to at least one embodiment, the emission spectrum of the electromagnetic radiation emitted by the phosphor comprises an emission peak with an emission maximum in the near-ultraviolet to infrared range of the electromagnetic spectrum.

According to at least one embodiment, the emission spectrum of the electromagnetic radiation emitted by the phosphor comprises an emission peak with an emission maximum that is in the near-ultraviolet to blue range of the electromagnetic spectrum. The near-ultraviolet to blue range of the electromagnetic spectrum comprises in particular wavelengths in the range of between and including 300 nanometers and 490 nanometers. In particular, the phosphor emits electromagnetic radiation in the near-ultraviolet, violet and/or blue range of the electromagnetic spectrum. The ultraviolet range comprises in particular electromagnetic radiation with wavelengths in the range of between and including 300 nanometers and 380 nanometers. The violet range comprises in particular electromagnetic radiation with wavelengths in the range of between and including 380 nanometers and 430 nanometers. The blue range comprises in particular wavelengths in the range of between and including 430 nanometers and 490 nanometers. For example, near-ultraviolet to blue emission is achieved by a phosphor with Ce³⁺ as activator element and z−b+c close to 4. In particular, an oxidic environment for the activator element E is achieved at z−b+c close to 4. This can lead to emission of the phosphor in the ultraviolet to blue wavelength range with Ce³⁺ as the activator element.

According to at least one embodiment of the phosphor, the emission spectrum of the electromagnetic radiation emitted by the phosphor comprises an emission peak with an emission maximum that is in the green to yellow range of the electromagnetic spectrum. The green to yellow range of the electromagnetic spectrum comprises in particular wavelengths in the range of between and including 490 nanometers and 600 nanometers. In particular, the phosphor emits electromagnetic radiation in the green and/or yellow range of the electromagnetic spectrum. In particular, the green range comprises electromagnetic radiation with wavelengths in the range of between and including 490 nanometers and 570 nanometers. The yellow range comprises in particular electromagnetic radiation with wavelengths in the range of between and including 570 nanometers and 600 nanometers. For example, green to yellow emission is achieved by a phosphor with Ce³⁺ and/or Mn²⁺ as activator element. For a green to yellow emission, Ce³⁺ comprises N atoms in its environment, for example. With Eu²⁺ as activator element E, for example, the phosphor comprises an emission peak with an emission maximum in the yellow range of the electromagnetic spectrum.

Advantageously, the green to yellow emitting phosphor can be used for general lighting, for store lighting, in high-power LEDs, for example for car headlights, and in projection, for example in projectors.

According to at least one embodiment of the phosphor, a dominant wavelength λ_{dom} of the electromagnetic radiation emitted by the phosphor is in the range of between and including 490 nanometers and 780 nanometers, in particular in the range of between and including 490 nanometers and 600 nanometers.

To determine the dominant wavelength of the electromagnetic radiation emitted by the phosphor, a straight line is drawn in the CIE standard diagram from the white point through the color locus of the electromagnetic radiation. The point of intersection of the straight line with the spectral color line delimiting the CIE standard diagram, which is closer to the color locus of emission of the phosphor, denotes the dominant wavelength of the electromagnetic radiation. In general, the dominant wavelength differs from the wavelength of the emission maximum.

According to at least one embodiment of the phosphor, in particular with the molecular formula Li₈MC[LiSi₄N₄O₈]:Ce³⁺, the emission spectrum of the electromagnetic radiation emitted by the phosphor comprises an emission peak with an emission maximum which is in the range of between and including 490 nanometers and 550 nanometers, in particular in the range of between and including 500 nanometers and 530 nanometers.

According to at least one embodiment of the phosphor, in particular with the molecular formula Li₈MC[LiSi₄N₄O₈]:Ce³⁺, a dominant wavelength λ_{dom} of the electromagnetic radiation emitted by the phosphor is in the range of between and including 500 nanometers and 600 nanometers, in particular in the range of between and including 525 nanometers and 575 nanometers.

According to at least one embodiment of the phosphor, the emission spectrum of the electromagnetic radiation emitted by the phosphor comprises an emission peak with an emission maximum that is in the orange to red range of the electromagnetic spectrum. The orange to red range of the electromagnetic spectrum comprises in particular wavelengths in the range of between and including 600 nanometers and 780 nanometers. In particular, the phosphor emits electromagnetic radiation in the orange and/or red range of the electromagnetic spectrum. The orange range comprises, for example, electromagnetic radiation with wavelengths in the range of between and including 600 nanometers and 640 nanometers. The red range includes, for example, electromagnetic radiation with wavelengths in the range of between and including 640 nanometers and 780 nanometers. For example, an orange to red emission is achieved by a phosphor with Eu²⁺ as the activator element. Red emission can be achieved with Mn²⁺ or Mn⁴⁺. Furthermore, it is possible that a Ce³⁺-activated phosphor with MC equal to Ho, Pr, Tm, and Eu comprises an emission in the orange to red wavelength range.

Advantageously, the orange to red emitting phosphor can be used for general lighting, store lighting, horticultural lighting, and for backlighting displays.

According to at least one embodiment of the phosphor, a dominant wavelength λ_{dom} of the electromagnetic radiation emitted by the phosphor is in the range of between and including 600 nanometers and 780 nanometers, in particular in the range of between and including 600 nanometers and 750 nanometers.

According to at least one embodiment of the phosphor, the emission spectrum of the electromagnetic radiation emitted by the phosphor comprises an emission peak with an emission maximum that is in the near-infrared to infrared range of the electromagnetic spectrum. The near-infrared range of the electromagnetic spectrum comprises, for example, wavelengths in the range of between and including 780 nanometers and 3.0 micrometers, in particular in the range of between and including 800 nanometers and 1500 nanometers, for example in the range of between and including 850 nanometers and 1050 nanometers. For example, near-infrared emission is achieved by a phosphor with Eu²⁺ as activator element. Near-infrared to infrared emission can also be observed with Cr³⁺, Nd³⁺, Tm³⁺, Er³⁺, Ni²⁺, Ti²⁺, Ti³⁺, or Bi³⁺ as activator element.

It is also possible that Ce³⁺ can be used as an activator element for near-infrared emission, in particular with MC equal to Nd, Er, or Tm. In this case, the activator element Ce³⁺ acts as a sensitizer for MC equal to Nd, Er, or Tm. In particular, the activator element Ce³⁺ transfers a part of the absorbed energy to the Nd, Er, or Tm, so that an emission that can be traced back to transitions in the Ce³⁺ can almost no longer be measured. For example, the phosphor with MC equal to Nd or Er and E equal to Ce³⁺ or with MC equal to Gd and E equal to Ce³⁺ and Nd³⁺ emits in the range of between and including 850 nanometers and 1050 nanometers. For example, the phosphor with MC equal to Nd or Er, in particular with E equal to Ce³⁺, also emits in the of range between and including 1050 nanometers and 2500 nanometers, in particular in the range of between and including 1050 nanometers and 1700 nm.

In particular, the phosphor with MC equal to Tm emits in the range of between and including 750 nanometers and 850 nanometers. For example, the phosphor, in particular with MC equal to Er, comprises an emission maximum in the range of between and including 1500 nanometers and 1650 nanometers. Advantageously, the phosphor with near-infrared and/or infrared emission can be used for spectroscopic analysis, for example of foods or polymers, and for sensor applications.

For example, amino groups comprise an absorption band around about 1050 nanometers and/or at about 1500 nanometers. The absorption band can be used in particular to detect the protein content of food. The phosphor described here comprises in particular an emission in this range. It can therefore be used advantageously in applications that serve to determine the protein content of food. For example, the phosphor with MC equal to Nd or Er is used for such applications.

Furthermore, due to the emission properties described above, the phosphor described here, in particular with Cr³⁺ or Ni²⁺ as activator element or with MC=Nd or Er, can advantageously be used in applications in which broadband emission in the infrared spectral range is required. For example, the phosphor is used in analyzers comprising a silicon detector. The sensitivity of the silicon detector decreases significantly with increasing wavelength from about 900 nanometers. This effect can be counteracted with the phosphor described herein. As a result, the measurement accuracy of the spectroscopic investigations can be advantageously increased and, for example, weak absorption bands in the range above 900 nanometers can also be detected.

Furthermore, a phosphor described herein with an emission in the infrared range can be used in optical coherence tomography, in particular in the field of medicine, for example in ophthalmology, or angiography. In coherence tomography, wavelengths in the range of between and including 800 nanometers and 1400 nanometers are used in particular. Angiography is used, for example, to visualize blood vessels. Similarly, the phosphor described herein with an emission in the infrared range can be used in facial recognition, in particular for unlocking a smartphone or for authentication, or in optical temperature measurement. In optical temperature measurement, for example, the change in emission is observed as a function of the ambient temperature.

It is possible that phosphors with Cr³⁺ as activator element comprise a low efficiency. This can be explained by the moderate excitability of the Laporte-prohibited d-d electron transition of the Cr³⁺ activator element. It is also possible that Cr³⁺-activated phosphors comprise only a low temperature stability of the emission, as increased temperature can lead to increased non-radiative transitions of the excited Cr³⁺ electrons to the ground state and thus to a decrease in emission intensity. With other phosphors, such an effect can already occur at temperatures below room temperature, i.e. around 23° C.

For lanthanide ions, such as Nd³⁺ or Er³⁺, shielding of their 4f electrons by the electrons of the closed 5s²5p⁶ xenon shell is observable. Optical transitions between 4f states, which may also be responsible for the emission of the phosphor described herein, are thus hardly influenced by lattice vibrations or interactions with ligands, which can also be enhanced by an increased temperature. Thus, with the phosphor herein, especially with MC=Nd or Er, non-radiative transitions to the ground state due to lattice vibrations are less likely. Therefore, advantageously, the phosphor with MC or E=Nd or Er described herein is used in applications where emission in the near infrared region is required. The phosphors with MC or E=Nd or Er can comprise a more stable emission even at higher operating temperatures compared to other phosphors.

Previously used materials such as Cd(Te,Se) material systems, for example quantum dots, fulfill the necessary criteria of a continuous emission spectrum in the near infrared range for spectroscopic investigations, but they are not suitable for industrial applications due to the toxicity of Cd. However, the phosphor described here is free of Cd in particular and is therefore advantageously not subject to any strict restrictions on use.

According to at least one embodiment of the phosphor, the emission spectrum of the electromagnetic radiation emitted by the phosphor comprises a centroid wavelength λ_{centroid} in the range of between and including 700 nanometers and 2000 nanometers.

The centroid wavelength designates the center of gravity of a spectral distribution of an emission spectrum. In other words, the centroid wavelength indicates where the center of the emission spectrum is located. The centroid wavelength is calculated as the weighted arithmetic mean of the wavelengths λ, weighted with their amplitudes using the distribution function s(λ):

$${λ}_{centroid} = \frac{{\int }_{- ∞}^{∞} λ \cdot s ( λ ) d λ}{{\int }_{- ∞}^{∞} s ( λ ) d λ} .$$

According to at least one embodiment of the phosphor, an emission peak in the emission spectrum of the electromagnetic radiation emitted by the phosphor comprises a full width at half maximum (FWHM) of at most 800 nanometers, in particular of at most 500 nanometers, for example of at most 300 nanometers or of at most 250 nanometers.

The term full width at half maximum refers to a curve with a maximum, such as the emission spectrum, where the full width at half maximum is the area on the x-axis corresponding to the two y-values corresponding to half of the maximum.

According to at least one embodiment of the phosphor, an emission peak in the emission spectrum of the electromagnetic radiation emitted by the phosphor comprises a full width at half maximum in the range of between and including 50 nanometers and 250 nanometers, in particular in the range of between and including 80 nanometers and 150 nanometers. In other words, the phosphor is in particular a broadband emitting phosphor. Advantageously, such a phosphor can be used in white light applications. Due to the large full width at half maximum, a large wavelength range is covered, so that a mixture of different phosphors is advantageously no longer necessary.

For example, an emission peak of a phosphor with Ce³⁺ as activator element comprises a full width at half maximum in the range of between and including 70 nanometers and 250 nanometers. For example, a phosphor with Eu²⁺ as activator element comprises an emission peak with a full width at half maximum in the range of between and including 10 nanometers and 180 nanometers or between and including 10 nanometers and 150 nanometers.

According to at least one embodiment of the phosphor, an emission peak in the emission spectrum of the electromagnetic radiation emitted by the phosphor comprises a full width at half maximum of at most 50 nanometers. In particular, the full width at half maximum is at most 30 nanometers or at most 20 nanometers. In other words, the phosphor is, for example, a narrow-band emitting phosphor. Advantageously, such a phosphor can be used in applications in which a defined narrowband wavelength range is required, for example in display applications with color filters. If a broader wavelength range were made available for the color filter, energy would be lost due to the unsuitable wavelengths. The present phosphor at can therefore increase the efficiency of such applications.

For example, a phosphor with Mn⁴⁺ as the activator element comprises an emission peak with a full width at half maximum of at most 50 nanometers. Emission peaks resulting from MC or E equal to Eu³⁺ can also comprise a full width at half maximum of at most 50 nanometers. In particular, the phosphor with E equal to Mn⁴⁺, Pr³⁺, Ho³⁺, Nd³⁺, Tb³⁺, Tm³⁺, Er³⁺, Sm³⁺ or Eu³⁺ comprises an emission peak with a full width at half maximum in the range of between and including 1 nanometer and 20 nanometers.

According to at least one embodiment of the phosphor, the emission spectrum comprises a plurality of emission peaks. In particular, the plurality of emission peaks comprises at least two emission peaks, for example three or more emission peaks, which comprise, for example, a different spectral intensity and/or a different full width at half maximum.

In particular, the phosphor comprises an emission peak with an emission maximum in the green to yellow wavelength range of the electromagnetic spectrum and an emission peak in the orange to red wavelength range and/or in the near-infrared to infrared wavelength range of the electromagnetic spectrum.

Thus, it is advantageously possible to achieve a higher color rendering index (CRI) when using the phosphor in an optoelectronic component than when using only a conventional phosphor, for example a garnet. In particular, an improved CRI is observed with phosphors, especially with the molecular formula Li₈MC[LiSi₄N₄O₈]:Ce³⁺, with MC equal to Ho, Pr, Tm, Tb, Sm, or Eu. The phosphor described herein with E equal to Ho, Pr, or Eu can also advantageously lead to an improved color rendering index in optoelectronic components.

Furthermore, it is advantageously possible that only a single phosphor needs to be used due to the different emission peaks and not a mixture of different phosphors. In particular, the use of expensive red-emitting nitride phosphors can be avoided.

According to at least one embodiment of the phosphor, an emission spectrum of the electromagnetic radiation emitted by the phosphor comprises only one emission peak.

According to at least one embodiment, the phosphor comprises an improved luminous efficacy of radiation. The luminous efficacy of radiation (LER) of the phosphor is the quotient of a luminous flux of the electromagnetic radiation emitted by the phosphor and the radiant power of the electromagnetic radiation emitted by the phosphor. The greater the luminous efficacy of radiation, the greater the luminous flux that can be used by the eye for a given power.

For example, an improved luminous efficacy of radiation can be observed for phosphors, in particular with the molecular formula Li₈MC[LiSi₄N₄O₈]:Ce³⁺, with MC equal to Y, Gd, Tm, Lu, Sm, or Dy.

According to at least one embodiment, the phosphor, in particular with the molecular formula Li₈MC[LiSi₄N₄O₈]:Ce³⁺, comprises a luminous efficacy of radiation in the range of between and including 400 lm·W_{opt.}⁻¹ and 500 lm·W_{opt.}⁻¹. For example, the luminous efficacy of radiation of the phosphor is greater than 430 lm·W_{opt.}⁻¹. Thus, the phosphor described herein may advantageously comprise a higher luminous efficacy of radiation than conventional garnet phosphors.

According to at least one embodiment of the phosphor, in particular with the molecular formula Li₈MC[LiSi₄N₄O₈]:Ce³⁺, an intensity of the emission of the phosphor at about 100° C. is at least 70%, in particular at least 75%, for example about 85% of the intensity of the emission of the phosphor at about 25° C. Thus, the phosphor advantageously comprises a high temperature stability.

According to at least one embodiment, the phosphor is crystalline. In other words, the host structure of the phosphor comprises a defined crystal structure. The crystal structure can be described with the help of a unit cell. The unit cell is a unit from which the host structure can be built up by repeated translation in three directions.

Six lattice parameters are required to describe the three-dimensional unit cell of the crystal structure, three lengths a, b, and c and three angles α, β, and γ. The three lattice parameters a, b, and c are the lengths of the lattice vectors that span the unit cell. The other three lattice parameters α, β, and γ are the angles between these lattice vectors. α is the angle between b and c, β is the angle between a and c and γ is the angle between a and b. V corresponds to the volume of the unit cell.

According to at least one embodiment of the phosphor, the crystal structure of the host structure of the phosphor comprises a scaffold. In particular, the scaffold is composed of scaffold formers, such as MA, MD, ME and MG, in combination with oxygen and nitrogen. In the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, the scaffold-forming components of the phosphor are given in square brackets. Li, MB, MF and MC, for example, are arranged in spaces between the scaffold. In particular, the activator element E is also arranged in the spaces of the scaffold. The activator element E, for example, occupies the same places in the host structure as MC.

According to at least one embodiment of the phosphor, the scaffold is composed of layers and/or a three-dimensional network. In other words, the crystal structure of the host structure of the phosphor may comprise layers and/or a three-dimensional network. In particular, the layers or the three-dimensional network are formed with tetrahedra. For example, the three-dimensional network is formed from linked layers.

In particular, the scaffold and/or a position of the atoms in the spaces between the scaffold change depending on the composition of the phosphor. This can be explained, for example, by different atomic radii and/or by preferred coordination spheres of the elements used. For example, the structure changes in the presence of MB, MF, ME and/or MG. However, it is also possible that the structure remains the same even in the presence of MB, MF, ME and/or MG.

According to at least one embodiment of the phosphor, the crystal structure of the host structure of the phosphor comprises coordination polyhedra comprising Li, MB, MF, MC, MA, MD, ME or MG as central atom. In particular, the coordination polyhedra are selected from the following group: tetrahedron, trigonal bipyramid, square bipyramid, pentagonal bipyramid, hexagonal bipyramid, square pyramid, pentagonal pyramid, hexagonal pyramid, octahedron, cube, trigonal prism, square prism, trigonal antiprism, tetragonal, in particular square, antiprism. It is also possible that Li, MB, MF, MC, MA, MD, ME or MG is trigonal planar or square planar coordinated. The tetrahedra can be single, double or triple capped and/or distorted.

According to at least one embodiment of the phosphor, the coordination polyhedra are at least partially corner-linked. Corner-linked coordination polyhedra comprise in particular a common corner. For example, such a corner is formed by an anion.

According to at least one embodiment of the phosphor, the coordination polyhedra are at least partially edge-linked. Edge-linked coordination polyhedra comprise in particular a common edge.

According to at least one embodiment of the phosphor, the crystal structure of the host structure of the phosphor comprises at least one structural element selected from the following group: MA(N,O)₄ tetrahedron, MD(N,O)₄ tetrahedron, ME(N,O)₄ tetrahedron, MG(N,O)₄ tetrahedron. In particular, the crystal structure comprises Si(N,O)₄ tetrahedra and/or Li(N,O)₄ tetrahedra.

In particular, the tetrahedra comprise a tetrahedral gap. The tetrahedral gap is an area inside the respective tetrahedron. For example, the term “tetrahedral gap” is used to describe the area inside the tetrahedron that remains free when spheres are placed in the corners of the tetrahedron that are thought to be touching.

The N atoms and/or the O atoms of the tetrahedron span the tetrahedron, whereby the MA atom, the MD atom, the ME atom, or the MG atom is located in the tetrahedral gap of the spanned tetrahedron, depending on the type of tetrahedron. In other words, the tetrahedra are centered around the MA atom, the MD atom, the ME atom, or the MG atom, depending on the type of tetrahedron. The MA atom, the MD atom, the ME atom, or the MG atom is surrounded in the shape of a tetrahedron by a total of four N atoms and/or O atoms. In particular, all N atoms and/or O atoms spanning the tetrahedron have a similar distance to the MA atom, the MD atom, the ME atom, or the MG atom located in the tetrahedral gap.

According to at least one embodiment of the phosphor, the crystal structure of the host structure of the phosphor comprises corner-linked MA(N,O)₄ tetrahedra, MD(N,O)₄ tetrahedra, ME(N,O)₄ tetrahedra and/or MG(N,O)₄ tetrahedra. In particular, the MA(N,O)₄ tetrahedra, MD(N,O)₄ tetrahedra, ME(N,O)₄ tetrahedra and/or MG(N,O)₄ tetrahedra are corner-linked on all sides.

According to at least one embodiment of the phosphor, the crystal structure of the host structure of the phosphor comprises edge-linked MA(N,O)₄ tetrahedra, MD(N,O)₄ tetrahedra, ME(N,O)₄ tetrahedra and/or MG(N,O)₄ tetrahedra.

According to at least one embodiment of the phosphor, MC and/or E are eightfold coordinated in the crystal structure of the host structure of the phosphor. In other words, there are eight anions in a coordination sphere of MC and/or E. In particular, an MC atom and/or an E atom are surrounded squarely antiprismatically by eight anions. It has become apparent that eightfold coordination has a positive influence on the emission properties of MC and/or E.

According to at least one embodiment of the phosphor, in particular with the molecular formula Li₈MC[LiSi₄N₄O₈]:E, the crystal structure of the host structure of the phosphor comprises fivefold coordinated Li. In particular, Li is trigonally bipyramidal and/or square pyramidally coordinated. However, it is also possible that Li is coordinated differently in the phosphor.

According to at least one embodiment of the phosphor, in particular with the molecular formula Li₈MC[LiSi₄N₄O₈]:E, the crystal structure of the host structure of the phosphor comprises different layers. In particular, the layers are arranged alternately. For example, the layers lie in the ab plane.

According to at least one embodiment of the phosphor, in particular with the molecular formula Li₈MC[LiSi₄N₄O₈]:E, the crystal structure of the host structure of the phosphor comprises a first layer. The first layer is, for example, a lithosilicate layer. A lithosilicate layer comprises in particular Si(N,O)O tetrahedra and Li(N,O)O tetrahedra.

According to at least one embodiment of the phosphor, in particular with the molecular formula Li₈MC[LiSi₄N₄O₈]:E, the first layer comprises structural elements selected from the following group: MA(N,O)₄ tetrahedra, MD(N,O)₄ tetrahedra, ME(N,O)₄ tetrahedra, MG(N,O)₄ tetrahedra. In particular, the structural elements in the first layer are corner-linked, for example on all sides. In particular, the first layer comprises Si(N,O)₄ tetrahedra and Li(N,O)₄ tetrahedra. For example, a Li(N,O)₄ tetrahedron is corner-linked with four Si(N,O)₄ tetrahedra.

According to at least one embodiment of the phosphor, in particular with the molecular formula Li₈MC[LiSi₄N₄O₈]:E, the first layer comprises four-rings MA(N,O)₄ tetrahedra, MD(N,O)₄ tetrahedra, ME(N,O)₄ tetrahedra and/or MG(N,O)₄ tetrahedra, in particular MD(N,O)₄ tetrahedra, for example Si(N,O)₄ tetrahedra. The four-rings are formed in particular by corner linking of the tetrahedra.

According to at least one embodiment of the phosphor, in particular with the molecular formula Li₈MC[LiSi₄N₄O₈]:E, the crystal structure of the host structure of the phosphor comprises channels. In particular, the channels are created by the four-rings in the first layer. For example, the channels run along the c-axis.

According to at least one embodiment of the phosphor, in particular with the molecular formula Li₈MC[LiSi₄N₄O₈]:E, the MC atoms are arranged in the channels. In particular, the MC atom is squarely antiprismatically coordinated. It is possible that the activator element E occupies the same positions as the MC atoms in the crystal structure of the host structure of the phosphor.

According to at least one embodiment of the phosphor, in particular with the molecular formula Li₈MC[LiSi₄N₄O₈]:E, the crystal structure of the host structure of the phosphor comprises a second layer. In particular, the first layer and the second layer are arranged alternately. For example, the first layer and the second layer are linked to each other. In this way, a three-dimensional network can be formed.

According to at least one embodiment of the phosphor, in particular with the molecular formula Li₈MC[LiSi₄N₄O₈]:E, the second layer comprises coordination polyhedra with Li as the central atom. In particular, the second layer comprises fivefold coordinated Li. For example, the Li in the second layer is trigonally bipyramidal and/or quadratically pyramidal coordinated. In other words, the second layer comprises trigonal Li(N,O)₅ bipyramids and/or square Li(N,O)₅ pyramids. In particular, the coordination polyhedra with Li as the central atom, for example the trigonal Li(N,O)₅ bipyramids and/or the square Li(N,O)₅ pyramids, are edge-linked.

In particular, the coordination polyhedra with Li as the central atom, for example the trigonal Li(N,O)₅ bipyramids and/or the square Li(N,O)₅ pyramids, are arranged in the second layer in such a way that the channels from the first layer are continued. For example, four trigonal Li(N,O)₅ bipyramids and four square Li(N,O)₅ pyramids are arranged in such a way that the channels from the first layer are continued.

According to at least one embodiment of the phosphor, in particular with the molecular formula Li₈MC[LiSi₄N₄O]:E, the first layer and the second layer form a three-dimensional network. Therefore, the phosphor can also be referred to as lithium oxonitridolithosilicate.

According to at least one embodiment of the phosphor, in particular with the molecular formula Li₈MC[LiSi₄N₄O]:E, the crystal structure of the host structure of the phosphor comprises a tetragonal space group, in particular P4/n.

According to at least one embodiment of the phosphor, in particular with the molecular formula Li₈MC[LiSi₄N₄O]:E, the crystal structure of the host structure of the phosphor comprises a lattice parameter a in the range of between and including 8.00 Å and 12.00 Å, in particular in the range of between and including 9.50 Å and 10.50 Å. In a tetragonal space group, the lattice parameter a is in particular equal to the lattice parameter b.

According to at least one embodiment of the phosphor, in particular with the molecular formula Li₈MC[LiSi₄N₄O]:E, the crystal structure of the host structure of the phosphor comprises a lattice parameter c in the range of between and including 4.00 Å and 6.00 Å, in particular in the range of between and including 4.50 Å and 5.50 Å.

According to at least one embodiment of the phosphor, in particular with the molecular formula Li₈MC[LiSi₄N₄O]:E, the crystal structure of the host structure of the phosphor comprises a cell volume V in the range of between and including 400 Å³ and 600 Å³, in particular in the range of between and including 450 Å³ and 550 Å³.

According to at least one embodiment, the phosphor comprises the same crystal structure as Li₈Gd[LiSi₄N₄O₈]:E.

A method for producing a phosphor is further disclosed. In at least one example, the phosphor according to the embodiments mentioned above is produced with the method described herein. In particular, all the explanations given for the phosphor also apply to the method and vice versa.

According to at least one embodiment of the method, a phosphor comprising an element or a combination of elements from the group of monovalent elements, an element or a combination of elements from the group of trivalent elements, an element or a combination of elements from the group of tetravalent elements, oxygen and/or nitrogen, and an activator element E is produced.

According to at least one embodiment of the method, a phosphor with the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E is produced, wherein 0≤x≤4, 0≤c≤1, 0≤z≤4, 0≤a≤8, 0≤b≤4, 0≤2x+a≤8, 0≤z+b≤4, −4≤−z+b−c≤4, MB is an element or a combination of elements from the group of divalent elements, MC is an element or a combination of elements from the group of trivalent elements, MA is Li and/or Na, MD is an element or a combination of elements from the group of tetravalent elements, ME is an element or a combination of elements from the group of trivalent elements, MF is an element or a combination of elements from the group of monovalent elements, MG is an element or a combination of elements from the group of pentavalent elements and E is an activator element.

According to at least one embodiment of the method, reactants are provided. In particular, the reactants are selected from a group formed by the elements, oxides, nitrides, nitridosilicates, halides, oxalates, citrates, carbonates, amides, and imides of monovalent elements, divalent elements, trivalent elements, tetravalent elements, pentavalent elements, and the activator element. In particular, the reactants are selected from the group formed by the elements, oxides, nitrides, nitridosilicates, halides, oxalates, citrates, carbonates, amides, and imides of Li, MB, MF, MC, MA, MD, ME, MG, and E. For example, the reactants, in particular for producing the phosphor with the molecular formula Li₈MC[LiSi₄N₄O₈]:E, are selected from the group formed by the elements, oxides, nitrides, nitridosilicates, and fluorides of Li, MC, Si, and E. In particular, the reactants are selected from the group formed by Si, Si₃N₄, Li₂SiN₂, SiO₂, Li₂O, Li₃N, LiN₃, LiF, Gd, Gd₂O₃, GdF₃, Dy, Dy₂O₃, DyF₃, Ho, HO₂O₃, HoF₃, Pr, Pr₂O₃, Pr₆O₁₁, PrF₃, Nd, Nd₂O₃, NdF₃, Y, Y₂O₃, YF₃, Tm, Tm₂O₃, TmF₃, Tb, Tb₂O₃, Tb₄O₇, TbF₃, Er, Er₂O₃, ErF₃, Lu, Lu₂O₃, LuN, LuF₃, Yb, Yb₂O₃, YbF₃, Sm, Sm₂O₃, SmF₃, Ce, CeO₂, CeF₃, CeN, EuF₂, Eu₂O₃. Advantageously, the reactants can be obtained easily and inexpensively.

According to at least one embodiment of the method, the reactants are mixed to form a reactant mixture. The mixing is carried out in particular with a hand mortar, a mortar mill, a ball mill, or a multi-axis mixer.

According to at least one embodiment of the method, the reactant mixture is heated. In particular, the heating takes place in a tube furnace, a flow tube furnace, or in a high-frequency furnace.

According to at least one embodiment, the method comprises the steps of providing reactants, mixing the reactants to form a reactant mixture, and heating the reactant mixture. In particular, the steps are carried out in the specified order.

In particular, it is possible for the method to produce a mixture comprising or consisting of the phosphor. Further components of the mixture can be, for example, reactants which have not reacted during the producing of the phosphor, impurities, and/or secondary phases which were formed during the producing.

According to at least one embodiment of the method, the heating to a first temperature in the range of between and including 700° C. and 1600° C., in particular in the range of between and including 800° C. and 1600° C., for example in the range of between and including 900° C. and 1400° C. is carried out.

According to at least one embodiment of the method, the heating to a first temperature in the range of between and including 800° C. and 1100° C., in particular to a temperature in the range of between and including 900° C. and 1000° C. is carried out. In particular, such a temperature is used when using a Ta tube. Advantageously, the phosphor, in particular with the molecular formula Li₈MC[LiSi₄N₄O]:E, can thus be produced at a relatively low temperature. Garnets RE₃(Al,Ga)₅O₁₂:E, on the other hand, are produced at a temperature of at least 1500° C. Thus, energy can be advantageously saved with the method described herein.

According to at least one embodiment of the method, the reactant mixture is heated to the first temperature for a time in the range of between and including 30 minutes and 20 hours, in particular for a time in the range of between and including 8 hours and 15 hours, for example for a time of about 12 hours.

According to at least one embodiment of the method, the reactant mixture is cooled, in particular slowly, after heating. For example, a temperature program comprising a second temperature and/or a third temperature is run through during cooling. To reach the second temperature, a first cooling rate is set in particular. In particular, a second cooling rate is set to reach the third temperature.

In particular, the second temperature is at most 600° C., for example at most 500° C. In particular, the third temperature is at most 200° C., for example at most 150° C. In particular, the first cooling rate is at most 500° C./h, in particular at most 6° C./h, for example at most 3° C./h, for example at about 2° C./h or at about 1° C./h. In particular, the second cooling rate is at most 250° C./h, in particular at most 20° C./h, for example at most 18° C./h.

According to at least one embodiment of the method, the reactant mixture is heated under a protective gas atmosphere. For example, the protective gas atmosphere is an atmosphere of argon and/or N₂, in particular argon. In particular, the heating of the reactant mixture leads to an overpressure of the protective gas during the reaction.

According to at least one embodiment of the method, the heating takes place in a W-crucible, a Ni-crucible or a Ta-tube. Heating in a W-crucible or a Ni-crucible takes place, for example, in a flow tube furnace or a high-frequency furnace. Heating in a Ta tube takes place in a tube furnace, for example.

According to at least one embodiment of the method, a flux is added to the reactant mixture. In particular, at most 10 wt. %, in particular with at most 5 wt. %, of the flux is added to the total amount of the reactant mixture. The flux can advantageously be used to improve the crystallinity of the phosphor and/or to support crystal growth.

In particular, the flux comprises a compound selected from the group formed by halides, in particular chlorides and/or fluorides, boron-containing compounds, and combinations thereof. For example, the flux is a compound or a combination of compounds selected from the following group: Li, LiF, LiCl, NaF, NaCl, SrCl₂, SrF₂, CaCl₂, CaF₂, BaCl₂, BaF₂, NH₄Cl, NH₄F, KF, KCl, MgF₂, MgCl₂, AlF₃, H₃BO₃, B₂O₃, Li₂B₄O₇, NaBO₂, Na₂B₄O₇, LiBF₄, NH₄HF₂, NaBF₄, KBF₄, EuF₃, and compounds derived therefrom, such as hydrates. Advantageously, a reactant can also serve as flux.

According to at least one embodiment of the method, the phosphor, in particular with the molecular formula Li₈MC[LiSi₄N₄O₈]:E, is produced with the reactants Si₃N₄, SiO₂, Li₂O, and MC₂O₃, MC₆O₁₁, or MCF₃. The reactant mixture further comprises a reactant for E, for example CeF₃. In particular, the reactants Si₃N₄, SiO₂, Li₂O, and MC₂O₃, MC₆O₁₁, or MCF₃ are used in a ratio of 2.2:1.6:10.5:0.3 to 2:2:10.5:1 or from 2:2:10.5:0.3 to 2:2:10.5:1. For example, Li or LiF is added to the reactant mixture as flux with a maximum of 10 wt. %, in particular with a maximum of 5 wt. % based on the total amount of the reactant mixture.

Furthermore, the use of a phosphor described herein is specified. All features disclosed in relation to the phosphor therefore also apply to the use and vice versa.

According to at least one embodiment, the phosphor is used in a light source. In particular, the light source is an arrangement with an optoelectronic component that emits electromagnetic radiation in the ultraviolet to infrared wavelength range, in particular in the visible wavelength range of the electromagnetic spectrum.

An optoelectronic component is further described. In particular, the optoelectronic component comprises the phosphor described herein. All explanations made for the phosphor and the method for producing a phosphor therefore also apply in particular to the optoelectronic component and vice versa.

According to at least one embodiment, the optoelectronic component comprises a radiation-emitting semiconductor chip. In particular, the radiation-emitting semiconductor chip emits electromagnetic radiation of a first wavelength range during operation. The semiconductor chip can comprise an active, in particular epitaxially grown, layer sequence which contains an active region that can generate the electromagnetic radiation of the first wavelength range during operation of the component. The semiconductor chip is, for example, a light-emitting diode chip or a laser diode chip. The electromagnetic radiation of the first wavelength range, which is generated in the semiconductor chip, is emitted, for example, by a radiation exit surface of the semiconductor chip. In particular, the electromagnetic radiation of the first wavelength range comprises the excitation wavelength of the phosphor described herein.

According to at least one embodiment, the optoelectronic component comprises a conversion element with a phosphor described herein. In particular, the phosphor converts the electromagnetic radiation of the first wavelength range into electromagnetic radiation of a second wavelength range. The first wavelength range is at least partially different from the second wavelength range. The conversion element is arranged, for example, in such a way that the electromagnetic radiation of the first wavelength range emitted by the radiation-emitting semiconductor chip strikes the conversion element. The electromagnetic radiation of the second wavelength range comprises the electromagnetic radiation emitted by the phosphor.

According to at least one embodiment, the optoelectronic component comprises a radiation-emitting semiconductor chip and a conversion element with the phosphor described herein.

According to at least one embodiment of the optoelectronic component, the radiation-emitting semiconductor chip comprises a micro-LED. Here and in the following, LED is the abbreviation for light emitting diode. In particular, the radiation-emitting semiconductor chip is a micro LED.

Micro LEDs can comprise a width, a length, a thickness, and/or a diameter smaller than or equal to 100 micrometers, in particular smaller than or equal to 70 micrometers, for example smaller than or equal to 50 micrometers. In particular, micro-LEDs, for example rectangular micro-LEDs, comprise an edge length, in particular in plan view of the layers of the layer stack, of a luminous surface smaller than or equal to 70 micrometers, for example smaller than or equal to 50 micrometers. A micro LED is, for example, a light-emitting diode in which a growth substrate is removed, so that a thickness of the micro LED is, for example, in the range of between and including 1.5 micrometers and 10 micrometers.

For example, the micro LED is provided on a wafer with detachable holding structures. The micro LED can be detached from the wafer non-destructively.

In particular, micro LEDs are mainly used in displays. The micro LEDs form pixels or sub-pixels and emit light in a defined color. Due to the small pixel size and high density at small distances, micro LEDs are suitable for small monolithic displays for augmented reality applications, in particular data glasses. Other applications are also being developed, in particular for use in data communication or for pixelated lighting applications.

According to at least one embodiment of the optoelectronic component, the first wavelength range comprises wavelengths in the ultraviolet to blue wavelength range of the electromagnetic spectrum. For example, the first wavelength range comprises wavelengths in the range of between and including 300 nanometers and including 550 nanometers, in particular in the range of between and including 400 nanometers and 500 nanometers.

In particular, the radiation-emitting semiconductor chip emits electromagnetic radiation with a dominant wavelength λ_{dom} in the range of between and including 430 nanometers and 460 nanometers.

According to at least one embodiment of the optoelectronic component, the radiation-emitting semiconductor chip emits blue light with a power of at least 0.25 W_{opt.}/mm², of at least 0.5 W_{opt.}/mm2 or of at least 1 W_{opt.}/mm².

According to at least one embodiment of the optoelectronic component, the first wavelength range comprises wavelengths in the red region of the electromagnetic spectrum. For example, the first wavelength range comprises wavelengths in the range of between and including 600 nanometers and 780 nanometers. In particular, a radiation-emitting semiconductor chip that emits electromagnetic radiation of the first wavelength range with wavelengths in the red region of the electromagnetic spectrum is used together with a phosphor described herein with Cr, Ho, Pr, Nd, Er, Cu, or Ni as activator element E. For example, a red-emitting radiation-emitting semiconductor chip can also be combined with the phosphor with MC equal to Ho, Pr, Tb, Er, Tm, or Nd. With MC equal to Ho, Pr, Tb, Er, Tm, or Nd, for example, electromagnetic radiation from the red region of the electromagnetic spectrum excites f→f transitions, which can lead to emission of the phosphor in the near-infrared or infrared region.

According to at least one embodiment of the optoelectronic component, the first wavelength range comprises wavelengths in the range of between and including 700 nanometers and 1650 nanometers. In particular, in this case a phosphor described herein with infrared emission is used in the conversion element.

According to at least one embodiment of the optoelectronic component, the radiation-emitting semiconductor chip and the conversion element are arranged in a housing, in particular in a cavity of a housing. The housing advantageously serves to mechanically stabilize and protect the semiconductor chip arranged therein and the conversion element arranged therein.

According to at least one embodiment of the optoelectronic component, the conversion element is in direct contact with the radiation-emitting semiconductor chip.

According to at least one embodiment of the optoelectronic component, the conversion element is arranged at a distance from the radiation-emitting semiconductor chip. However, it is possible for the conversion element to be connected to the radiation-emitting semiconductor chip, for example via an adhesive layer. The adhesive layer comprises, for example, a silicone resin and/or an epoxy resin.

According to at least one embodiment of the optoelectronic component, the conversion element comprises the shape of a platelet. In particular, the phosphor is embedded in an inorganic matrix material. Alternatively, it is possible for the phosphor to form a layer with an organic matrix material or an inorganic matrix material and for the layer to be arranged on a transparent carrier. The layer with the phosphor and the transparent carrier then together form the platelet.

According to at least one embodiment of the optoelectronic component, the conversion element comprises a matrix material. The phosphor is embedded in the matrix material, for example. The matrix material comprises in particular a material selected from the group formed by glass, such as silicate glass, water glass, or quartz glass, and polymers, such as polystyrene, polysilazane, polymethyl methacrylate (PMMA), polycarbonate, polyacrylate, polytetrafluoroethylene, polyvinyl, silicone resin, silicone, polysiloxane, epoxy resin, and combinations thereof. Silicone and/or polysiloxane can be fluorinated. In particular, the phosphor is homogeneously distributed in the matrix material. However, it is also possible that the phosphor comprises a concentration gradient in the matrix material.

According to at least one embodiment of the optoelectronic component, the conversion element is designed as a casting. The casting fills the cavity of the housing at least partially, for example. In addition to the phosphor, the casting also in particular comprises the matrix material. In particular, the casting covers side surfaces of the radiation-emitting component.

According to at least one embodiment of the optoelectronic component, a non-converting casting is arranged in the cavity of the housing. For example, the non-converting casting comprises a transmittance for electromagnetic radiation in the visible wavelength range of at least 85% or at least 95%.

Such a non-converting casting may further comprise scattering particles. The scattering particles are, for example, selected from the group formed by SiO₂ particles, TiO₂ particles, BaSO₄ particles, Al₂O₃ particles, ZrO₂ particles, and combinations thereof. In particular, the scattering particles are homogeneously distributed in the non-converting casting. However, it is also possible that the scattering particles comprise a concentration gradient in the non-converting casting.

According to at least one embodiment of the optoelectronic component, the conversion element comprises scattering particles. The scattering particles are, for example, selected from the group formed by SiO₂ particles, TiO₂ particles, BaSO₄ particles, Al₂O₃ particles, ZrO₂ particles, and combinations thereof. In particular, the scattering particles are homogeneously distributed in the conversion element.

According to at least one embodiment of the optoelectronic component, the conversion element only partially converts the electromagnetic radiation of the first wavelength range into the electromagnetic radiation of the second wavelength range, wherein the unconverted part of the electromagnetic radiation of the first wavelength range is transmitted by the conversion element. In other words, a partial conversion of the electromagnetic radiation of the first wavelength range into electromagnetic radiation of the second wavelength range takes place. In this case, the radiation-emitting component emits a mixed light composed of the electromagnetic radiation of the first wavelength range and the electromagnetic radiation of the second wavelength range. For example, the radiation-emitting component emits white mixed light.

According to at least one embodiment of the optoelectronic component, no electromagnetic radiation of the first wavelength range is transmitted by the conversion element. “No” in this context means that so little electromagnetic radiation of the first wavelength range is transmitted that it no longer perceptibly influences the light emitted by the component. For example, at most 10%, in particular at most 5%, for example at most 1% of the electromagnetic radiation of the first wavelength range is transmitted by the conversion element. The radiation-emitting component then only emits the electromagnetic radiation of the second wavelength range. In other words, a full conversion of the electromagnetic radiation of the first wavelength range into electromagnetic radiation of the second wavelength range takes place.

According to at least one embodiment, the conversion element is free of another phosphor. “Free of another phosphor” means that only one phosphor described herein or a mixture of different phosphors described herein is contained in the conversion element and leads to a wavelength conversion.

According to at least one embodiment of the optoelectronic component, the conversion element comprises at least one further phosphor. In particular, the at least one further phosphor is different from the phosphor described herein. However, it is also possible that the conversion element comprises two different phosphors as described herein. In other words, the at least one further phosphor may be a phosphor described herein but different in composition from the phosphor. In particular, the at least one further phosphor converts the electromagnetic radiation of the first wavelength range into electromagnetic radiation of a third wavelength range. The third wavelength range is at least partially different from the second wavelength range and/or the first wavelength range. In particular, the optoelectronic component emits a mixed light composed of the electromagnetic radiation of the first wavelength range, the electromagnetic radiation of the second wavelength range, and/or the electromagnetic radiation of the third wavelength range.

According to at least one embodiment, the phosphor in the conversion element is present as a ceramic or in a matrix material. A phosphor present as a ceramic is in particular largely free of the matrix material and/or the at least one further phosphor. In at least one example, the ceramic formed from the phosphor comprises a low porosity. This prevents or virtually prevents unwanted light scattering and ensures good heat dissipation.

According to at least one embodiment of the optoelectronic component, the at least one further phosphor is arranged in a separate layer. In other words, the phosphor and the at least one further phosphor are not mixed with each other.

According to at least one embodiment, a layer with the phosphor is arranged next to, above, or below a layer with the at least one further phosphor. Above or below refers here and in the following to a direction perpendicular to a main extension plane of the radiation-emitting semiconductor chip.

In particular, the layer with the phosphor and the layer with the at least one further phosphor are arranged laterally next to each other on the radiation-emitting semiconductor chip. In particular, the radiation-emitting semiconductor chip comprises pixels that can be controlled separately from one another. For example, a pixelated optoelectronic component can be provided by the layers arranged side by side with the phosphor and the at least one further phosphor. Such a pixelated optoelectronic component can advantageously emit electromagnetic radiation with different wavelength ranges depending on the region. For example, such an optoelectronic component is suitable for use in a display.

According to at least one embodiment of the optoelectronic component, the phosphor and the at least one further phosphor are mixed in the conversion element. In other words, the phosphor and the at least one further phosphor are not arranged in different layers. In particular, the phosphor and the at least one further phosphor form a homogeneous mixture.

According to at least one embodiment of the optoelectronic component, the at least one further phosphor is a ceramic phosphor and/or a quantum dot phosphor. In particular, the at least one further phosphor is selected from the group formed by the following compounds or combinations of these compounds: Ce³⁺ doped garnets such as YAG and LuAG, for example (Y,Lu,Gd,Tb)₃(Al₁₋ₓGaₓ)₅O₁₂:Ce³⁺, Eu²⁺ doped nitrides, for example (Ca,Sr)AlSiN₃:Eu²⁺, Sr(Ca,Sr)Si₂Al₂N₆:Eu²⁺ (SCASN), (Sr,Ca)AlSiN₃*Si₂N₂O:Eu²⁺, (Ca,Ba,Sr)₂Si₅N₈:Eu²⁺, SrLiAl₃N₄:Eu²⁺ oder SrLi₂Al₂O₂N₂:Eu²⁺, Ce³⁺ doped nitrides, for example (Ca,Sr)Al_{(1-4x/3)}Si₍₁₊ₓ₎N₃:Ce³⁺ (x=0.2-0.5), Eu²⁺ doped sulfides, (Ba,Sr,Ca)Si₂O₂N₂:Eu²⁺, SiAlONs, nitride orthosilicates, for example AE₂₋ₓ₋ₐREₓEuₐSi_{1-y}O_{4-x-2y}Nₓ, orthosilicate such as (Ba,Sr,Ca)₂SiO₄:Eu²⁺, chlorosilicates, for example Ca₈Mg(SiO₄)₄Cl₂:Eu²⁺), Mn⁴⁺ doped fluorides, for example (K,Na)₂(Si,Ti)F₆:Mn⁴⁺, Eu²⁺ or Ce³⁺ doped litho silicates, such as (Li,Na,K,Rb,Cs)(Li₃SiO₄):E with E=Eu²⁺, Ce³⁺, (Sr,Li)Li₃AlO₄:Eu²⁺, or SrLi₃AlO₄:Eu²⁺.

Other possible compounds for the at least one further phosphor are in particular the following aluminum-containing and/or silicon-containing phosphors: (Ba_{1-x-y}SrₓCa_{y})SiO₄:Eu²⁺ (0≤x≤1, 0≤y≤1), (Ba_{1-x-y}SrₓCa_{y})₃SiO₅:Eu²⁺ (0≤x≤1, 0≤y≤1), Li₂SrSiO₄:Eu²⁺, oxo nitrides such as (Ba_{1-x-y}SrₓCa_{y})Si₂O₂N₂:Eu²⁺ (0≤x≤1; 0≤y≤1), SrSiAl₂O₃N₂:Eu²⁺, Ba₄₋ₓCaₓSi₆ON₁₀:Eu²⁺ (0≤x≤1), (Ba₁₋ₓSrₓ)Y₂Si₂Al₂O₂N₅:Eu²⁺ (0≤x≤1), SrₓSi_{(6-y)}Al_{y}O_{y}N_{(8-y)}:Eu²⁺ (0.05≤x≤0.5; 0.001≤y≤0.5), Si_{6-z}Al_{z}O_{z}N_{8-z}:Eu²⁺ (0≤z≤0.42), MₓSi₁₂₋ₘ₋ₙAlₘ₊ₙOₙN₁₆₋ₙ:Eu²⁺ (M=Li, Mg, Ca, Y; x=m/v; v=valency of M, x≤2), MₓSi₁₂₋ₘ₋ₙAlₘ₊ₙOₙN₁₆₋ₙ:Ce³⁺, AE₂₋ₓ₋ₐREₓEuₐSi_{1-y}O_{4-x-2y}Nₓ (AE=Sr, Ba, Ca, Mg; RE=rare earth element), AE₂₋ₓ₋ₐREₓEuₐSi_{1-y}O_{4-x-2y}Nₓ (AE=Sr, Ba, Ca, Mg; RE=rare earth element), Ba₃Si₆O₁₂N₂:Eu²⁺ or nitrides such as La₃Si₆N₁₁:Ce³⁺, (La₁₋ₓYₓ)₃Si₆N₁₁:Ce³⁺, (Ba_{1-x-y}SrₓCa_{y})₂Si₅N₈:Eu²⁺, (Ca_{1-x-y}SrₓBa_{y})AlSiN₃:Eu²⁺ (0≤x≤1; 0≤y≤1), Sr(Sr₁₋ₓCaₓ)Al₂Si₂N₆:Eu²⁺ (0≤x≤0.2), Sr(Sr₁₋ₓCaₓ)Al₂Si₂N₆:Ce³⁺ (0≤x≤0.2) SrAlSi₄N₇:Eu²⁺, (Ba_{1-x-y}SrₓCa_{y})SiN₂:Eu²⁺ (0≤x≤1; 0≤y≤1), (Ba_{1-x-y}SrₓCa_{y})SiN₂:Ce³⁺ (0≤x≤1; 0≤y≤1), (Sr₁₋ₓCaₓ)LiAl₃N₄:Eu²⁺ (0≤x≤1), (Ba_{1-x-y}SrₓCa_{y})Mg₂Al₂N₄:Eu²⁺ (0≤x≤1; 0≤y≤1), (Ba_{1-x-y}SrₓCa_{y})Mg₃SiN₄:Eu²⁺ (0≤x≤1; 0≤y≤1).

According to at least one embodiment, the optoelectronic component emits white mixed light. Such an optoelectronic component can be used in general lighting, for high-power LEDs, for example for car headlights, or in projection applications, for example in projectors. In particular, the optoelectronic component that emits white mixed light comprises only the phosphor described here in the conversion element. However, it is also possible that the conversion element of the optoelectronic component comprises the at least one further phosphor.

For example, the phosphor, in particular with the molecular formula Li₈MC[LiSi₄N₄O]:E, with MC equal to Gd, Dy, Y, Ho, Tb, Lu, Sm, Yb, Tm, or Pr and/or E equal to Ce³⁺ and/or Eu²⁺ is used in the optoelectronic component that emits white mixed light.

According to at least one embodiment, the optoelectronic component comprises a color rendering index (CRI) of at least 70. The color rendering index is a value that indicates how the color rendering of an artificial light source compares with natural light, such as sunlight. For example, the phosphor described here, in particular with the molecular formula Li₈MC[LiSi₄N₄O]:E with E equal to Ce³⁺ and MC equal to Ho, Tb, Lu, Tm, Sm, or Pr, is used in the conversion element. Advantageously, only the phosphor described here and no phosphor mixture is required to achieve a CRI of at least 70. Optoelectronic components with a CRI of at least 70 are used in street lighting, for example.

According to at least one embodiment, the optoelectronic component comprises a CRI of at least 90. In particular, the phosphor and the at least one further phosphor are used in the conversion element of the optoelectronic component with the CRI of at least 90. For example, the conversion element of the optoelectronic component comprises a phosphor emitting green to yellow and a phosphor emitting red. Advantageously, optoelectronic components with a CRI of at least 90 can be used for general lighting or store lighting.

Advantageously, conventional green to yellow emitting garnet phosphors can be replaced by the phosphor described herein with green to yellow emission. At the same time, it is possible that the phosphor described herein comprises a similar dominant wavelength as the garnet phosphor. Thus, comparable color coordinates can advantageously be achieved with the phosphor described herein. For example, the phosphor with the molecular formula Li₈MC[LiSi₄N₄O₈]:E with E equal to Ce³⁺, Eu²⁺ or Mn²⁺ is used as a green to yellow emitting phosphor.

Furthermore, it is possible to replace conventional red-emitting phosphors with the red-emitting phosphor described herein. The phosphor with the molecular formula Li₈MC[LiSi₄N₄O₈]:E with E equal to Eu²⁺, Mn²⁺ or Mn⁴⁺ can be used as a red-emitting phosphor.

Advantageously, the optoelectronic component can comprise an increased R9 value in addition to a high CRI. For example, the optoelectronic component comprises a conversion element with a phosphor emitting green to yellow and a phosphor emitting red. In particular, the red-emitting phosphor is adapted and/or selected in such a way that the increased R9 value is achieved. The R9 value describes the specific ability of the light to accurately reproduce the red color of objects.

According to at least one embodiment, the optoelectronic component is used in a display. In particular, the optoelectronic component is used as a backlighting unit of the display. For example, the conversion element of the optoelectronic component comprises the phosphor described herein, in particular with the molecular formula Li₈MC[LiSi₄N₄O₈]:E, with E equal to Mn⁴⁺. The Mn⁴⁺-activated phosphor advantageously comprises a narrow-band emission. Therefore, a high color gamut can be achieved for the display. The color gamut is also referred to as the color range. The color gamut comprises the set of all colors of a color space that can be reproduced by a component such as the display.

According to at least one embodiment, the optoelectronic component emits electromagnetic radiation in the wavelength range of between and including 650 nanometers and 780 nanometers. In other words, the optoelectronic component can emit long-wavelength red light. For example, the phosphor, in particular with the molecular formula Li₈MC[LiSi₄N₄O₈]:E, with E equal to Eu²⁺ or Mn⁴⁺, is used in such an optoelectronic component. Chlorophyll, for example, comprises an absorption peak in the range of between and including 650 nanometers and 700 nanometers. Therefore, the optoelectronic component can advantageously be used to illuminate greenhouses, i.e. in horticulture.

According to at least one embodiment of the optoelectronic component, the conversion element comprises the phosphor described herein with an emission peak in the near-infrared to infrared wavelength range of the electromagnetic spectrum.

A common method for analyzing the composition of organic substances, such as food or polymers, is to record the absorption and/or transmission of infrared or near-infrared radiation. Infrared or near-infrared radiation excites vibrational modes in the material to be analyzed, resulting in characteristic absorption bands. Due to the emission in the near-infrared to infrared wavelength range, the optoelectronic component, in particular with the phosphor described here with Cr³⁺ as activator element or with MC=Nd, can advantageously be used as a light source in a corresponding, for example small, handy and portable, analysis component or spectrometer. The optoelectronic component can be combined with a silicon detector that covers the near-infrared to infrared wavelength range and can be produced inexpensively. Advantageously, the optoelectronic component can also be used for sensor applications in portable components and industrial machines where a compact broadband infrared light source is required.

Halogen lamps are conventionally used as a broadband infrared light source. In comparison, the optoelectronic component described herein comprises significantly smaller dimensions. Furthermore, the heat development is advantageously moderate and a pulsed operating mode is possible. In addition, a broad emission spectrum of almost continuous intensity can be achieved, for example by using a mixture of several phosphors.

### BRIEF DESCRIPTION OF THE DRAWINGS

Further advantageous embodiments, configurations, and developments of the phosphor, the method for producing a phosphor, and the optoelectronic component are shown in the following exemplary embodiments illustrated in conjunction with the figures.

FIG. 1 shows a schematic view of a phosphor according to an exemplary embodiment.

FIG. 2 shows a secondary electron image of crystals of a phosphor according to an exemplary embodiment.

FIGS. 3 to 9 show schematic sections of a host structure of a phosphor according to an exemplary embodiment.

FIG. 10 shows a refined powder diffractogram of a phosphor according to an exemplary embodiment.

FIG. 11 shows an excitation spectrum and an emission spectrum of a phosphor according to an exemplary embodiment.

FIG. 12 shows emission spectra of a phosphor according to an exemplary embodiment and a comparative example.

FIG. 13 shows the temperature behavior of a phosphor according to an exemplary embodiment.

FIGS. 14, 15A, and 15B show emission spectra of a phosphor according to various exemplary embodiments.

FIG. 16 schematically shows various steps of a method for producing a phosphor according to an exemplary embodiment.

FIGS. 17 to 22 show schematic sectional views of optoelectronic components according to various exemplary embodiments.

FIGS. 23 to 25 show simulated emission spectra of optoelectronic components according to various exemplary embodiments and according to various comparative examples.

FIG. 26 shows a refined powder diffractogram of a phosphor according to an exemplary embodiment.

FIG. 27 shows an excitation spectrum and an emission spectrum of a phosphor according to an exemplary embodiment.

FIG. 28 shows emission spectra of phosphors according to an exemplary embodiment and a comparative example.

FIG. 29 shows the temperature behavior of a phosphor according to an exemplary embodiment.

FIG. 30 shows powder diffractograms of a phosphor according to an exemplary embodiment.

FIG. 31 shows an emission spectrum of a phosphor according to an exemplary embodiment.

FIGS. 32 to 36 show simulated emission spectra of optoelectronic components according to various exemplary embodiments and according to various comparative examples.

FIGS. 37A, 37B, and 37C shows a secondary electron image of crystals of a phosphor according to an exemplary embodiment.

FIG. 38 shows powder diffractograms of a phosphor according to an exemplary embodiment.

FIGS. 39A, 39B, and 40 show emission spectra of phosphors according to various exemplary embodiments.

FIG. 41 shows simulated emission spectra of optoelectronic components according to various exemplary embodiments.

FIG. 42 shows a secondary electron image of crystals of a phosphor according to an exemplary embodiment.

FIG. 43 shows powder diffractograms of a phosphor according to an exemplary embodiment.

FIGS. 44 and 45A to 45D show emission spectra of a phosphor according to an exemplary embodiment.

FIG. 46 shows a secondary electron image of crystals of a phosphor according to an exemplary embodiment.

FIG. 47 shows powder diffractograms of a phosphor according to an exemplary embodiment.

FIG. 48 shows an excitation spectrum and an emission spectrum of a phosphor according to an exemplary embodiment.

FIG. 49A shows emission spectra of phosphors according to various exemplary embodiments and a comparative example.

FIG. 49B shows emission spectra of phosphors according to various exemplary embodiments.

FIG. 50 shows the temperature behavior of a phosphor according to an exemplary embodiment and a comparative example.

FIGS. 51 to 53 show simulated emission spectra of optoelectronic components according to various exemplary embodiments and according to various comparative examples.

FIGS. 54A and 54B show emission spectra of a phosphor according to an exemplary embodiment.

FIG. 55 shows a logarithmic plot of an emission intensity of a phosphor according to an exemplary embodiment against time.

FIG. 56 shows emission spectra of phosphors according to various exemplary embodiments.

FIG. 57 shows a secondary electron image of a phosphor according to an exemplary embodiment.

FIG. 58 shows powder diffractograms of a phosphor according to an exemplary embodiment.

FIG. 59 shows emission spectra of a phosphor according to an exemplary embodiment.

FIG. 60 shows an emission spectrum and an excitation spectrum of a phosphor according to an exemplary embodiment.

FIG. 61 shows the temperature behavior of a phosphor according to an exemplary embodiment.

FIG. 62 shows simulated emission spectra of optoelectronic components according to an exemplary embodiment and according to various comparative examples.

FIG. 63 shows a secondary electron image of a phosphor according to an exemplary embodiment.

FIG. 64 shows powder diffractograms of a phosphor according to an exemplary embodiment.

FIG. 65 shows a refined powder diffractogram of a phosphor according to an exemplary embodiment.

FIG. 66 shows emission spectra of a phosphor according to an exemplary embodiment.

FIG. 67 shows an emission spectrum and excitation spectra of a phosphor according to an exemplary embodiment.

FIG. 68 shows the temperature behavior of a phosphor according to an exemplary embodiment.

FIG. 69 shows simulated emission spectra of optoelectronic components according to an exemplary embodiment of and according to various comparative examples.

FIG. 70 shows a secondary electron image of a phosphor according to an exemplary embodiment.

FIG. 71 shows powder diffractograms of a phosphor according to an exemplary embodiment.

FIGS. 72 to 75 show emission spectra of a phosphor according to an exemplary embodiment.

FIGS. 76A and 76B show secondary electron images of a phosphor according to an exemplary embodiment.

FIG. 77 shows powder diffractograms of a phosphor according to an exemplary embodiment.

FIG. 78 shows an excitation spectrum and an emission spectrum of a phosphor according to an exemplary embodiment.

FIG. 79 shows emission spectra of a phosphor according to an exemplary embodiment.

FIG. 80 shows emission spectra of a phosphor according to an exemplary embodiment and various comparative examples.

FIG. 81 shows the temperature behavior of a phosphor according to an exemplary embodiment.

FIG. 82 shows simulated emission spectra of optoelectronic components according to an exemplary embodiment and according to various comparative examples.

FIG. 83 shows a secondary electron image of a phosphor according to an exemplary embodiment.

FIG. 84 shows powder diffractograms of a phosphor according to an exemplary embodiment.

FIG. 85 shows an emission spectrum of a phosphor according to an exemplary embodiment.

FIG. 86 shows a secondary electron image of a phosphor according to an exemplary embodiment.

FIG. 87 shows powder diffractograms of a phosphor according to an exemplary embodiment.

FIG. 88 shows emission spectra of a phosphor according to various exemplary embodiments.

FIG. 89 shows simulated emission spectra of optoelectronic components according to an exemplary embodiment and according to various comparative examples.

FIG. 90 shows emission spectra of a phosphor according to various exemplary embodiments.

Elements that are identical, similar, or have the same effect are marked with the same reference signs in the figures. The figures and the proportions of the elements shown in the figures are not to be regarded as true to scale. Rather, individual elements, in particular layer thicknesses, may be shown exaggeratedly large for better visualization and/or better understanding.

### DETAILED DESCRIPTION

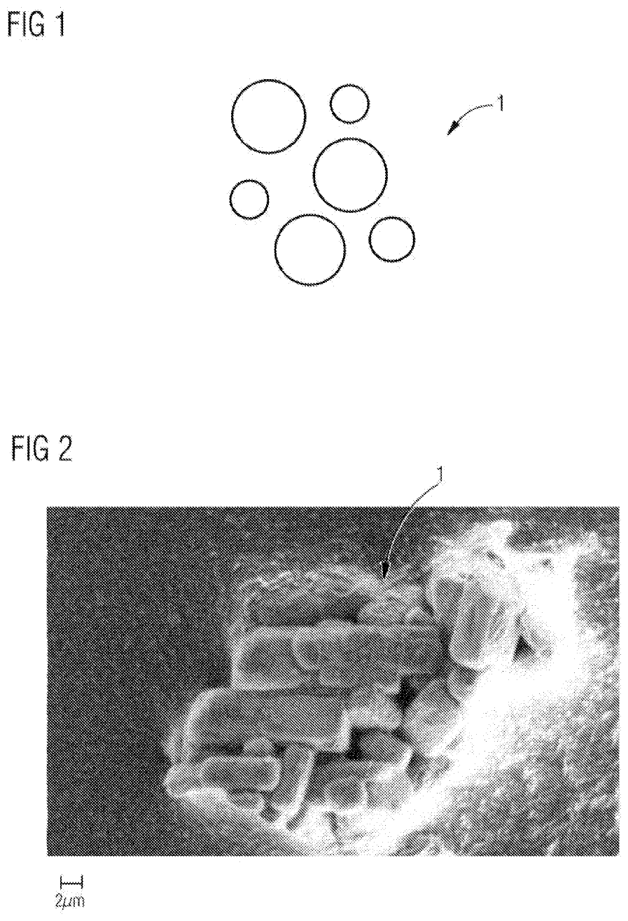

The exemplary embodiment of the phosphor 1 of FIG. 1 comprises the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, wherein 0≤x≤4, 0≤c≤1, 0≤z≤4, 0≤a≤8, 0≤b≤4, 0≤2x+a≤8, 0≤z+b≤4, −4≤−z+b−c≤4, MB is an element or a combination of elements selected from the group of divalent elements, MC is an element or a combination of elements selected from the group of trivalent elements, MA is Li and/or Na, MD is an element or a combination of elements selected from the group of tetravalent elements, ME is an element or a combination of elements selected from the group of trivalent elements, MF is an element or a combination of elements selected from the group of monovalent elements, MG is an element or a combination of elements selected from the group of pentavalent elements, and E is an activator element.

The phosphor 1 is present in the form of particles comprising a particle size in the range of between and including 500 nanometers and 50 micrometers.

FIG. 2 shows a secondary electron image of crystals of a phosphor 1 according to a further exemplary embodiment. The phosphor 1 presently comprises the molecular formula Li₈Gd[LiSi₄N₄O₈]:Ce³⁺. The secondary electron image is the result of a scanning electron microscope (SEM) examination at an acceleration voltage of 3 kV. The scale is shown at the bottom left of FIG. 2. The phosphor 1 is present as isolated, cuboid crystals.

In Table 1 crystallographic data for phosphor 1 with the molecular formula Li₈Gd[LiSi₄N₄O₈]:Ce³⁺ are summarized. The activator element Ce³⁺ was not included in the refinement due to its low concentration and low scattering contribution.

In Table 1 the measured section of the reciprocal space over the limits of the associated Miller indices (hkl) is shown. Furthermore, the conventional R-value of all reflections R₁ is given, which indicates the mean percentage deviation between observed and calculated structure factors. The weighted R-value wR₂ contains a weighting factor that weights the reflexes according to a defined scheme depending on their standard deviation, among other things. For a good structural model, R₁ should be below 5% and wR₂ below 10%. The goodness of fit (GooF), which should be close to 1, is specified as a further quality factor for the congruence between the calculated and measured structure.

TABLE 1
Crystallographic data for Li₈Gd[LiSi₄N₄O₈]:Ce³⁺

| Molecular formula | Li₈Gd[LiSi₄N₄O₈] | |
|---|---|---|
| Crystal system | tetragonal | |
| Space group | P4/n | (No. 85) |
| a/Å | 9.9322 | (8) |
| c/Å | 5.0482 | (6) |
| Cell volume/Å³ | 498.00 | (8) |
| T/K | 297 | (2) |
| Radiation/Å | Mo-Kα | (λ = 0.71073) |

| | |
|---|---|
| Measuring range | 2.9° < θ < 37.76° |
| | −17 ≤ h ≤ 16 |
| | −16 ≤ k ≤ 13 |
| | −8 ≤ l ≤ 7 |
| Number of all reflexes | 12572 |
| Independent reflexes | 1303 |
| Number of parameters | 60 |
| Δρₘₐₓ, Δρₘᵢₙ/eÅ⁻³ | 3.56/−1.47 |
| R₁ (I ≥ 2σ(I)/all) | 0.0335/0.0489 |
| wR₂ (I ≥ 2σ(I)/all) | 0.0664/0.0718 |
| GooF | 1.15 |

Table 2 shows the crystallographic position parameters of Li₈Gd[LiSi₄N₄O₈]:Ce³⁺. The Wyckoff position describes the symmetry of the point positions according to R.W.G. Wyckoff. x, y, and z indicate the atomic positions.

TABLE 2
Atomic positions of Li₈Gd[LiSi₄N₄O₈]:Ce³⁺

| | Wyckoff | | | | | Occupation |
|---|---|---|---|---|---|---|
| Atom | position | x | y | z | U_{eq} | (Occ) |
| Gd1 | 2c | 0 | 0.5 | 0.11494(6) | 0.00945(5) | 1 |
| Si1 | 8g | 0.21321(9) | 0.46576(9) | 0.6722(2) | 0.0083(2) | 1 |
| O2 | 8g | 0.7947(2) | 0.5399(2) | 0.3461(4) | 0.0099(5) | 1 |
| O1 | 8g | 0.3697(2) | 0.4403(3) | 0.7634(5) | 0.0108(5) | 1 |
| N1 | 8g | 0.1641(3) | 0.6186(3) | 0.8033(5) | 0.0105(6) | 1 |
| Li1 | 8g | 0.1609(8) | 0.2640(8) | 0.221(2) | 0.020(2) | 1 |
| Li2 | 8g | 0.3702(8) | 0.430(2) | 0.152(2) | 0.025(2) | 1 |
| Li3 | 2b | 0.5 | 0.5 | 0.5 | 0.020(3) | 1 |

The composition of phosphor 1 with the molecular formula Li₈Gd[LiSi₄N₄O₈]:Ce³⁺ determined by X-ray crystal structure analysis was confirmed by energy-dispersive X-ray analyses (SEM-EDX analyses) averaged over four measurements. The SEM-EDX analyses showed a ratio (Gd+Ce):Si of 1:4.1(5), which within the measurement error confirms the composition of phosphor 1 with the molecular formula Li₈Gd[LiSi₄N₄O₈]:Ce³⁺.

Table 3 summarizes crystallographic data for the phosphor 1 with the molecular formula Li₈Dy[LiSi₄N₄O₈]:Ce³⁺. The activator element Ce³⁺ was not included in the refinement due to its low concentration and low scattering contribution. Table 4 shows the crystallographic position parameters of Li₈Dy[LiSi₄N₄O₈]:Ce³⁺.

TABLE 3
Crystallographic data for Li₈Dy[LiSi₄N₄O₈]:Ce³⁺

| Molecular formula | Li₈Dy[LiSi₄N₄O₈] | |
|---|---|---|
| Crystal system | tetragonal | |
| Space group | P4/n | (No. 85) |
| a/Å | 9.9423 | (2) |
| c/Å | 5.0520 | (2) |
| Cell volume/Å³ | 499.39 | (2) |
| T/K | 284 | |
| Radiation/Å | Mo-Kα | (λ = 0.71073) |

| | |
|---|---|
| Measuring range | 2.9° < θ < 42.15° |
| | −18 ≤ h ≤ 18 |
| | −18 ≤ k ≤ 18 |
| | −9 ≤ l ≤ 9 |
| Number of all reflexes | 25467 |
| Independent reflexes | 1523 |
| Number of parameters | 60 |
| Δρₘₐₓ, Δρₘᵢₙ/eÅ⁻³ | 2.70/−2.38 |
| R₁ (I ≥ 2σ(I)/all) | 0.0300/0.0375 |
| wR₂ (I ≥ 2σ(I)/all) | 0.0559/0.0575 |
| GooF | 1.43 |

TABLE 4
Atomic positions of Li₈Dy[LiSi₄N₄O₈]:Ce³⁺

| | Wyckoff | | | | | Occupation |
|---|---|---|---|---|---|---|
| Atom | position | x | y | z | U_{eq} | (Occ) |
| Dy1 | 2c | 1/2 | 0 | 0.11522(4) | 0.00818(4) | 1 |
| Si1 | 8g | 0.28660(5) | 0.96575(5) | 0.6721(2) | 0.0060(2) | 1 |
| O1 | 8g | 0.1298(2) | 0.9405(2) | 0.7631(3) | 0.0084(3) | 1 |
| O2 | 8g | 0.4605(2) | 0.2051(2) | 0.3452(3) | 0.0080(3) | 1 |
| N1 | 8g | 0.6189(2) | 0.1639(2) | 0.8035(4) | 0.0092(4) | 1 |
| Li1 | 8g | 0.1597(5) | 0.7365(4) | 0.7792(2) | 0.018(2) | 1 |
| Li2 | 8g | 0.1299(5) | 0.9332(6) | 0.153(2) | 0.023(2) | 1 |
| Li3 | 2b | 0 | 0 | 1/2 | 0.016(2) | 1 |

The composition of phosphor 1 with the molecular formula Li₈Dy[LiSi₄N₄O₈]:Ce³⁺ determined by X-ray crystal structure analysis was confirmed by energy-dispersive X-ray analyses (SEM-EDX analyses) averaged over two particles at an accelerating voltage of 25 kV. The SEM-EDX analyses showed a ratio (Dy+Ce):Si of 1:4.2(1), which within the measurement error confirms the composition of phosphor 1 with the molecular formula Li₈Dy[LiSi₄N₄O₈]:Ce³⁺.

Table 5 summarizes crystallographic data for the phosphor 1 with the molecular formula Li₈Nd[LiSi₄N₄O₈]:Ce³⁺. The activator element Ce³⁺ was not included in the refinement due to its low concentration and low scattering contribution. Table 6 shows the crystallographic position parameters of Li₈Nd[LiSi₄N₄O₈]:Ce³⁺.

TABLE 5
Crystallographic data for Li₈Nd[LiSi₄N₄O₈]:Ce³⁺

| Molecular formula | Li₈Nd[LiSi₄N₄O₈] | |
|---|---|---|
| Crystal system | tetragonal | |
| Space group | P4/n | (No. 85) |
| a/Å | 9.9707 | (2) |
| c/Å | 5.1081 | (2) |
| Cell volume/Å³ | 507.82 | (2) |
| T/K | 293 | |
| Radiation/Å | Mo-Kα | (λ = 0.71073) |

| | |
|---|---|
| Measuring range | 2.89° < θ < 42.13° |
| | −18 ≤ h ≤ 18 |
| | −18 ≤ k ≤ 17 |
| | −9 ≤ l ≤ 9 |
| Number of all reflexes | 28680 |
| Independent reflexes | 1711 |
| Number of parameters | 60 |
| Δρₘₐₓ, Δρₘᵢₙ/eÅ⁻³ | 1.76/−0.81 |
| R₁ (I ≥ 2σ(I)/all) | 0.0149/0.0159 |
| wR₂ (I ≥ 2σ(I)/all) | 0.0357/0.0360 |
| GooF | 1.20 |

TABLE 6
Atomic positions of Li₈Nd[LiSi₄N₄O₈]:Ce³⁺

| | Wyckoff | | | | | Occupation |
|---|---|---|---|---|---|---|
| Atom | position | x | y | z | U_{eq} | (Occ) |
| Nd1 | 2c | 0 | 1/2 | 0.11560(2) | 0.00567(2) | 1 |
| Si1 | 8g | 0.96802(3) | 0.71438(3) | 0.67072(5) | 0.00509(5) | 1 |
| O1 | 8g | 0.94351(7) | 0.87017(6) | 0.7658(2) | 0.0074(2) | 1 |
| O2 | 8g | 0.03779(7) | 0.29086(7) | 0.3474(2) | 0.0077(2) | 1 |
| N1 | 8g | 0.87885(8) | 0.33601(8) | 0.7973(2) | 0.0078(2) | 1 |
| Li1 | 8g | 0.7375(2) | 0.8359(3) | 0.7740(6) | 0.0209(6) | 1 |
| Li2 | 8g | 0.0642(3) | 0.1298(2) | 0.1476(5) | 0.0193(6) | 1 |
| Li3 | 2b | 0 | 0 | 1/2 | 0.0134(7) | 1 |

Table 7 summarizes crystallographic data for the phosphor 1 with the molecular formula Li₈Ho[LiSi₄N₄O₈]:Ce³⁺. The activator element Ce³⁺ was not included in the refinement due to its low concentration and low scattering contribution. Table 8 shows the crystallographic position parameters of Li₈Ho[LiSi₄N₄O₈]:Ce³⁺.

TABLE 7
Crystallographic data for Li₈Ho[LiSi₄N₄O₈]:Ce³⁺

| Molecular formula | Li₈Ho[LiSi₄N₄O₈] |
|---|---|
| Crystal system | tetragonal |
| Space group | P4/n (No. 85) |
| a/Å | 9.9117(3) |
| c/Å | 5.0278(3) |
| Cell volume/Å³ | 493.94(4) |
| T/K | 173(2) |
| Radiation/Å | Mo K-L₃(λ = 0.71073) |
| Measuring range | 2.91° < θ < 38.55° |
| | −16 ≤ h ≤ 17 |
| | −12 ≤ k ≤ 17 |
| | −8 ≤ l ≤ 8 |
| Number of all reflexes | 8021 |
| Independent reflexes | 1377 |
| Number of parameters | 60 |
| Δρₘₐₓ, Δρₘᵢₙ/eÅ⁻³ | 2.12/−1.06 |
| R₁ (I ≥ 2σ(I)/all) | 0.0229/0.0262 |
| wR₂ (I ≥ 2σ(I)/all) | 0.0447/0.0459 |
| GooF | 1.10 |

TABLE 8
Atomic positions of Li₈Ho[LiSi₄N₄O₈]:Ce³⁺

| | Wyckoff | | | | | Occupation |
|---|---|---|---|---|---|---|
| Atom | position | x | y | z | U_{eq} | (Occ.) |
| Ho1 | 2c | 1/2 | 0 | 0.88559(3) | 0.00547(3) | 1 |
| Si1 | 8g | 0.28691(5) | 0.96524(5) | 0.3271(2) | 0.0044(2) | 1 |
| O1 | 8g | 0.2963(2) | 0.9606(2) | 0.6549(2) | 0.0061(3) | 1 |
| O2 | 8g | 0.1290(2) | 0.9398(2) | 0.2372(3) | 0.0063(3) | 1 |
| N1 | 8g | 0.3815(2) | 0.8351(2) | 0.1935(3) | 0.0059(3) | 1 |
| Li1 | 8g | 0.1304(4) | 0.9301(5) | 0.8495(8) | 0.016(2) | 1 |
| Li2 | 8g | 0.3410(4) | 0.7653(4) | 0.7795(8) | 0.013(2) | 1 |
| Li3 | 2b | 0 | 0 | 1/2 | 0.020(3) | 1 |

Table 9 summarizes crystallographic data for the phosphor 1 with the molecular formula Li₈Pr[LiSi₄N₄O₈]:Ce³⁺. The activator element Ce³⁺ was not included in the refinement due to its low concentration and low scattering contribution. Table 10 shows the crystallographic position parameters of Li₈Pr[LiSi₄N₄O₈]:Ce³⁺.

TABLE 9
Crystallographic data for Li₈Pr[LiSi₄N₄O₈]:Ce³⁺

| Molecular formula | Li₈Pr[LiSi₄N₄O₈] |
|---|---|
| Crystal system | tetragonal |
| Space group | P4/n (No. 85) |
| a/Å | 9.9570(3) |
| c/Å | 5.1203(2) |
| Cell volume/Å³ | 507.64(3) |
| T/K | 173(2) |
| Radiation/Å | Mo K-L₃ (λ = 0.71073) |
| Measuring range | 2.89° < θ < 39.44° |
| | −17 ≤ h ≤ 17 |
| | −17 ≤ k ≤ 17 |
| | −8 ≤ l ≤ 9 |
| Number of all reflexes | 9458 |
| Independent reflexes | 1500 |
| Number of parameters | 60 |
| Δρₘₐₓ, Δρₘᵢₙ/eÅ⁻³ | 1.45/−0.81 |
| R₁ (I ≥ 2σ(I)/all) | 0.0175/0.0200 |
| wR₂ (I ≥ 2σ(I)/all) | 0.0386/0.0397 |
| GooF | 1.08 |

TABLE 10
Atomic positions of Li₈Pr[LiSi₄N₄O₈]:Ce³⁺

| | Wyckoff | | | | | Occupation |
|---|---|---|---|---|---|---|
| Atom | position | x | y | z | U_{eq} | (Occ.) |
| Pr1 | 2c | 1/2 | 0 | 0.38435(2) | 0.00373(3) | 1 |
| Si1 | 8g | 0.28511(3) | 0.03094(3) | 0.82912(6) | 0.00356(7) | 1 |
| O1 | 8g | 0.29009(9) | 0.0368(2) | 0.1515(2) | 0.0055(2) | 1 |
| O2 | 8g | 0.12911(8) | 0.05551(9) | 0.7333(2) | 0.0051(2) | 1 |
| N1 | 8g | 0.6222(2) | 0.8364(2) | 0.7029(2) | 0.0054(2) | 1 |
| Li2 | 8g | 0.1292(3) | 0.0618(3) | 0.3521(5) | 0.0126(6) | 1 |
| Li1 | 8g | 0.1660(3) | 0.2626(3) | 0.7253(6) | 0.0137(6) | 1 |
| Li3 | 2a | 0 | 0 | 0 | 0.0105(9) | 1 |

In Table 11 crystallographic data for the phosphor 1 with the molecular formula Li₈Y[LiSi₄N₄O₈]:Ce³⁺ are summarized. The activator element Ce³⁺ was not included in the refinement due to its low concentration and low scattering contribution.

Table 12 shows the crystallographic position parameters of Li₈Y[LiSi₄N₄O₈]:Ce³⁺.

TABLE 11
Crystallographic data for Li₈Y[LiSi₄N₄O₈]:Ce³⁺

| Sum formula | Li₈Y[LiSi₄N₄O₈] |
|---|---|
| Crystal system | tetragonal |
| Space group | P4/n (No. 85) |
| a/Å | 9.9152(6) |
| c/Å | 5.0240(5) |
| Cell volume/Å³ | 493.92(6) |
| T/K | 173(2) |
| Radiation/Å | Mo K-L₃(λ = 0.71073) |
| Measuring range | 2.91° < θ < 36.39° |
| | −16 ≤ h ≤ 16 |
| | −16 ≤ k ≤ 15 |
| | −8 ≤ l ≤ 8 |
| Number of all reflexes | 15092 |
| Independent reflexes | 1063 |
| Number of parameters | 60 |
| Δρₘₐₓ, Δρₘᵢₙ/eÅ⁻³ | 0.70/−0.57 |
| R₁ (I ≥ 2σ(I)/all) | 0.0350/0.0480 |
| wR₂ (I ≥ 2σ(I)/all) | 0.0656/0.0691 |
| GooF | 1.32 |

TABLE 12
Atomic positions of Li₈Y[LiSi₄N₄O₈]:Ce³⁺

| | Wyckoff | | | | | Occupation |
|---|---|---|---|---|---|---|
| Atom | position | x | y | z | U_{eq} | Occ. |
| Y1 | 2c | 0 | 1/2 | 0.11592(8) | 0.00835(8) | 1 |
| Si1 | 8g | 0.21268(5) | 0.46483(6) | 0.6741(2) | 0.0085(2) | 1 |
| O1 | 8g | 0.2027(2) | 0.4601(2) | 0.3446(3) | 0.0104(4) | 1 |
| O2 | 8g | 0.3708(2) | 0.4387(2) | 0.7624(3) | 0.0109(4) | 1 |
| N1 | 8g | 0.1653(2) | 0.6179(2) | 0.8099(4) | 0.0106(4) | 1 |
| Li2 | 8g | 0.3705(4) | 0.4297(5) | 0.1570(9) | 0.020(2) | 1 |
| Li1 | 8g | 0.3408(4) | 0.2348(4) | 0.7819(8) | 0.017(2) | 1 |
| Li3 | 2b | 1/2 | 1/2 | 1/2 | 0.017(2) | 1 |

In Table 13 crystallographic data for the phosphor 1 with the molecular formula Li₈Tm[LiSi₄N₄O₈]:Ce³⁺ are summarized. The activator element Ce³⁺ was not included in the refinement due to its low concentration and low scattering contribution. Table 14 shows the crystallographic position parameters of Li₈Tm[LiSi₄N₄O₈]:Ce³⁺.

TABLE 13
Crystallographic data for Li₈Tm[LiSi₄N₄O₈]:Ce³⁺

| Molecular formula | Li₈Tm[LiSi₄N₄O₈] |
|---|---|
| Crystal system | tetragonal |
| Space group | P4/n (No. 85) |
| a/Å | 9.9226(3) |
| c/Å | 5.0054(3) |
| Cell volume/Å³ | 492.82(4) |
| T/K | 301 |
| Radiation/Å | Mo K-L_{2, 3} (λ = 0.71073) |
| Measuring range | 2.9° < θ < 36.32° |
| | −15 ≤ h ≤ 16 |
| | −16 ≤ k ≤ 16 |
| | −8 ≤ l ≤ 8 |
| Number of all reflexes | 18555 |
| Independent reflexes | 1143 |
| Number of parameters | 60 |
| Δρₘₐₓ, Δρₘᵢₙ/eÅ⁻³ | 1.59/−1.35 |
| R₁ (I ≥ 2σ(I)/all) | 0.0245/0.0288 |
| wR₂ (I ≥ 2σ(I)/all) | 0.0522/0.0534 |
| GooF | 1.31 |

TABLE 14
Atomic positions of Li₈Tm[LiSi₄N₄O₈]:Ce³⁺

| | Wyckoff | | | | | Occupation |
|---|---|---|---|---|---|---|
| Atom | position | x | y | z | U_{eq} | (Occ.) |
| Tm1 | 2c | 1/2 | 0 | 0.11551(5) | 0.01001(5) | 1 |
| Si1 | 8g | 0.71215(7) | 0.03583(7) | 0.6736(2) | 0.0086(2) | 1 |
| O2 | 8g | 0.7022(2) | 0.0406(2) | 0.3447(4) | 0.0110(4) | 1 |
| O1 | 8g | 0.8698(2) | 0.0616(2) | 0.7614(4) | 0.0114(4) | 1 |
| N1 | 8g | 0.6172(2) | 0.1646(2) | 0.8087(5) | 0.0109(5) | 1 |
| Li1 | 8g | 0.8427(6) | 0.2652(5) | 0.781(2) | 0.018(2) | 1 |
| Li2 | 8g | 0.8716(6) | 0.0719(7) | 0.156(2) | 0.027(2) | 1 |
| Li3 | 2b | 0 | 0 | 1/2 | 0.021(2) | 1 |

The composition of phosphor 1 with the molecular formula Li₈Tm[LiSi₄N₄O₈]:Ce³⁺ determined by X-ray crystal structure analysis was confirmed by energy-dispersive X-ray analyses (SEM-EDX analyses) at an accelerating voltage of 20 kV. The SEM-EDX analysis showed a ratio (Tm+Ce):Si of 1:4.0(1), which within the measurement error confirms the composition of phosphor 1 with the molecular formula Li₈Tm[LiSi₄N₄O₈]:Ce³⁺.

In Table 15 crystallographic data for the phosphor 1 with the molecular formula Li₈Tb[LiSi₄N₄O₈]:Ce³⁺ are summarized. The activator element Ce³⁺ was not included in the refinement due to its low concentration and low scattering contribution. Table 16 shows the crystallographic position parameters of Li₈Tb[LiSi₄N₄O₈]:Ce³⁺.

TABLE 15
Crystallographic data for Li₈Tb[LiSi₄N₄O₈]:Ce³⁺

| Molecular formula | Li₈Tb[LiSi₄N₄O₈] |
|---|---|
| Crystal system | tetragonal |
| Space group | P4/n (No. 85) |
| a/Å | 9.9441(3) |
| c/Å | 5.0353(2) |
| Cell volume/Å³ | 497.92(3) |
| T/K | 300(2) |
| Radiation/Å | Mo K-L_{2, 3} (λ = 0.71073) |
| Measuring range | 2.9° < θ < 3795° |
| | −17 ≤ h ≤ 17 |
| | −17 ≤ k ≤ 17 |
| | −8 ≤ l ≤ 8 |
| Number of all reflexes | 18134 |
| Independent reflexes | 1267 |
| Number of parameters | 60 |
| Δρₘₐₓ, Δρₘᵢₙ/eÅ⁻³ | 1.62/−0.80 |
| R₁ (I ≥ 2σ(I)/all) | 0.0137/0.0140 |
| wR₂ (I ≥ 2σ(I)/all) | 0.0329/0.0331 |
| GooF | 1.26 |

TABLE 16
Atomic positions of Li₈Tb[LiSi₄N₄O₈]:Ce³⁺

| | Wyckoff | | | | | Occupation |
|---|---|---|---|---|---|---|
| Atom | position | x | y | z | U_{eq} | (Occ. ) |
| Tb1 | 2c | 0 | 1/2 | 0.88397(2) | 0.00763(2) | 1 |
| Si1 | 8g | 0.21301(3) | 0.46526(3) | 0.32727(6) | 0.00703(6) | 1 |
| O2 | 8g | 0.20425(8) | 0.46018(8) | 0.6546(2) | 0.0091(2) | 1 |
| O1 | 8g | 0.36976(7) | 0.43978(8) | 0.2366(2) | 0.0096(5) | 1 |
| N1 | 8g | 0.11812(9) | 0.33567(9) | 0.1952(2) | 0.0099(2) | 1 |
| Li1 | 8g | 0.3409(3) | 0.2352(2) | 0.7819(6) | 0.0206(6) | 1 |
| Li2 | 8g | 0.3712(3) | 0.4326(4) | 0.849(7) | 0.0268(8) | 1 |
| Li3 | 2b | 1/2 | 1/2 | 1/2 | 0.0190(9) | 1 |

The composition of the phosphor 1 with the molecular formula Li₈Tb[LiSi₄N₄O₈]:Ce³⁺ determined by X-ray crystal structure analysis was confirmed by energy-dispersive X-ray analyses (SEM-EDX analyses) at an accelerating voltage of 20 kV. The SEM-EDX analysis showed a ratio (Tb+Ce):Si of 1:4.0(4) averaged over three particles, which confirms the composition of phosphor 1 with the molecular formula Li₈Tb[LiSi₄N₄O₈]:Ce³⁺ within the measurement error. Averaged over two positions within a single crystal, the SEM-EDX analysis at an accelerating voltage of 25 kV showed a ratio (Tb+Ce):Si of 1:3.7(1), which also confirms the composition of the phosphor 1 with the molecular formula Li₈Tb[LiSi₄N₄O₈]:Ce³⁺ within the measurement error.

In Table 17 crystallographic data for the phosphor 1 with the molecular formula Li₈Er[LiSi₄N₄O₈]:Ce³⁺ are summarized. The activator element Ce³⁺ was not included in the refinement due to its low concentration and low scattering contribution. Table 18 shows the crystallographic position parameters of Li₈Er[LiSi₄N₄O₈]:Ce³⁺.

TABLE 17
Crystallographic data for Li₈Er[LiSi₄N₄O₈]:Ce³⁺

| Molecular formula | Li₈Er[LiSi₄N₄O₈] |
|---|---|
| Crystal system | tetragonal |
| Space group | P4/n (No. 85) |
| a/Å | 9.937(2) |
| c/Å | 5.008(2) |
| Cell volume/Å³ | 494.5(2) |
| T/K | 173 |
| Radiation/Å | Mo K-L_{2, 3}(λ = 0.71073) |
| Measuring range | 2.9° < θ < 35.29° |
| | −15 ≤ h ≤ 14 |
| | −16 ≤ k ≤ 16 |
| | −8 ≤ l ≤ 6 |
| Number of all reflexes | 6664 |
| Independent reflexes | 1032 |
| Number of parameters | 60 |
| Δρₘₐₓ, Δρₘᵢₙ/eÅ⁻³ | 1.04/−1.21 |
| R₁ (I ≥ 2σ(I)/all) | 0.0382/0.0557 |
| wR₂ (I ≥ 2σ(I)/all) | 0.0757/0.0813 |
| GooF | 1.21 |

TABLE 18
Atomic positions of Li₈Er[LiSi₄N₄O₈]:Ce³⁺

| | Wyckoff | | | | | Occupation |
|---|---|---|---|---|---|---|
| Atom | position | x | y | z | U_{eq} | (Occ.) |
| He1 | 2c | 1/2 | 0 | 0.11547(9) | 0.01214(9) | 1 |
| Si1 | 8g | 0.2875(2) | 0.0358(2) | 0.6741(3) | 0.0116(3) | 1 |
| O1 | 8g | 0.2982(3) | 0.0394(3) | 0.3460(6) | 0.0123(8) | 1 |
| O2 | 8g | 0.1299(3) | 0.0626(4) | 0.7626(7) | 0.0138(9) | 1 |
| N1 | 8g | 0.3827(4) | 0.1640(4) | 0.8112(8) | 0.014(2) | 1 |
| Li1 | 8g | 0.1293(8) | 0.069(2) | 0.164(2) | 0.024(3) | 1 |
| Li2 | 8g | 0.157(2) | 0.2657(9) | 0.786(2) | 0.023(3) | 1 |
| Li3 | 2b | 0 | 0 | 1/2 | 0.023(5) | 1 |

The composition of the phosphor 1 with the molecular formula Li₈Er[LiSi₄N₄O₈]:Ce³⁺ determined by X-ray crystal structure analysis was confirmed by energy-dispersive X-ray analyses (SEM-EDX analyses) at an accelerating voltage of 20 kV. The SEM-EDX analysis showed a ratio (Er+Ce):Si of 1:4.2 (3) averaged over two particles, which confirms the composition of the phosphor 1 with the molecular formula Li₈Er[LiSi₄N₄O₈]:Ce³⁺ within the measurement error.

In Table 19 crystallographic data for the phosphor 1 with the molecular formula Li₈Lu[LiSi₄N₄O₈]:Ce³⁺ are summarized. The activator element Ce³⁺ was not included in the refinement due to its low concentration and low scattering contribution. Table 20 shows the crystallographic position parameters of Li₈Lu[LiSi₄N₄O₈]:Ce³⁺.

TABLE 19
Crystallographic data for Li₈Lu[LiSi₄N₄O₈]:Ce³⁺

| Molecular formula | Li₈Lu[LiSi₄N₄O₈] |
|---|---|
| Crystal system | tetragonal |
| Space group | P4/n (No. 85) |
| a/Å | 9.8968(4) |
| c/Å | 4.9866(3) |
| Cell volume/Å³ | 488.42(4) |
| T/K | 173(2) |
| Radiation/Å | Mo K-L_{2, 3} (λ = 0.71073) |
| Measuring range | 2.91° < θ < 37.86° |
| | −17 ≤ h ≤ 16 |
| | −17 ≤ k ≤ 16 |
| | −8 ≤ l ≤ 8 |
| Number of all reflexes | 11840 |
| Independent reflexes | 1271 |
| Number of parameters | 60 |
| Δρₘₐₓ, Δρₘᵢₙ/eÅ⁻³ | 2.88/−3.10 |
| R₁ (I ≥ 2σ(I)/all) | 0.0218/0.0239 |
| wR₂ (I ≥ 2σ(I)/all) | 0.0508/0.0517 |
| GooF | 1.30 |

TABLE 20
Atomic positions of Li₈Lu[LiSi₄N₄O₈]:Ce³⁺

| | Wyckoff | | | | | Occupation |
|---|---|---|---|---|---|---|
| Atom | position | x | y | z | U_{eq} | (Occ.) |
| Lu1 | 2c | 0 | 1/2 | 0.38521(3) | 0.00631(4) | 1 |
| Si1 | 8g | 0.21235(6) | 0.46410(6) | 0.8256(2) | 0.0046(2) | 1 |
| O2 | 8g | 0.2006(2) | 0.4595(2) | 0.1557(3) | 0.0062(3) | 1 |
| O1 | 8g | 0.3704(2) | 0.4378(2) | 0.7388(3) | 0.0064(3) | 1 |
| N1 | 8g | 0.1166(2) | 0.3357(2) | 0.6895(3) | 0.0067(3) | 1 |
| Li1 | 8g | 0.3432(4) | 0.2337(4) | 0.716(2) | 0.013(2) | 1 |
| Li2 | 8g | 0.3700(5) | 0.4299(6) | 0.348(2) | 0.020(2) | 1 |
| Li3 | 2b | 1/2 | 1/2 | 0 | 0.015(2) | 1 |

The composition of the phosphor 1 with the molecular formula Li₈Lu[LiSi₄N₄O₈]:Ce³⁺ determined by X-ray crystal structure analysis was confirmed by energy-dispersive X-ray analyses (SEM-EDX analyses) at an accelerating voltage of 25 kV. The SEM-EDX analysis showed a ratio (Lu+Ce):Si of 1:4.0(1) averaged over two particles, which confirms the composition of the phosphor 1 with the molecular formula Li₈Lu[LiSi₄N₄O₈]:Ce³⁺ within the measurement error.

In Table 21 crystallographic data for the phosphor 1 with the molecular formula Li₈Yb[LiSi₄N₄O₈]:Ce³⁺ are summarized. The activator element Ce³⁺ was not included in the refinement due to its low concentration and low scattering contribution. Table 22 shows the crystallographic position parameters of Li₈Yb[LiSi₄N₄O₈]:Ce³⁺.

TABLE 21
Crystallographic data for Li₈Yb[LiSi₄N₄O₈]:Ce³⁺

| Molecular formula | Li₈Yb[LiSi₄N₄O₈] |
|---|---|
| Crystal system | tetragonal |
| Space group | P4/n (No. 85) |
| a/Å | 9.936(2) |
| c/Å | 5.0002(8) |
| Cell volume/Å³ | 493.6(2) |
| T/K | 153(2) |
| Radiation/Å | Mo K-L_{2, 3} (λ = 0.71073) |
| Measuring range | 2.9° < θ < 33.23° |
| | −15 ≤ h ≤ 15 |
| | −15 ≤ k ≤ 13 |
| | −7 ≤ l ≤ 7 |
| Number of all reflexes | 5704 |
| Independent reflexes | 888 |
| Number of parameters | 60 |
| Δρₘₐₓ, Δρₘᵢₙ/eÅ⁻³ | 2.07/−1.38 |
| R₁ (I ≥ 2σ(I)/all) | 0.0314/0.0387 |
| wR₂ (I ≥ 2σ(I)/all) | 0.0646/0.0669 |
| GooF | 1.27 |

TABLE 22
Atomic positions of Li₈Yb[LiSi₄N₄O₈]:Ce³⁺

| | Wyckoff | | | | | Occupation |
|---|---|---|---|---|---|---|
| Atom | position | x | y | z | U_{eq} | (Occ.) |
| Yb1 | 2c | 1/2 | 0 | 0.11571(8) | 0.00993(8) | 1 |
| Si1 | 8g | 0.7126(2) | 0.0355(2) | 0.6743(2) | 0.0068(2) | 1 |
| O2 | 8g | 0.7010(3) | 0.0399(3) | 0.3455(6) | 0.0090(7) | 1 |
| O1 | 8g | 0.8700(3) | 0.0621(3) | 0.7622(6) | 0.0096(7) | 1 |
| N1 | 8g | 0.6173(3) | 0.1632(3) | 0.8093(7) | 0.0093(8) | 1 |
| Li1 | 8g | 0.8416(8) | 0.2655(7) | 0.789(2) | 0.015(2) | 1 |
| Li2 | 8g | 0.8728(9) | 0.064(2) | 0.160(2) | 0.027(3) | 1 |
| Li3 | 2b | 0 | 0 | 1/2 | 0.022(4) | 1 |

The composition of the phosphor 1 with the molecular formula Li₈Yb[LiSi₄N₄O₈]:Ce³⁺ determined by X-ray crystal structure analysis was confirmed by energy-dispersive X-ray analyses (SEM-EDX analyses) at an accelerating voltage of 25 kV. The SEM-EDX analysis showed a ratio (Yb+Ce):Si of 1:4.0(2) averaged over two particles and five measuring points, which confirms the composition of the phosphor 1 with the molecular formula Li₈Yb[LiSi₄N₄O₈]:Ce³⁺ within the measurement error.

In Table 23 crystallographic data for the phosphor 1 with the molecular formula Li₈Sm[LiSi₄N₄O₈]:Ce³⁺ are summarized. The activator element Ce³⁺ was not included in the refinement due to its low concentration and low scattering contribution. Table 24 shows the crystallographic position parameters of Li₈Sm[LiSi₄N₄O₈]:Ce³⁺.

TABLE 23
Crystallographic data for Li₈Sm[LiSi₄N₄O₈]:Ce³⁺

| Molecular formula | Li₈Sm[LiSi₄N₄O₈] |
|---|---|
| Crystal system | tetragonal |
| Space group | P4/n (No. 85) |
| a/Å | 9.9387(2) |
| c/Å | 5.0672(2) |
| Cell volume/Å³ | 500.53(2) |
| T/K | 173(2) |
| Radiation/Å | Mo K-L_{2, 3} (λ = 0.71073) |
| Measuring range | 2.9° < θ < 38.58° |
| | −17 ≤ h ≤ 17 |
| | −16 ≤ k ≤ 17 |
| | −7 ≤ l ≤ 8 |
| Number of all reflexes | 11972 |
| Independent reflexes | 1392 |
| Number of parameters | 60 |
| Δρₘₐₓ, Δρₘᵢₙ/eÅ⁻³ | 0.78/−0.82 |
| R₁ (I ≥ 2σ(I)/all) | 0.0180/0.0200 |
| wR₂ (I ≥ 2σ(I)/all) | 0.0193/0.0197 |
| GooF | 1.04 |

TABLE 24
Atomic positions of Li₈Sm[LiSi₄N₄O₈]:Ce³⁺

| | Wyckoff | | | | | Occupation |
|---|---|---|---|---|---|---|
| Atom | position | x | y | z | U_{eq} | (Occ.) |
| Sm1 | 2c | 1/2 | 0 | 0.11609(3) | 0.00382(3) | 1 |
| Si1 | 8g | 0.28588(4) | 0.96707(4) | 0.67207(8) | 0.00359(8) | 1 |
| O2 | 8g | 0.2928(2) | 0.9616(2) | 0.3469(2) | 0.0051(2) | 1 |
| O1 | 8g | 0.1295(2) | 0.9419(2) | 0.7654(2) | 0.0053(2) | 1 |
| N1 | 8g | 0.3799(2) | 0.8358(2) | 0.8018(2) | 0.0054(3) | 1 |
| Li1 | 8g | 0.1634(3) | 0.7365(3) | 0.7794(7) | 0.0133(8) | 1 |
| Li2 | 8g | 0.1297(3) | 0.9355(4) | 0.1496(6) | 0.0151(8) | 1 |
| Li3 | 2b | 0 | 0 | 1/2 | 0.011(2) | 1 |

The composition of the phosphor 1 with the molecular formula Li₈Sm[LiSi₄N₄O₈]:Ce³⁺ determined by X-ray crystal structure analysis was confirmed by energy-dispersive X-ray analyses (SEM-EDX analyses) at an accelerating voltage of 25 kV. The SEM-EDX analysis showed a ratio (Sm+Ce):Si of 1:4.0(3) averaged over four measurements, which confirms the composition of the phosphor 1 with the molecular formula Li₈Sm[LiSi₄N₄O₈]:Ce³⁺ within the measurement error.

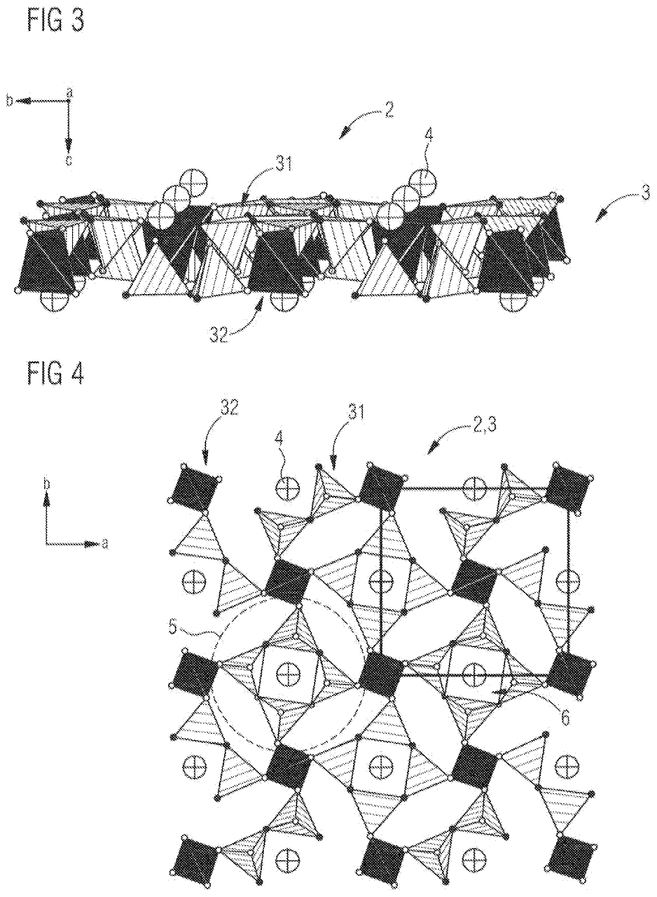

FIGS. 3 to 8 show schematic sections of a crystal structure of a host structure 2 of a phosphor 1 according to an exemplary embodiment. The phosphor 1 comprises the molecular formula Li₈MC[LiSi₄N₄O₈]:E with MC=Gd, Dy, Ho, Pr, Nd, Tm, Tb, Er, Lu, Yb, Sm, or Y and E=Ce³⁺, Eu²⁺ and/or Nd³⁺.

In FIG. 3 a section of the host structure 2 of the phosphor 1 with the molecular formula Li₈MC[LiSi₄N₄O₈]:E with MC=Gd, Dy, Ho, Pr, Nd, Tm, Tb, Er, Lu, Yb, Sm, or Y and E=Ce³⁺, Eu²⁺ and/or Nd³⁺ is shown approximately along the [1̅00] direction. The section shows a first layer 3 and MC atoms 4. The first layer 3 is composed of corner-linked SiO₂N₂ tetrahedra 31 and LiO₄ tetrahedra 32. The first layer 3 can also be referred to as a lithosilicate layer.

In FIG. 4 the first layer 3 is shown along the [001̅] direction. At the same time, the unit cell of the crystal structure of the host structure 2 is indicated with black lines. The SiO₂N₂ tetrahedra 31 form four-rings 5, which create channels 6 along the c-axis. The MC atoms 4 are located in the channels 6. The LiO₄ tetrahedra 32 are corner-linked on all sides in the first layer 3.

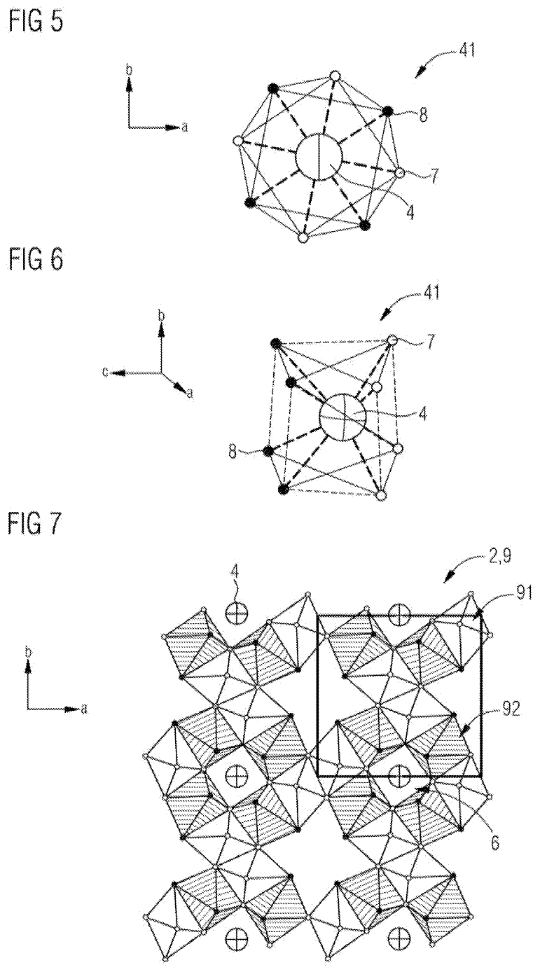

A coordination sphere of the MC atoms 4 of Li₈MC[LiSi₄N₄O₈]:E with MC=Gd, Dy, Ho, Pr, Nd, Tm, Tb, Er, Lu, Yb, Sm, or Y and E=Ce³⁺, Eu²⁺ and/or Nd³⁺ is shown in FIGS. 5 and 6 from different directions. FIG. 5 shows the coordination sphere along the [001̅] direction, whereas FIG. 6 shows the coordination sphere approximately along the [1̅00] direction. Presently, the MC atom 4 is surrounded by four O atoms 7 and four N atoms 8 in an antiprismatic square. The MC atom 4 thus comprises an eightfold coordination. At opposite corners of the square antiprism 41 around the MC atom 4, one O atom 7 and one N atom 8 are opposite each other. At the corners of the square faces of the square antiprism 41 along the c-axis there are only O atoms 7 or only N atoms 8. If the composition of the phosphor is different from Li₈MC[LiSi₄N₄O]:E, the occupation of the O atoms and/or N atom can change. It is also possible that some of the N atoms 8 are located at positions of the O atoms 7 and vice versa.

It is assumed that the activator element E, in this case Ce³⁺, can occupy the positions of the MC atoms 4 in the crystal structure of the host structure 2 according to its charge and ionic radius.

In FIG. 7 a second layer 9 of the host structure 2 of the phosphor 1 with the molecular formula Li₈MC[LiSi₄N₄O]:E with MC=Gd, Dy, Ho, Pr, Nd, Tm, Tb, Er, Lu, Yb, Sm, or Y and E=Ce³⁺, Eu²⁺ and/or Nd³⁺ is shown. The second layer 9 is shown in the ab plane, i.e. along the [001̅] direction. At the same time, the unit cell of the crystal structure of the host structure 2 is indicated with black lines.

The second layer 9 is presently composed of fivefold coordinated Li. In other words, the coordination number of Li is 5. The second layer 9 comprises trigonal LiO₃N₂ bipyramids 92 and trigonal LiO₄N bipyramids 91. The trigonal bipyramids 91, 92 can also be described as a square pyramid. Alternatively, the polyhedra around the Li atoms can also be described, for example, as distorted tetrahedral with an additional anion further away. In the alternative description of the environment of the Li atom, the coordination number of Li also remains 5.

The trigonal LiO₃N₂ bipyramids 92 and the trigonal LiO₄N bipyramids 91 are edge-linked. Furthermore, four trigonal LiO₃N₂ bipyramids 92 and four trigonal LiO₄N bipyramids 91 are arranged in such a way that the channel 6, in which the MC atoms 4 are located along the c-axis, from the first layer 3 is continued in the center.

The first layer 3 and the second layer 9 are arranged alternately in the crystal structure of the host structure 2 of the phosphor 1 with the molecular formula Li₈MC[LiSi₄N₄O]:E with MC=Gd, Dy, Ho, Pr, Nd, Tm, Tb, Er, Lu, Yb, Sm, or Y and E=Ce³⁺, Eu²⁺ and/or Nd³⁺. In other words, between two first layers 3 there is a second layer 9. The first layer 3 and the second layer 9 are linked to each other via common corners and edges. In this way, a three-dimensional network is formed. The phosphor 1 can also be referred to as lithium oxonitridolithosilicate.

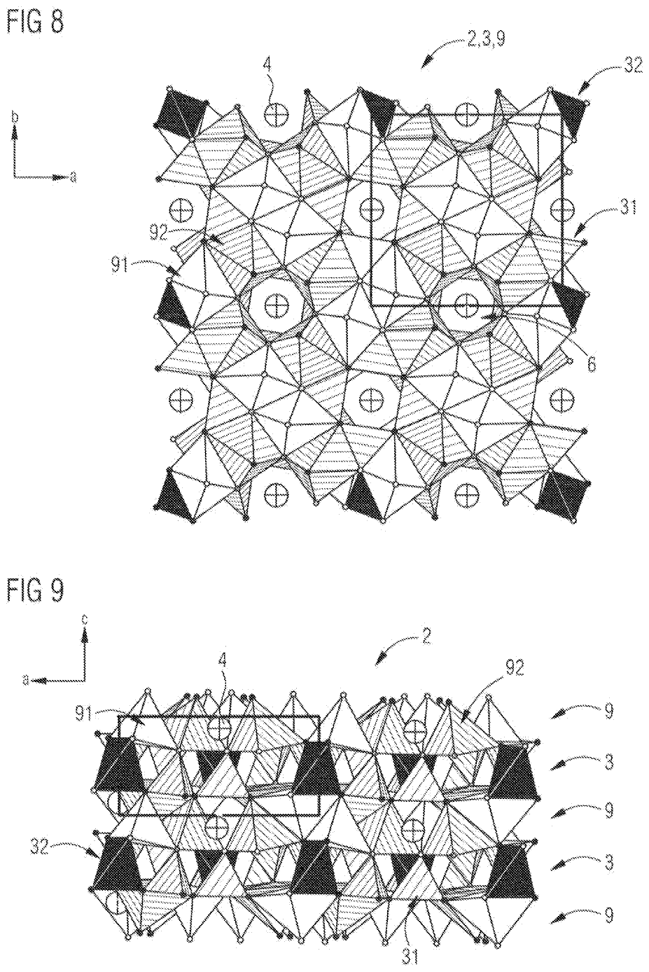

A first layer 3 and a second layer 9 along the [001̅] direction are shown in FIG. 8. FIG. 9 shows five alternating repeating layers 3, 9 along the [01̅0] direction. In FIGS. 8 and 9, the unit cell of the crystal structure of the host structure 2 is indicated with black lines.

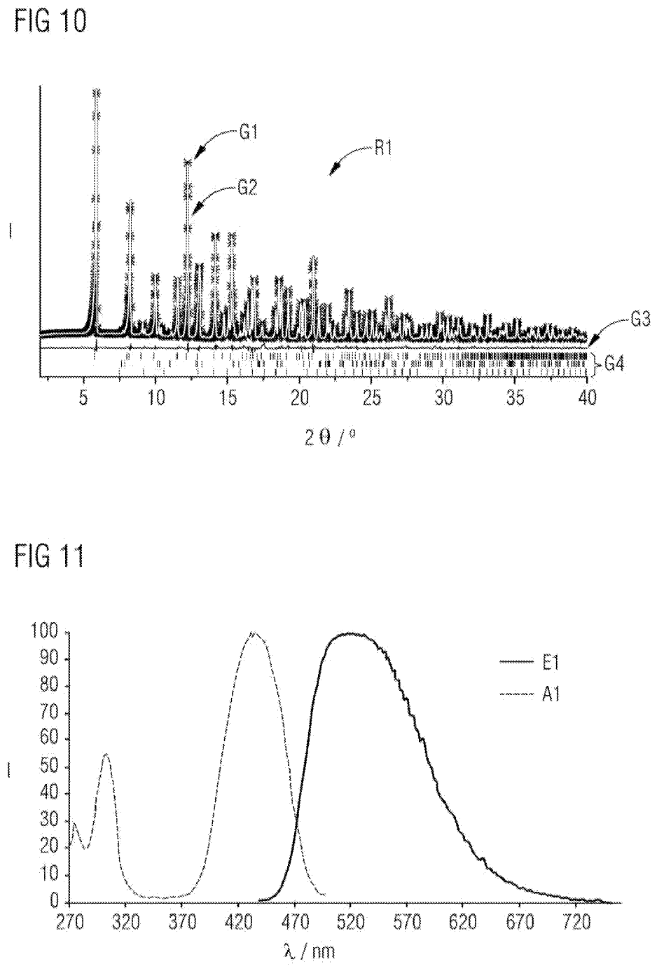

FIG. 10 shows a Rietveld-refined powder diffractogram R1 of the host structure 2 of the phosphor 1 according to the exemplary embodiment with the molecular formula Li₈Gd[LiSi₄N₄O]:Ce³⁺. The powder diffractogram was recorded with Mo-Kα₁ radiation. The relative intensity I is plotted in arbitrary units against the diffraction angle 2θ in degrees. The crosses of the powder diffractogram show the measured values G1. The white solid line with a black border shows a calculated powder diffractogram G2. The line G3 is the difference between the values of curve G2 and curve G1. In other words, it is a difference diagram G3. The black markings G4 correspond to the theoretical reflection positions for Li₈Gd[LiSi₄N₄O₈](top), Li₄SiO₄ (middle) and Gd₂O₃ (bottom). The theoretical reflection positions for Li₈Gd[LiSi₄N₄O₈] were calculated using the previously described crystal structure of the host structure 2 of the phosphor with the molecular formula Li₈Gd[LiSi₄N₄O]:Ce³⁺.

The results of the Rietveld refinement are summarized in Table 25. The Rietveld refinement shows that the powder sample contains in addition to phosphor 1 with the molecular formula Li₈Gd[LiSi₄N₄O₈]:Ce³⁺Li₄SiO₄ and Gd₂O₃. However, only in small proportions.

TABLE 25
Results of the Rietveld refinement of
a powder sample of Li₈Gd[LiSi₄N₄O₈]

| Composition | |
|---|---|
| Li₈Gd[LiSi₄N₄O₈]/wt % | 79.1(4) |
| Li₄SiO₄/wt % | 17.1(5) |
| Gd₂O₃/wt % | 3.8(4) |
| Crystallographic data | |
| Diffractometer | STOE STADI P |
| Radiation; wavelength/Å | Mo—Kα₁; 0.7093 |
| a/Å | 9.9876(2) |
| c/Å | 5.07508(7) |
| Cell volume/Å³ | 506.25(2) |
| 2 θ Range/° | 2-40.085 |
| 2 θ increment/° | 0.015 |
| Rₑₓₚ/% | 0.94 |
| R_{wp}/% | 4.87 |
| Rₚ/% | 3.03 |
| R_{Bragg}/% | 1.511 |

Due to the activator element E, the exemplary embodiment of the phosphor 1 with the molecular formula Li₈Gd[LiSi₄N₄O₈]:Ce³⁺ comprises phosphor properties. An excitation spectrum A1 and an emission spectrum E1 of a powder sample of phosphor 1 with the molecular formula Li₈Gd[LiSi₄N₄O₈]:Ce³⁺ are shown in FIG. 11. The excitation spectrum A1 is based on the raw data maximum of the emission curve, which is located at about 510 nanometers. The emission spectrum E1 was recorded at an excitation wavelength of 430 nanometers. The phosphor 1 with the molecular formula Li₈Gd[LiSi₄N₄O₈]:Ce³⁺ comprises an emission maximum λₘₐₓ at about 517 nanometers. Further optical data of phosphor 1 with the molecular formula Li₈Gd[LiSi₄N₄O]:Ce³⁺ are summarized in Table 26.

TABLE 26
Optical data for a powder sample of Li₈Gd[LiSi₄N₄O₈]:Ce³⁺.

| | Li₈Gd[LiSi₄N₄O₈]:Ce³⁺ |
|---|---|
| LER/lm W_{opt.}⁻¹ | 436.2 |
| λₘₐₓ/nm | 517.4 |
| λ_{dom}/nm | 551.8 |
| λ_{centroid}/nm | 544.5 |
| FWHM/nm | 112.3 |
| CIE-x | 0.322(1) |
| CIE-y | 0.548(1) |

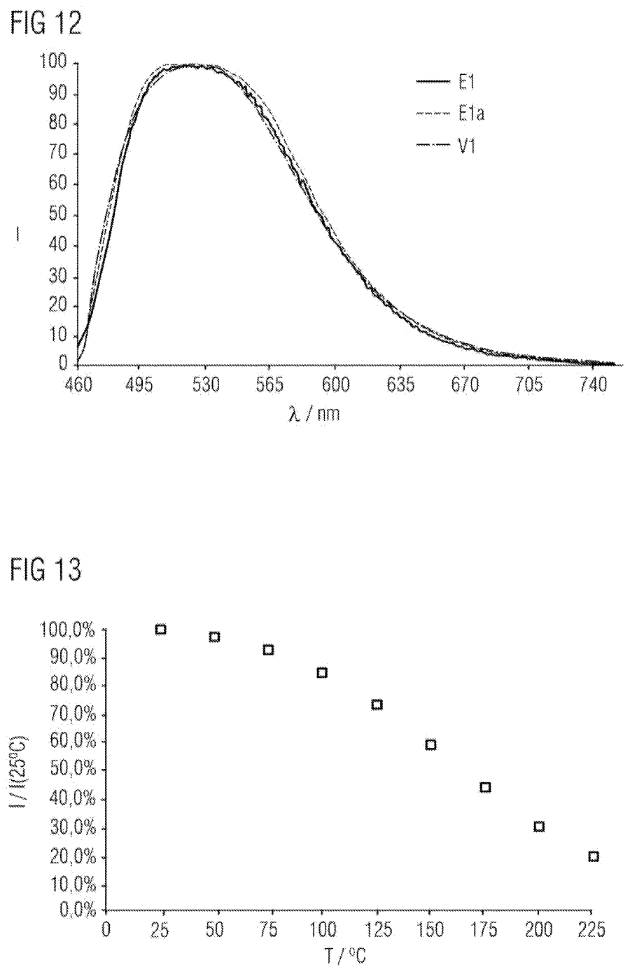

FIG. 12 shows emission spectra E1, Ela, and V1 of phosphors 1. The emission spectrum E1 for a powder sample of the exemplary embodiment of the phosphor 1 with the molecular formula Li₈Gd[LiSi₄N₄O₈]:Ce³⁺ was recorded at an excitation wavelength of 430 nanometers. The emission spectrum Ela for a single crystal of the exemplary embodiment of the phosphor 1 with the molecular formula Li₈Gd[LiSi₄N₄O₈]:Ce³⁺ was recorded at an excitation wavelength of 448 nanometers. The emission spectrum V1 of a comparative example of a phosphor 1 with the molecular formula Lu₃(Al/Ga)₅O₁₂:Ce³⁺ was recorded at an excitation wavelength of 448 nanometers. The emission spectra show that the emissions of Li₈Gd[LiSi₄N₄O₈]:Ce³⁺ and Lu₃(Al/Ga)₅O₁₂:Ce³⁺ are spectrally comparable. However, phosphor 1 comprises an improved photometric radiation equivalent (LER). Due to the similar emission of Li₈Gd[LiSi₄N₄O₈]:Ce³⁺ and Lu₃(Al/Ga)₅O₁₂:Ce³⁺, Lu₃(Al/Ga)₅O₁₂:Ce³⁺ can be replaced by Li₈Gd[LiSi₄N₄O₈]:Ce³⁺ in conventional optoelectronic components.

Furthermore, it can be seen from FIG. 12 that the emission of the single crystal of Li₈Gd[LiSi₄N₄O₈]:Ce³⁺ is representative of the powder sample of Li₃Gd[LiSi₄N₄O₈]:Ce³⁺. Selected optical data of Li₈Gd[LiSi₄N₄O₈]:Ce³⁺ and Lu₃(Al/Ga)₅O₁₂:Ce³⁺ are summarized in Table 27.

TABLE 27
Comparison of the optical data of
Li₈Gd[LiSi₄N₄O₈]:Ce³⁺ and Lu₃(Al/Ga)₅O₁₂:Ce³⁺.

| | Li₈Gd[LiSi₄N₄O₈]:Ce³⁺ | Lu₃(Al/Ga)₅O₁₂:Ce³⁺ |
|---|---|---|
| LER/lm W_{opt.}⁻¹ | 434 (+2%) | 427 |
| λₘₐₓ/nm | 516.5 | 523.4 |
| λ_{dom}/nm | 552.6 | 551.4 |
| FWHM/nm | 116.2 | 114.6 |
| CIE-x | 0.325(1) | 0.320(1) |
| CIE-y | 0.547(1) | 0.543(1) |

The temperature behavior of the exemplary embodiment of phosphor 1 with the molecular formula Li₈Gd[LiSi₄N₄O₈]:Ce³⁺ is shown in FIG. 13. On the x-axis the temperature T in ° C. and on the y-axis the quotient of the integral intensity of the emission at the current temperature and that at 25° C. is shown. The step size is 25° C. The maximum temperature is 225° C. The phosphor 1 with the molecular formula Li₈Gd[LiSi₄N₄O₈]:Ce³⁺ shows a decrease in emission intensity with increasing temperature. However, at a temperature of about 100° C., which corresponds to a typical operating temperature of optoelectronic components, the relative emission intensity is still about 85%.

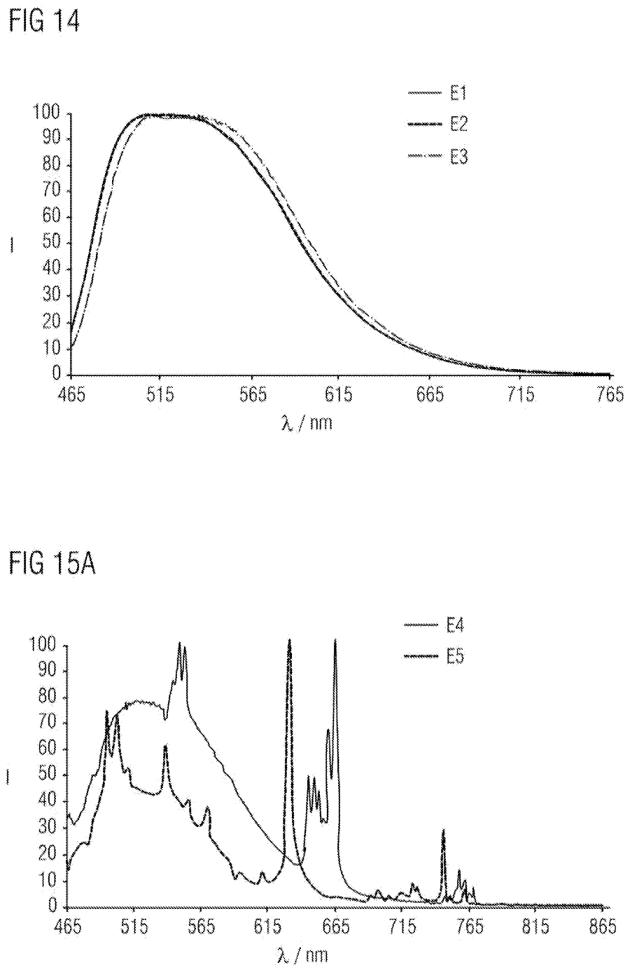

FIG. 14 shows emission spectra E1 to E3 of phosphors 1 according to various exemplary embodiments with the molecular formula Li₈MC[LiSi₄N₄O₈]:Ce³⁺ in a range of between and including 465 nanometers and 765 nanometers. The phosphors 1 were excited with a wavelength of 448 nanometers. For the phosphor 1, on which the emission spectrum E1 is based, is MC=Gd. For the phosphor 1, on which the emission spectrum E2 is based, is MC=Dy. For the phosphor 1, on which emission spectrum E3 is based, is MC=Y.

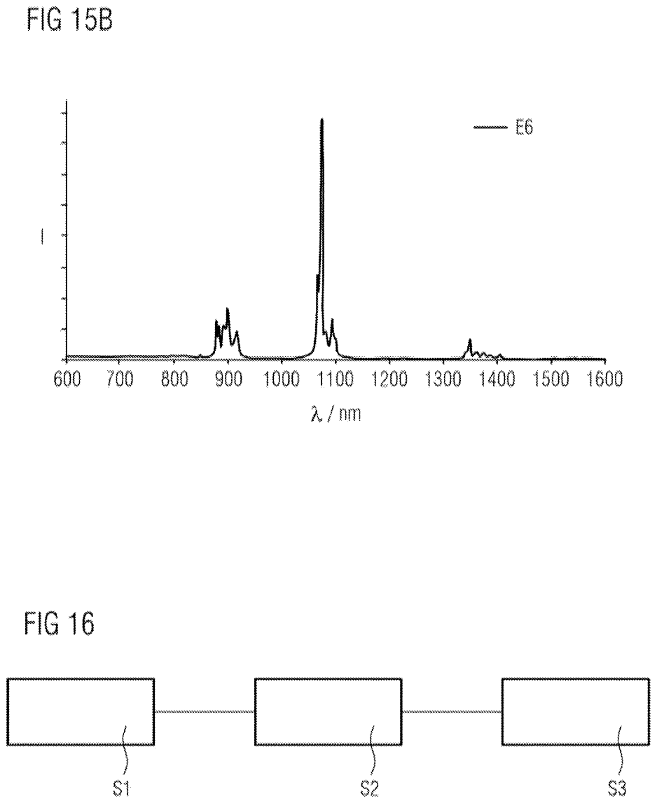

FIG. 15A shows emission spectra E4 and E5 of phosphors 1 according to various exemplary embodiments with the molecular formula Li₈MC[LiSi₄N₄O₈]:Ce³⁺ in a range of between and including 465 nanometers and 865 nanometers. The phosphors 1 were excited with a wavelength of 448 nanometers. In the case of the phosphor 1, on which the emission spectrum E4 is based, is MC=Ho. For the phosphor 1, on which emission spectrum E5 is based, is MC=Pr.

FIG. 15B shows an emission spectrum E6 of a phosphor 1 according to an exemplary embodiment with the molecular formula Li₈MC[LiSi₄N₄O₈]:Ce³⁺ in a range of between and including 600 nanometers and 1600 nanometers. Presently, the phosphor 1 was excited with a wavelength of 450 nanometers. For the phosphor 1, on which the emission spectrum E6 is based, is MC=Nd.

The emission spectra E2 to E6 are based on raw products of the respective phosphor 1 possibly with impurities. In the case of MC=Ho, Pr, and Nd, the activator element Ce³⁺ can act as a sensitizer. This results in the additional emission peaks in the emission spectra E4 to E6 in FIGS. 15A and 15B compared to the emission spectra E1 to E3 in FIG. 14.

The additional emission peaks are caused by f→f transitions of MC.

The phosphors 1 with MC=Ho and Pr comprise an emission in the green to yellow range of the electromagnetic spectrum as well as in the orange to red range of the electromagnetic spectrum. The phosphor with the molecular formula Li₈Nd[LiSi₄N₄O₈]:Ce³⁺ shows almost no emission in the green to yellow range of the electromagnetic spectrum. For Li₈Nd[LiSi₄N₄O₈]:Ce³⁺, emission is mainly observed in the infrared region of the electromagnetic spectrum.

FIG. 16 schematically shows various steps of a method for producing a phosphor 1. In a first method step S1, reactants are provided. The reactants comprise, for example, for synthesizing the phosphor 1 with the molecular formula Li₈Gd[LiSi₄N₄O]:Ce³⁺Si, Si₃N₄, Li₂SiN₂, SiO₂, Li₂O, Li₃N, LiN₃, LiF, Gd, Gd₂O₃, GdF₃, Ce, CeO₂, CeF₃, and/or CeN. For example, the reactants comprise for the synthesis of the phosphor 1 with the molecular formula Li₈Dy[LiSi₄N₄O₈]:Ce³⁺Si, Si₃N₄, Li₂SiN₂, SiO₂, Li₂O, Li₃N, LiN₃, LiF, Dy, Dy₂O₃, DyF₃, Ce, CeO₂, CeF₃, and/or CeN. For the synthesis of the phosphor 1 with the molecular formula Li₈Ho[LiSi₄N₄O₈]:Ce³⁺, the reactants comprise, for example, Si, Si₃N₄, Li₂SiN₂, SiO₂, Li₂O, Li₃N, LiN₃, LiF, Ho, Ho₂O₃, HoF₃, Ce, CeO₂, CeF₃, and/or CeN. The reactants comprise, for example, for synthesizing the phosphor 1 with the molecular formula Li₈Pr[LiSi₄N₄O₈]:Ce³⁺Si, Si₃N₄, Li₂SiN₂, SiO₂, Li₂O, Li₃N, LiN₃, LiF, Pr, Pr₂O₃, Pr₆O₁₁, PrF₃, Ce, CeO₂, CeF₃ and/or CeN. The reactants comprise, for example, for synthesizing the phosphor 1 with the molecular formula Li₈Nd[LiSi₄N₄O₈]:Ce³⁺Si, Si₃N₄, Li₂SiN₂, SiO₂, Li₂O, Li₃N, LiN₃, LiF, Nd, Nd₂O₃, NdF₃, Ce, CeO₂, CeF₃, and/or CeN. For the synthesis of the phosphor 1 with the molecular formula Li₈Y[LiSi₄N₄O₈]:Ce³⁺, the reactants comprise, for example, Si, Si₃N₄, Li₂SiN₂, SiO₂, Li₂O, Li₃N, LiN₃, LiF, Y, Y₂O₃, YF₃, Ce, CeO₂, CeF₃, and/or CeN. The reactants comprise, for example, for synthesizing the phosphor 1 with the molecular formula Li₈Gd[LiSi₄N₄O₈]:Ce³⁺,Nd³⁺Si, Si₃N₄, Li₂SiN₂, SiO₂, Li₂O, Li₃N, LiN₃, LiF, Gd₂O₈, GdF₃, Ce, CeO₂, CeF₃, CeN, NdF₃, and/or Nd₂O₃. The reactants comprise, for example, for the synthesis of the phosphor 1 with the molecular formula Li₈Tm[LiSi₄N₄O]:Ce³⁺Si, Si₃N₄, Li₂SiN₂, SiO₂, Li₂O, Li₃N, LiN₃, LiF, Tm, Tm₂O₃, TmF₃, Ce, CeO₂, CeF₃, and/or CeN. The reactants comprise, for example, for synthesizing the phosphor 1 with the molecular formula Li₈Tb[LiSi₄N₄O]:Ce³⁺Si, Si₃N₄, Li₂SiN₂, SiO₂, Li₂O, Li₃N, LiN₃, LiF, Tb, Tb₂O₃, TbF₃, Ce, CeO₂, CeF₃, and/or CeN. For the synthesis of the phosphor 1 with the molecular formula Li₈Er[LiSi₄N₄O₈]:Ce³⁺, the reactants comprise, for example, Si, Si₃N₄, Li₂SiN₂, SiO₂, Li₂O, Li₃N, LiN₃, LiF, Er, Er₂O₃, ErF₃, Ce, CeO₂, CeF₃, and/or CeN. The reactants comprise, for example, for synthesizing the phosphor 1 with the molecular formula Li₈Lu[LiSi₄N₄O]:Ce³⁺Si, Si₃N₄, Li₂SiN₂, SiO₂, Li₂O, Li₃N, LiN₃, LiF, Lu, Lu₂O₃, LuN, LuF₃, Ce, CeO₂, CeF₃, and/or CeN. The reactants comprise, for example, for synthesizing the phosphor 1 with the molecular formula Li₈Yb[LiSi₄N₄O₈]:Ce³⁺Si, Si₃N₄, Li₂SiN₂, SiO₂, Li₂O, Li₃N, LiN₃, LiF, Yb, Yb₂O₃, YbF₃, Ce, CeO₂, CeF₃, and/or CeN. For the synthesis of the phosphor 1 with the molecular formula Li₈Sm[LiSi₄N₄O₈]:Ce³⁺, the reactants comprise, for example, Si, Si₃N₄, Li₂SiN₂, SiO₂, Li₂O, Li₃N, LiN₃, LiF, Sm, Sm₂O₃, SmF₃, Ce, CeO₂, CeF₃, and/or CeN. For the synthesis of phosphor 1 with the molecular formula Li₈Y[LiSi₄N₄O₈]:Eu²⁺, for example, the reactants comprise Eu²⁺Si, Si₃N₄, Li₂SiN₂, SiO₂, Li₂O, Li₃N, LiN₃, LiF, Y, Y₂O₃, YF₃, EuF₂.

The reactants are mixed in a second method step S2 to form a mixture of reactants. In addition to the reactants, the reactant mixture can also contain a flux, for example with up to 5% by weight based on the weight of the reactants used. The reactant mixture is transferred to a W-crucible, Ni-crucible, or a Ta-tube.

In a third method step S3, the reactant mixture is heated in a flow tube furnace, a high-frequency furnace, or in a tube furnace. Heating is carried out to a first temperature of at least 920° C. This temperature is maintained for a period of between and including 4 hours and 20 hours. It is then cooled to a second temperature of less than 600° C. with a cooling rate of no more than 6° C./h. This is followed by cooling with a cooling rate of less than 20° C./h to a third temperature of less than 200° C. The oven is then switched off.

Production of Li₈Gd[LiSi₄N₄O₈]:Ce³⁺

The phosphor 1 with the molecular formula Li₈Gd[LiSi₄N₄O₈]:Ce³⁺ is produced from the reactants Si₃N₄, SiO₂, Li₂O, and Gd₂O₃ in the molar ratio 2:2:10.5:1, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Gd. The exact weights for producing Li₈Gd[LiSi₄N₄O₈]:Ce³⁺ are summarized in Table 28.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled to a second temperature of about 500° C. with a cooling rate of about 2° C./h. In a second cooling step, the material is cooled with a cooling rate of about 18° C./h to a third temperature of about 150° C. and the furnace is then switched off.

TABLE 28
Weights for the synthesis of Li₈Gd[LiSi₄N₄O₈]:Ce³⁺.

| Reactant | Quantity | |
|---|---|---|
| Si₃N₄ | 25.89 mg | (0.185 mmol) |
| SiO₂ | 11.09 mg | (0.185 mmol) |
| Li₂O | 28.95 mg | (0.969 mmol) |
| Gd₂O₃ | 33.44 mg | (0.092 mmol) |
| CeF₃ | 0.64 mg | (0.003 mmol) |

Production of Li₈Gd[LiSi₄N₄O₈]:Ce³⁺,Nd³⁺

The phosphor 1 with the molecular formula Li₈Gd[LiSi₄N₄O₈]:Ce³⁺,Nd³⁺ is produced from the reactants Si₃N₄, SiO₂, Li₂O, and Gd₂O₃ in the molar ratio 2:2:10.5:0.9, possibly a flux such as LiF or Li with up to 5 wt. % and with CeF₃ and NdF₃ as reactants for the activator elements Ce³⁺ and Nd³⁺. The exact weights for producing Li₈Gd[LiSi₄N₄O₈]:Ce³⁺,Nd³⁺ are summarized in Table 29. The synthesis was carried out as described for Li₈Gd[LiSi₄N₄O₈]:Ce³⁺,Nd³⁺.

TABLE 29
Weights for the synthesis of Li₈Gd[LiSi₄N₄O₈]:Ce³⁺, Nd³⁺

| Reactant | Quantity | |
|---|---|---|
| Si₃N₄ | 25.96 mg | (0.185 mmol) |
| SiO₂ | 11.12 mg | (0.185 mmol) |
| Li₂O | 29.04 mg | (0.972 mmol) |
| Gd₂O₃ | 30.19 mg | (0.083 mmol) |
| CeF₃ | 1.82 mg | (0.009 mmol) |
| NdF₃ | 1.86 mg | (0.009 mmol) |

Production of Li₈Dy[LiSi₄N₄O₈]:Ce³⁺

The phosphor 1 with the molecular formula Li₈Dy[LiSi₄N₄O₈]:Ce³⁺ is produced from the reactants Si₃N₄, SiO₂, Li₂O, and DyF₃ in the molar ratio 2:2:10.5:1, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Dy. The exact weights for producing Li₈Dy[LiSi₄N₄O₈]:Ce³⁺ are summarized in Table 30.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled to a second temperature of about 500° C. with a cooling rate of about 2° C./h. In a second cooling step, the material is cooled with a cooling rate of about 18° C./h to a third temperature of about 150° C. and the furnace is then switched off.

TABLE 30
Weights for the synthesis of Li₈Dy[LiSi₄N₄O₈]:Ce³⁺.

| Reactant | Quantity | |
|---|---|---|
| Si₃N₄ | 29.79 mg | (0.212 mmol) |
| SiO₂ | 12.76 mg | (0.212 mmol) |
| Li₂O | 33.31 mg | (1.115 mmol) |
| DyF₃ | 23.30 mg | (0.106 mmol) |
| CeF₃ | 0.84 mg | (0.004 mmol) |

Production of Li₃Ho[LiSi₄N₄O₈]:Ce³⁺

The phosphor 1 with the molecular formula Li₈Ho[LiSi₄N₄O₈]:Ce³⁺ is produced from the reactants Si₃N₄, SiO₂, Li₂O, and HoF₃ in the molar ratio 2:2:10.5:1, possibly a flux such as LiF or Li with up to 5% by weight and with CeF₃ as the reactant for the activator element Ce³⁺. The activator element Ce³⁺ comprises a content in the range of between and including 0.01 mol % and 10 mol %, in particular in the range of between and including 0.1 mol % and 5 mol % with respect to Ho. The exact weights for producing Li₈Ho[LiSi₄N₄O₈]:Ce³⁺ are summarized in Table 31.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. It is then cooled to a second temperature of about 500° C. with a cooling rate of about 2° C./h or about 1° C./h. In a second cooling step, cooling takes place with a cooling rate of about 18° C./h to a third temperature of about 150° C. and the oven is then switched off.

TABLE 31
Weights for the synthesis of Li₈Ho[LiSi₄N₄O₈]:Ce³⁺.

| Reactant | Quantity |
|---|---|
| Si₃N₄ | 29.71 mg (0.212 mmol) |
| SiO₂ | 12.73 mg (0.212 mmol) |
| Li₂O | 33.23 mg (1.112 mmol) |
| HoF₃ | 23.50 mg (0.106 mmol) |
| CeF₃ | 0.83 mg (0.004 mmol) |

Production of Li₈Pr[LiSi₄N₄O₈]:Ce³⁺

The phosphor 1 with the molecular formula Li₈Pr[LiSi₄N₄O₈]:Ce³⁺ is produced from the reactants Si₃N₄, SiO₂, Li₂O, and Pr₆O₁₁ in the molar ratio 2:2:10.5:0.3, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Pr. The exact weights for producing Li₈Pr[LiSi₄N₄O₈]:Ce³⁺ are summarized in Table 32.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C. and this temperature is maintained for around 12 hours. It is then cooled to a second temperature of about 500° C. with a cooling rate of about 2° C./h or about 1° C./h. In a second cooling step, cooling takes place with a cooling rate of about 18° C./h to a third temperature of about 150° C. and the oven is then switched off.

TABLE 32
Weights for the synthesis of Li₉Pr[LiSi₄N₄O₈]:Ce³⁺.

| Reactat | Quantity |
|---|---|
| Si₃N₄ | 26.46 mg (0.189 mmol) |
| SiO₂ | 11.33 mg (0.189 mmol) |
| Li₂O | 29.59 mg (0.990 mmol) |
| Pr₆O₁₁ | 28.90 mg (0.028 mmol) |
| CeF₃ | 3.72 mg (0.019 mmol) |

Production of Li₃Nd[LiSi₄N₄O]:Ce³⁺

The phosphor 1 with the molecular formula Li₈Nd[LiSi₄N₄O₈]:Ce³⁺ is produced from the reactants Si₃N₄, SiO₂, Li₂O, and Nd₂O₃ in the molar ratio 2:2:10.5:0.9, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Nd. The exact weights for producing Li₈Nd[LiSi₄N₄O₈]:Ce³⁺ are summarized in Table 33.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C. and this temperature is maintained for around 12 hours. The material is then cooled to a second temperature of around 500° C. with a cooling rate of around 2° C./h. In a second cooling step, the material is cooled with a cooling rate of about 18° C./h to a third temperature of about 150° C. and the furnace is then switched off.

TABLE 33
Weights for the synthesis of Li₈Nd[LiSi₄N₄O₈]:Ce³⁺.

| Reactant | Quantity |
|---|---|
| Si₃N₄ | 26.55 mg (0.189 mmol) |
| SiO₂ | 11.37 mg (0.189 mmol) |
| Li₂O | 29.69 mg (0.994 mmol) |
| Nd₂O₃ | 28.66 mg (0.085 mmol) |
| CeF₃ | 3.73 mg (0.019 mmol) |

Production of Li₈Y[LiSi₄N₄O₈]:Ce³⁺

The phosphor 1 with the molecular formula Li₈Y[LiSi₄N₄O₈]:Ce³⁺ is produced from the reactants Si₃N₄, SiO₂, Li₂O, and Y₂O₃ in the molar ratio 2:2:10.5:0.9, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Y. The exact weights for producing Li₈Y[LiSi₄N₄O₈]:Ce³⁺ are summarized in Table 34.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled to a second temperature of around 500° C. with a cooling rate of around 2° C./h. In a second cooling step, the material is cooled with a cooling rate of about 18° C./h to a third temperature of about 150° C. and the furnace is then switched off.

TABLE 34
Weights for the synthesis of Li₈Y[LiSi₄N₄O₈]:Ce³⁺.

| Reactant | Quantity |
|---|---|
| Si₃N₄ | 27.78 mg (0.198 mmol) |
| SiO₂ | 11.90 mg (0.198 mmol) |
| Li₂O | 35.50 mg (1.188 mmol) |
| Y₂O₃ | 20.92 mg (0.089 mmol) |
| CeF₃ | 3.9 mg (0.020 mmol) |

Production of Li₈Tm[LiSi₄N₄O₈]:Ce³⁺

The phosphor 1 with the molecular formula Li₈Tm[LiSi₄N₄O₈]:Ce³⁺ is produced from the reactants Si₃N₄, SiO₂, Li₂O, and Tm₂O₃ in the molar ratio 2:2:10.5:0.9, possibly a flux such as LiF or Li with up to 5% by weight and with CeF₃ as reactant for the activator element Ce³⁺. The activator element Ce³⁺ comprises a content in the range of between and including 0.01 mol % and 15 mol %, in particular in the range of between and including 0.1 mol % and 10 mol % with respect to Tm. The exact weights for producing Li₈Tm[LiSi₄N₄O₈]:Ce³⁺ are summarized in Table 35.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled to a second temperature of around 500° C. with a cooling rate of around 2° C./h. In a second cooling step, the material is cooled with a cooling rate of about 18° C./h to a third temperature of about 150° C. and the furnace is then switched off.

TABLE 35
Weights for the synthesis of Li₈Tm[LiSi₄N₄O₈]:Ce³⁺

| Reactant | Quantity |
|---|---|
| Si₃N₄ | 25.48 mg (0.182 mmol) |
| SiO₂ | 10.91 mg (0.182 mmol) |
| Li₂O | 28.49 mg (0.954 mmol) |
| Tm₂O₃ | 31.54 mg (0.082 mmol) |
| CeF₃ | 3.58 mg (0.018 mmol) |

Production of Li₃Tb[LiSi₄N₄O]:Ce³⁺

The phosphor 1 with the molecular formula Li₈Tb[LiSi₄N₄O₈]:Ce³⁺ is produced from the reactants Si₃N₄, SiO₂, Li₂O, and Tb₂O₃ in the molar ratio 2:2:10.5:0.9, possibly a flux such as LiF or Li with up to 5% by weight and with CeF₃ as reactant for the activator element Ce³⁺. The activator element Ce³⁺ comprises a content in the range of between and including 0.01 mol % and 10 mol %, in particular in the range of between and including 0.1 mol % and 5 mol % with respect to Tb. The exact weights for producing Li₈Tb[LiSi₄N₄O₈]:Ce³⁺ are summarized in Table 36.

Prior to synthesis, the reactants are intimately mixed in a glovebox under an inert gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled to a second temperature of around 500° C. with a cooling rate of around 2° C./h. In a second cooling step, the material is cooled with a cooling rate of about 18° C./h to a third temperature of about 150° C. and the furnace is then switched off.

TABLE 36
Weights for the synthesis of Li₈Tb[LiSi₄N₄O₈]:Ce³⁺

| Reactant | Quantity |
|---|---|
| Si₃N₄ | 25.90 mg (0.185 mmol) |
| SiO₂ | 11.09 mg (0.185 mmol) |
| Li₂O | 28.97 mg (0.969 mmol) |
| Tb₂O₃ | 30.40 mg (0.083 mmol) |
| CeF₃ | 3.64 mg (0.018 mmol) |

Production of Li₈Er[LiSi₄N₄O₈]:Ce³⁺

The phosphor 1 with the molecular formula Li₈Er[LiSi₄N₄O₈]:Ce³⁺ is produced from the reactants Si₃N₄, SiO₂, Li₂O, and Er₂O₃ in the molar ratio 2:2:10.5:0.9, possibly a flux such as LiF or Li with up to 5% by weight and with CeF₃ as reactant for the activator element Ce³⁺. The activator element Ce³⁺ comprises a content in the range of between and including 0.01 mol % and 15 mol %, in particular in the range of between and including 0.1 mol % and 5 mol % with respect to Er. The exact weights for producing Li₈Er[LiSi₄N₄O₈]:Ce³⁺ are summarized in Table 37.

Prior to synthesis, the reactants are intimately mixed in a glovebox under an inert gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. The material is then cooled with a cooling rate of about 2° C./h to a second temperature of about 500° C. In a second cooling step, the material is cooled with a cooling rate of about 18° C./h to a third temperature of about 150° C. and the furnace is then switched off.

TABLE 37
Weights for the synthesis of Li₈Er[LiSi₄N₄O₈]:Ce³⁺

| Reactant | Quantity |
|---|---|
| Si₃N₄ | 25.55 mg (0.182 mmol) |
| SiO₂ | 10.94 mg (0.182 mmol) |
| Li₂O | 28.57 mg (0.956 mmol) |
| Er₂O₃ | 31.35 mg (0.082 mmol) |
| CeF₃ | 3.59 mg (0.019 mmol) |

Production of Li₈Lu[LiSi₄N₄O₈]:Ce³⁺

The phosphor 1 with the molecular formula Li₈Lu[LiSi₄N₄O₈]:Ce³⁺ is produced from the reactants Si₃N₄, SiO₂, Li₂O, and Lu₂O₃ in the molar ratio 2.15:1.55:10.5:0.8, possibly a flux such as LiF or Li with up to 5 wt. % and with CeF₃ as the starting material for the activator element Ce³⁺. The activator element Ce³⁺ comprises a content in the range of between and including 0.01 mol % and 15 mol %, in particular in the range of between and including 0.1 mol % and 5 mol % with respect to Lu. The exact weights for producing Li₈Lu[LiSi₄N₄O₈]:Ce³⁺ are summarized in Table 38.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., wherein this temperature is maintained for around 12 hours. It is then cooled to a second temperature of around 500° C. with a cooling rate of around 1° C./h. In a second cooling step, it is cooled with a cooling rate of about 18° C./h to a third temperature of about 150° C. and the oven is then switched off.

TABLE 38
Weights for the synthesis of Li₈Lu[LiSi₄N₄O₈]:Ce³⁺.

| Reactant | Quantity |
|---|---|
| Si₃N₄ | 28.29 mg (0.202 mmol) |
| SiO₂ | 8.73 mg (0.145 mmol) |
| Li₂O | 29.43 mg (0.985 mmol) |
| Lu₂O₃ | 29.86 mg (0.075 mmol) |
| CeF₃ | 3.7 mg (0.019 mmol) |

Production of Li₈Yb[LiSi₄N₄O₈]:Ce³⁺

The phosphor 1 with the molecular formula Li₈Yb[LiSi₄N₄O₈]:Ce³⁺ is produced from the reactants Si₃N₄, SiO₂, Li₂O, and Yb₂O₃ in the molar ratio 2:2:10.5:0.9, possibly a flux such as LiF or Li with up to 5 wt. % and with CeF₃ as reactant for the activator element Ce³⁺. The activator element Ce³⁺ comprises a content in the range of between and including 0.01 mol % and 15 mol %, in particular in the range of between and including 0.1 mol % and 5 mol % with respect to Yb. The exact weights for producing Li₈Yb[LiSi₄N₄O₈]:Ce³⁺ are summarized in Table 39.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The synthesis of the material takes place at a first temperature of around 940° C., wherein this temperature is maintained for around 12 hours. It is then cooled to a second temperature of around 500° C. with a cooling rate of around 2° C./h. In a second cooling step, it is cooled with a cooling rate of about 18° C./h to a third temperature of about 150° C. and the oven is then switched off.

TABLE 39
Weights for the synthesis of Li₈Yb[LiSi₄N₄O₈]:Ce³⁺

| Reactant | Quantity |
|---|---|
| Si₃N₄ | 25.30 mg (0.180 mmol) |
| SiO₂ | 10.84 mg (0.180 mmol) |
| Li₂O | 28.30 mg (0.947 mmol) |
| Yb₂O₃ | 31.99 mg (0.081 mmol) |
| CeF₃ | 3.56 mg (0.018 mmol) |

Production of Li₈Sm[LiSi₄N₄O₈]:Ce³⁺

The phosphor 1 with the molecular formula Li₈Sm[LiSi₄N₄O₈]:Ce³⁺ is produced from the reactants Si₃N₄, SiO₂, Li₂O, and Sm₂O₃ in the molar ratio 2:2:10.5:0.85, possibly a flux such as LiF or Li with up to 5 wt. % and with CeF₃ as reactant for the activator element Ce³⁺. The activator element Ce³⁺ comprises a content in the range of between and including 0.01 mol % and 15 mol %, in particular in the range of between and including 0.1 mol % and 5 mol % with respect to Sm. The exact weights for producing Li₈Sm[LiSi₄N₄O₈]:Ce³⁺ are summarized in Table 40.

Prior to synthesis, the reactants are intimately mixed in a glovebox under a protective gas atmosphere and reacted in a Ta-tube in a tube furnace. After being filled with the reactants, the Ta tube is welded tightly with an arc under an Ar atmosphere. The material is synthesized at a first temperature of around 940° C., and this temperature is maintained for around 12 hours. It is then cooled to a second temperature of about 500° C. with a cooling rate of about 1° C./h. In a second cooling step, it is cooled with a cooling rate of about 18° C./h to a third temperature of about 150° C. and the furnace is then switched off.

TABLE 40
Weights for the synthesis of Li₈Sm[LiSi₄N₄O₈]:Ce³⁺

| Reactant | Quantity |
|---|---|
| Si₃N₄ | 26.22 mg (0.187 mmol) |
| SiO₂ | 11.23 mg (0.187 mmol) |
| Li₂O | 29.32 mg (0.981 mmol) |
| Sm₂O₃ | 27.70 mg (0.079 mmol) |
| CeF₃ | 5.53 mg (0.028 mmol) |

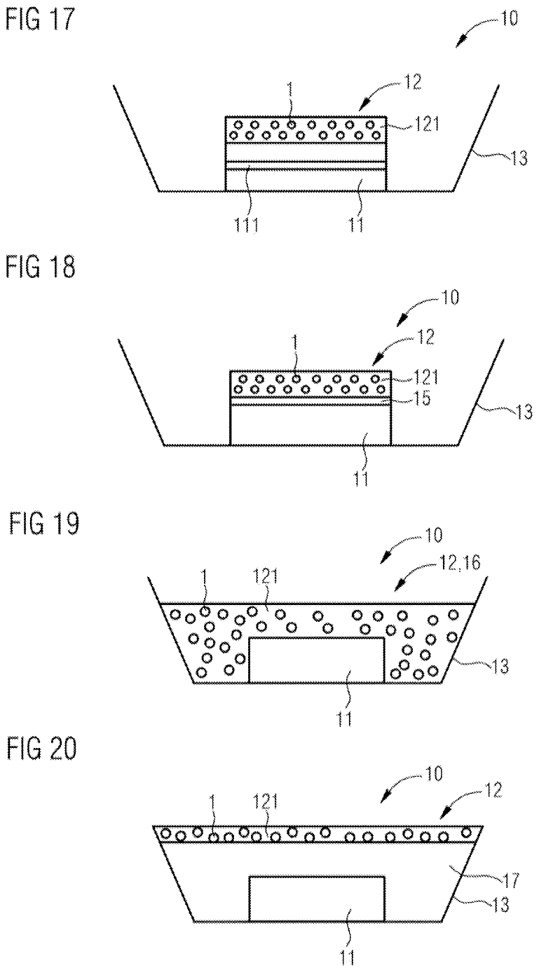

A first exemplary embodiment of an optoelectronic component 10 is shown in FIG. 17. Presently, the optoelectronic component 10 comprises a radiation-emitting semiconductor chip 11 with an epitaxially grown semiconductor layer sequence, which comprises an active region 111. The active region 111 is designed to generate electromagnetic radiation of a first wavelength range. The radiation-emitting semiconductor chip 11 emits the electromagnetic radiation of the first wavelength range through a radiation exit surface. For example, the radiation exit surface is parallel to a main extension plane of the radiation-emitting semiconductor chip 11. Presently, the radiation-emitting semiconductor chip 11 emits electromagnetic radiation from the blue wavelength range of the electromagnetic spectrum. For example, the radiation-emitting semiconductor chip emits electromagnetic radiation with a dominant wavelength λ_{dom} of about 455 nanometers or about 445 nanometers. The radiation-emitting semiconductor chip 11 is, for example, a micro-LED.

Presently, the optoelectronic component 10 further comprises a conversion element 12. The conversion element 12 is in direct mechanical contact with the radiation-emitting semiconductor chip 11. The conversion element 12 comprises a phosphor 1 with the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, in particular the phosphor 1 with the molecular formula Li₈MC[LiSi₄N₄O₈]:E with MC=Gd, Y, Pr, Nd, Ho, Tm, Tb, Er, Lu, Yb, Sm, or Dy. The phosphor 1 converts the electromagnetic radiation of the first wavelength range into electromagnetic radiation of a second wavelength range which is at least partially different from the first wavelength range.

The conversion element 12 and the radiation-emitting semiconductor chip 11 are arranged in a housing 13. The housing 13 comprises, for example, reflective surfaces.

Presently, the conversion element 12 further comprises a matrix material 121 in which particles of the phosphor 1 are embedded. The conversion element 12 is formed as a layer with a uniform thickness. The matrix material 121 is an inorganic or organic matrix material. The conversion element can be formed as a platelet. The conversion element 12 can also be formed as a ceramic and be largely free of a matrix material 121.

In particular, the matrix material 121 consists of a material selected from the group consisting of glass, such as silicate glass, water glass, or quartz glass, and polymers, such as polystyrene, polysilazane, polymethyl methacrylate, polycarbonate, polyacrylate, polytetrafluoroethylene, polyvinyl, silicone resin, silicone, polysiloxane, epoxy resin, and combinations thereof. The silicone and/or the polysiloxane may be fluorinated. The conversion element 12 may be configured for full conversion or partial conversion. Further, the conversion element 12 may comprise a further phosphor 14 and/or scattering particles (not shown). The further phosphor 14 and the scattering particles are, for example, homogeneously mixed with the phosphor 1.

The optoelectronic component 10 is suitable, for example, as a light source. In the case of partial conversion, the optoelectronic component 10 emits a mixed light from the electromagnetic radiation of the first wavelength range and the second wavelength range. In the case of full conversion, the optoelectronic component 10 emits only the electromagnetic radiation of the second wavelength range.

Compared to the first exemplary embodiment of the optoelectronic component 10, the second exemplary embodiment of the optoelectronic component 10 of FIG. 18 comprises an intermediate layer 15 between the radiation-emitting semiconductor chip 11 and the conversion element 12. Otherwise, the optoelectronic component 10 of the first exemplary embodiment and of the second exemplary embodiment have the same structure.

The intermediate layer 15 is configured, for example, as a carrier for the conversion element 12 and/or as an adhesive layer. The carrier serves to mechanically stabilize a conversion layer 12 with an organic matrix material. This is advantageous, for example, when producing the conversion element 12. The carrier consists of a transparent material. The adhesive layer comprises, for example, a silicone resin and/or an epoxy resin.

FIG. 19 shows a third exemplary embodiment of an optoelectronic component 10. The radiation-emitting semiconductor chip 11 and the housing 13 are the same as the corresponding elements of the optoelectronic component 10 of the first exemplary embodiment. In comparison to the first exemplary embodiment, however, the conversion element 12 is not formed as a layer with a uniform thickness, but as a converting casting 16. The conversion element 12 comprises the phosphor 1 and optionally a further phosphor 14 and/or scattering particles (not shown). The conversion element 12 surrounds the radiation-emitting semiconductor chip 11 in a form-fitting manner on at least two sides. The conversion element 12 further comprises a matrix material 121 which comprises, for example, a polysiloxane or an epoxy resin.

FIG. 20 shows a fourth exemplary embodiment of an optoelectronic component 10. Compared to the optoelectronic component 10 of the first exemplary embodiment, the conversion element is arranged at a distance from the radiation-emitting semiconductor chip 11. However, the conversion element 12 and the radiation-emitting semiconductor chip 11 are formed in the same way as the corresponding elements of the first exemplary embodiment. A non-converting casting 17 is arranged between the conversion element 12 and the radiation-emitting semiconductor chip 11. The conversion element 12 is flush with the housing 13.

The non-converting casting 17 at least partially surrounds the radiation-emitting semiconductor chip 11 in a form-fitting manner. The radiation-emitting semiconductor chip 11 is in direct mechanical contact with the non-converting casting 17. The non-converting casting 17 comprises a transmittance of at least 90% for the electromagnetic radiation of the first wavelength range.

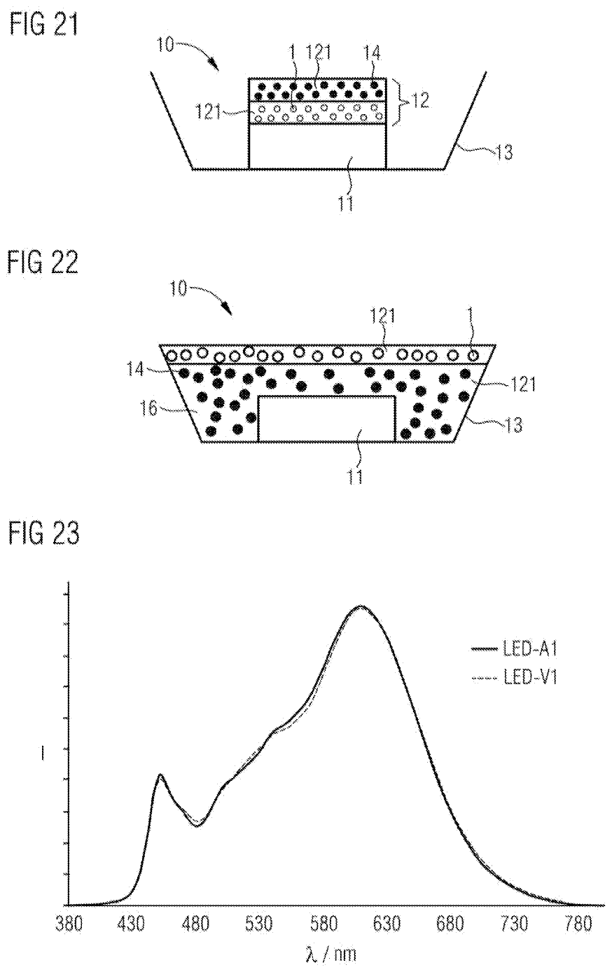

FIG. 21 shows a fifth exemplary embodiment of an optoelectronic component 10. The present optoelectronic component 10 has the same structure as the optoelectronic component 10 of the first exemplary embodiment. However, the conversion element 12 comprises a further phosphor 14, which is arranged in a separate layer. In other words, the phosphor 1 and the further phosphor 14 are not mixed with each other. The further phosphor 14 may also obey the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, in particular the molecular formula Li₈MC[LiSi₄N₄O₈]:E. However, the phosphor 1 and the further phosphor 14 differ in their composition. Alternatively, it is possible that the further phosphor 14 obeys a different molecular formula. The further phosphor 14 is embedded in the same matrix material 121 as the phosphor 1. However, it is also possible that the further phosphor 14 is embedded in a different matrix material 121. The further phosphor 14 may also comprise a mixture of different further phosphors.

The layer with the further phosphor 14 is presently arranged above the layer with the phosphor 1. In other words, the layer with the phosphor 1 is arranged between the radiation-emitting semiconductor chip 11 and the layer with the further phosphor 14. However, the two layers can also be arranged the other way around. That is, the layer with the phosphor 1 can also be arranged above the layer with the further phosphor 14.

The further phosphor 14 converts the electromagnetic radiation of the first wavelength range into electromagnetic radiation of a third wavelength range. The third wavelength range is at least partially different from the first wavelength range and the second wavelength range. The optoelectronic component 10 therefore emits a mixed light comprising the electromagnetic radiation of the first wavelength range, the second wavelength range and the third wavelength range.

The optoelectronic component 10 according to a sixth exemplary embodiment, which is shown in FIG. 22, has the same structure as the optoelectronic component 10 of the fourth exemplary embodiment. However, the optoelectronic component 10 presently comprises a converting casting 16 instead of the non-converting casting 17. In the present case, the converting casting 16 comprises a further phosphor 14 and a matrix material 121. The converting casting 16 forms part of the conversion element 12. The arrangement of the phosphor 1 and the further phosphor 14 in the converting casting 16 and in the layer above it can also be interchanged. The matrix materials 121 of the converting casting 16 and the overlying layer can be the same or different.

The conversion elements 12 of the fifth and sixth exemplary embodiment of the optoelectronic component 10 of FIGS. 21 and 22 can be configured for full conversion or for partial conversion. Thus, the optoelectronic component 10 of the fifth and sixth exemplary embodiments can emit electromagnetic radiation of the first to third wavelength range or electromagnetic radiation of the second and third wavelength range.

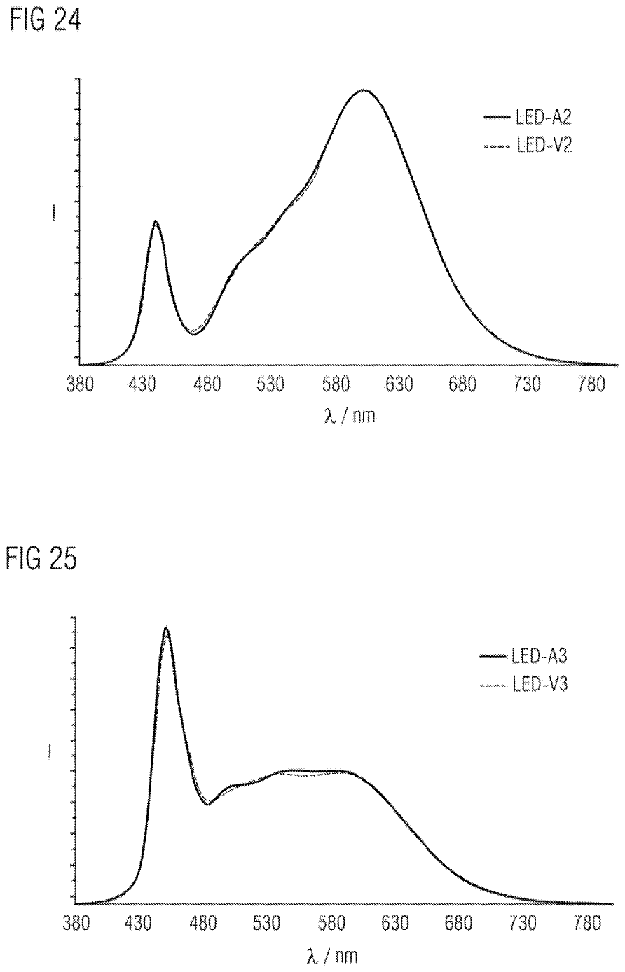

FIGS. 23 to 25 show simulated emission spectra LED-A1, LED-A2, LED-A3, LED-V1, LED-V2, and LED-V3 of optoelectronic components 10 according to various exemplary embodiments and comparative examples. In FIG. 23 the simulated emission spectra LED-A1 and LED-V1 are shown. The emission spectra LED-A2 and LED-V2 are shown in FIG. 24 and the emission spectra LED-A3 and LED-V3 are shown in FIG. 25.

The corresponding optoelectronic components 10 each comprise a radiation-emitting semiconductor chip 11 and a conversion element 12. The conversion element 12 of the exemplary embodiments with the simulated emission spectra LED-A1, LED-A2 and LED-A3 comprises the phosphor 1 with the molecular formula Li₈Gd[LiSi₄N₄O₈]:Ce³⁺ and at least one further phosphor 14 with the molecular formula (Sr,Ca)AlSiN₃:Eu²⁺ (SCASN1 to SCASN3). The conversion element 12 of the comparative examples with the simulated emission spectra LED-V1, LED-V2, and LED-V3 comprises a phosphor LuAGaG with the molecular formula Lu₃(Al,Ga)O₁₂:Ce³⁺ with a Ga content of 25% relative to the sum of Al and Ga and with a Ce content of about 2% relative to Lu and at least one further phosphor 14 with the molecular formula (Sr,Ca)AlSiN₃:Eu²⁺ (SCASN1 to SCASN3). The at least one further phosphor 14 with the molecular formula (Sr,Ca)AlSiN₃:Eu²⁺ emits in the orange or red wavelength range of the electromagnetic spectrum.

The radiation-emitting semiconductor chip 11 emits blue light. Furthermore, the ratios of phosphors 1 and 14 are adjusted to achieve a certain color locus and a certain color rendering index (CRI). The results of the simulations are summarized in Table 41.

TABLE 41
Data on white Light LED simulations.

| | LED-A1 | LED-V1 | LED-A2 | LED-V2 | LED-A3 | LED-V3 |
|---|---|---|---|---|---|---|
| blue LED (λ_{dom}/nm) | 455 | 455 | 445 | 445 | 455 | 455 |
| green phosphor | Li₈Gd[LiSi₄N₄O₈]:Ce³⁺ | LuAGaG | Li₈Gd[LiSi₄N₄O₈]:Ce³⁺ | LuAGaG | Li₈Gd[LiSi₄N₄O₈]:Ce³⁺ | LuAGaG |
| orange phosphor | — | — | SCASN1 | SCASN1 | — | — |
| red phosphor | SCASN3 | SCASN3 | SCASN2 | SCASN2 | SCASN3 | SCASN3 |
| CIE x | 0.437 | 0.437 | 0.437 | 0.437 | 0.313 | 0.314 |
| CIE y | 0.404 | 0.404 | 0.404 | 0.404 | 0.324 | 0.324 |
| CCT / K | 3000 | 3000 | 3000 | 3000 | 6504 | 6496 |
| CRI | 90 | 91 | 81 | 81 | 90 | 91 |
| R9 | 36 | 41 | −3 | −3 | 41 | 46 |
| LER / 1 m/Wₒₚₜ | 316 | 313 | 335 | 334 | 298 | 295 |

The results of the simulations show that with phosphor 1 of the molecular formula Li₈Gd[LiSi₄N₄O₈]:Ce³⁺, the same chromaticity coordinates and color temperatures are achieved in all three exemplary embodiments like for the comparative examples. Furthermore, the same or very similar color rendering values are also achieved. The phosphor 1 with the molecular formula Li₈Gd[LiSi₄N₄O₈]:Ce³⁺ is therefore very well suited to achieving optoelectronic components 10 with high color rendering at different color temperatures, at different target values for the CRI and at different emission wavelengths of the radiation-emitting semiconductor chip 12. Surprisingly, the LER values of the exemplary embodiments are also higher than those of the comparative examples. Thus, the phosphor with the molecular formula Li₈Gd[LiSi₄N₄O₈]:Ce³⁺ shows improved spectral efficiency in the application. With the phosphor of the molecular formula Li₈Dy[LiSi₄N₄O₈]:Ce³⁺, almost identical results to those shown in Table 41 are obtained.

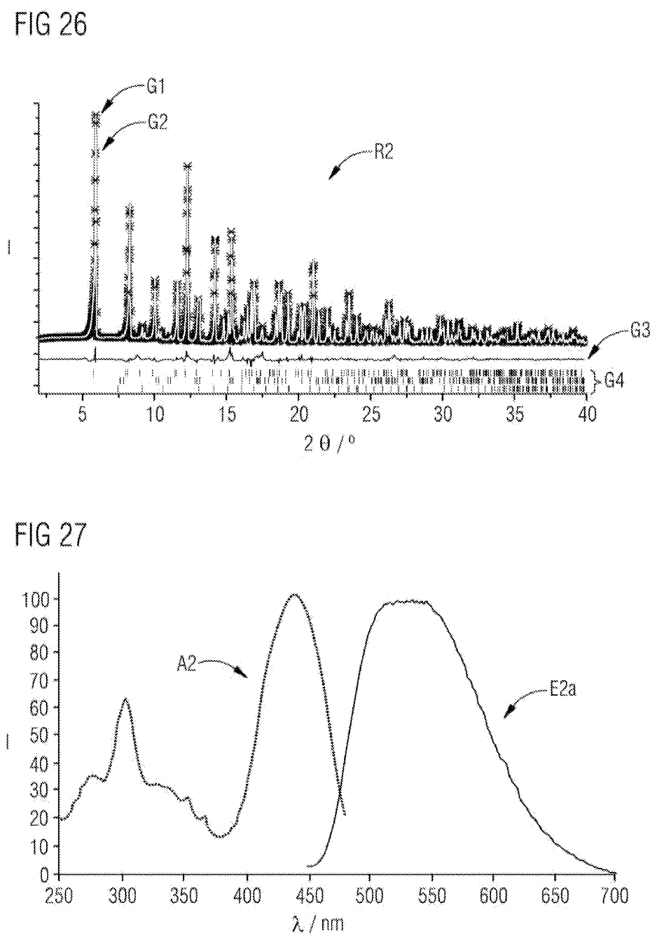

FIG. 26 shows a Rietveld-refined powder diffractogram R2 of the host structure 2 of the phosphor 1 according to the exemplary embodiment with the molecular formula Li₈Dy[LiSi₄N₄O₈]:Ce³⁺. The powder diffractogram was recorded with Mo-Kα₁ radiation. The relative intensity I is plotted in arbitrary units against the diffraction angle 2θ in degrees. The crosses of the powder diffractogram show the measured values G1. The white solid line with a black border shows a calculated powder diffractogram G2. The line G3 is the difference between the values of curve G2 and curve G1. In other words, it is a difference diagram G3. The black markings G4 correspond to the theoretical reflection positions for Li₈Dy[LiSi₄N₄O₈](top), Li₄SiO₄ (middle) and Dy₂O₃ (bottom). The theoretical reflection positions for Li₈Dy[LiSi₄N₄O₈] were calculated using the previously described crystal structure of host structure 2 of the phosphor with the molecular formula Li₈Dy[LiSi₄N₄O₈]:Ce³⁺.

TABLE 42
Results of the Rietveld refinement of
a powder sample of Li₈Dy[LiSi₄N₄O₈]
Composition

| | |
|---|---|
| Li₈Dy[LiSi₄N₄O₈] / wt % | 87(2) |
| Li₄SiO₄/ wt % | 12(2) |
| Dy₂O₃/ wt % | 0.58(7) |

Crystallographic data

| | |
|---|---|
| Diffractometer | STOE STADI P |
| Radiation; wavelength /Å | Mo-Kα₁; 0.7093 |
| a /Å | 9.9831(3) |
| c /Å | 5.0461(2) |
| cell volume /Å³ | 502.91(3) |
| 2 θ Range / ° | 2-40.085 |
| 2 θ increment / ° | 0.015 |
| Rₑₓₚ/% | 1.01 |
| R_{wp}/% | 10.36 |
| Rₚ/% | 6.72 |
| R_{Bragg}/% | 3.492 |

The Rietveld analysis shows that the investigated single crystal of Li₈Dy[LiSi₄N₄O₈]:Ce³⁺ with the crystal structure shown in FIGS. 3 to 9 is representative of the main phase of the powder sample of Li₈Dy[LiSi₄N₄O₈]:Ce³⁺. However, the powder sample also shows that minor phases are present in small proportions.

Due to the activator element E, the exemplary embodiment of the phosphor 1 with the molecular formula Li₈Dy[LiSi₄N₄O₈]:Ce³⁺ comprises phosphor properties. An excitation spectrum A2 and an emission spectrum E2a of a powder sample of phosphor 1 with the molecular formula Li₈Dy[LiSi₄N₄O₈]:Ce³⁺ are shown in FIG. 27. The excitation spectrum A2 is based on the raw data maximum of the emission curve, which is located at about 510 nanometers. The emission spectrum E2a was recorded at an excitation wavelength of 435 nanometers. The phosphor 1 with the molecular formula Li₈Dy[LiSi₄N₄O₈]:Ce³⁺ comprises an emission maximum λₘₐₓ at about 529 nanometers. Further optical data of phosphor 1 with the molecular formula Li₃Dy[LiSi₄N₄O₈]:Ce³⁺ are summarized in Table 43.

TABLE 43
Optical data for a powder sample of Li₈Dy[LiSi₄N₄O₈]:Ce³⁺.

| | Li₈Dy[LiSi₄N₄O₈]:Ce³⁺ |
|---|---|
| LER / lm W_{opt.}⁻¹ | 453.7 |
| λₘₐₓ / nm | 529.1 |
| λ_{dom} / nm | 556.5 |
| λ_{centroid} / nm | 548.1 |
| FWHM / nm | 115.4 |
| CIE-x | 0.344(1) |
| CIE-y | 0.554(1) |

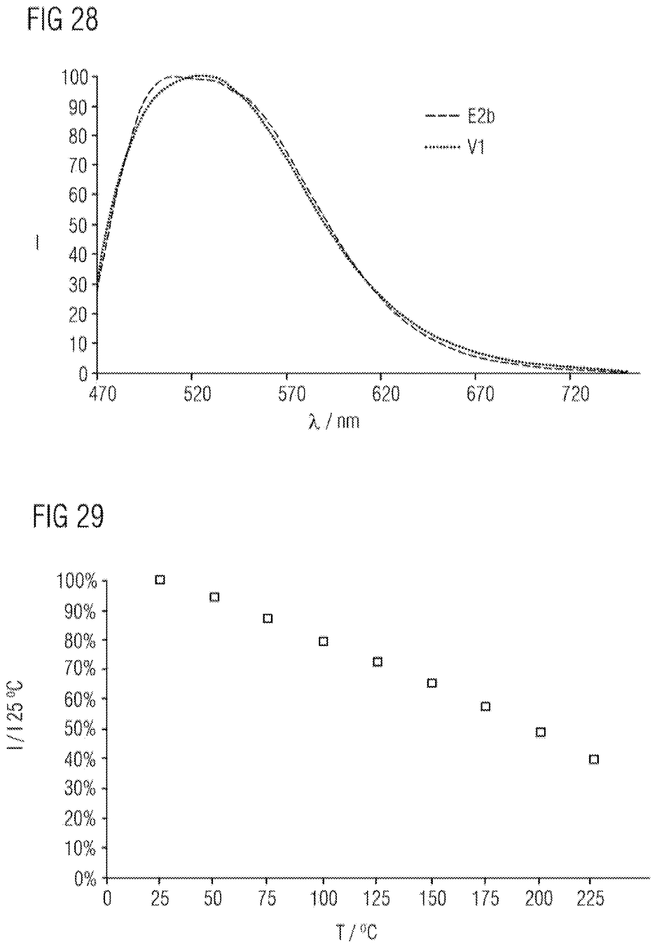

FIG. 28 shows emission spectra E2b and V1 of phosphors 1. The emission spectrum E2b for a single crystal of the exemplary embodiment of phosphor 1 with the molecular formula Li₈Dy[LiSi₄N₄O₈]:Ce³⁺ was recorded at an excitation wavelength of 448 nanometers. The emission spectrum V1 of a single grain of the comparative example of a phosphor 1 with the molecular formula Lu₃(Al/Ga)₅O₁₂:Ce³⁺ was recorded at an excitation wavelength of 448 nanometers. The emission spectra show that the emissions of Li₈Dy[LiSi₄N₄O₈]:Ce³⁺ and Lu₃(Al/Ga)₅O₁₂:Ce³⁺ are spectrally comparable. However, phosphor 1 comprises a slightly improved photometric radiation equivalent (LER). Due to the similar emission of Li₈Dy[LiSi₄N₄O₈]:Ce³⁺ and Lu₃(Al/Ga)₅O₁₂:Ce³⁺, Lu₃(Al/Ga)₅O₁₂:Ce³⁺ can be replaced by Li₈Dy[LiSi₄N₄O₈]:Ce³⁺ in conventional optoelectronic components.

Selected optical data of Li₈Dy[LiSi₄N₄O₈]:Ce³⁺ and Lu₃(Al/Ga)₅O₁₂:Ce³⁺ are summarized in Table 44.

TABLE 44
Comparison of the optical data of
Li₈Dy[LiSi₄N₄O₈]:Ce³⁺ and Lu₃(Al/Ga)₅O₁₂:Ce³⁺.

| | Li₈Dy[LiSi₄N₄O₈]:Ce³⁺ | Lu₃(Al/Ga)₅O₁₂:Ce³⁺ |
|---|---|---|
| LER / lm W_{opt.}⁻¹ | 432 (+1%) | 427 |
| λₘₐₓ / nm | 513.8 | 523.4 |
| λ_{dom} / nm | 551.7 | 551.4 |
| λ_{centroid} / nm | 542.9 | 543.7 |
| FWHM / nm | 114.8 | 114.6 |
| CIE-x | 0.321(1) | 0.320(1) |
| CIE-y | 0.546(1) | 0.543(1) |

The temperature behavior of the exemplary embodiment of phosphor 1 with the molecular formula Li₈Dy[LiSi₄N₄O₈]:Ce³⁺ is shown in FIG. 29. The x-axis shows the temperature T in ° C. and the y-axis the quotient of the integral intensity of the emission at the current temperature and that at 25° C. The step size is 25° C. The maximum temperature is 225° C. Phosphor 1 with the molecular formula Li₈Dy[LiSi₄N₄O]:Ce³⁺ shows a decrease in emission intensity with increasing temperature. However, at a temperature of about 100° C., which corresponds to a typical operating temperature of optoelectronic components, the relative emission intensity is still above 75%.

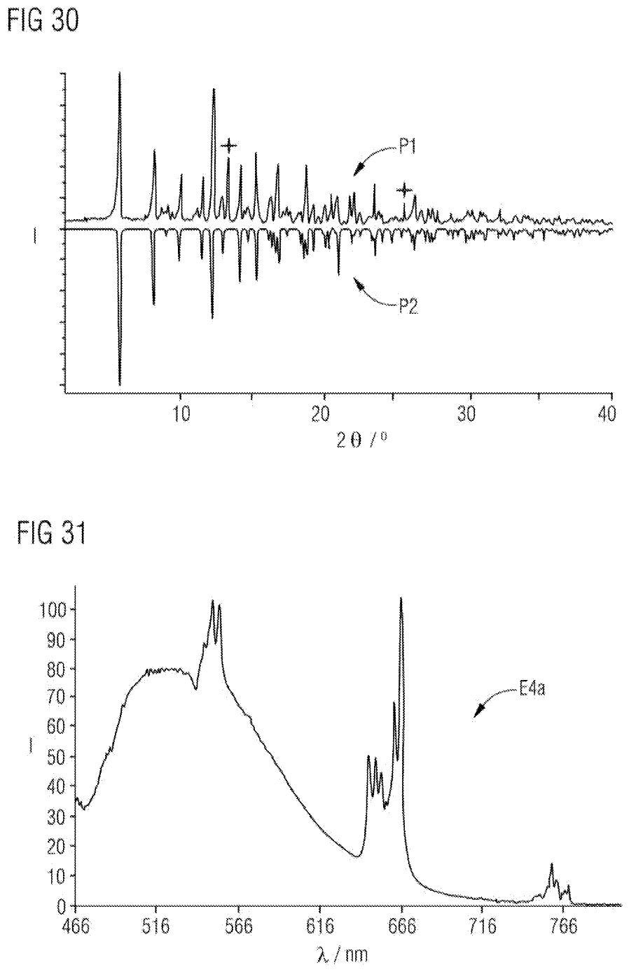

FIG. 30 shows a measured powder diffractogram P1 and a calculated powder diffractogram P2 of an exemplary embodiment of a phosphor 1 with the molecular formula Li₈Ho[LiSi₄NO₈]:Ce³⁺. The calculated powder diffractogram P2 was calculated using the structural model of phosphor 1 with the molecular formula Li₈Gd[LiSi₄N₄O₈]:Ce³⁺. Based on the agreement of the measured powder diffractogram P1 with the calculated powder diffractogram P2, it can be confirmed that Li₈Ho[LiSi₄N₄O]:Ce³⁺ crystallizes isotypically to Li₈Gd[LiSi₄N₄O]:Ce³⁺. In Li₈Ho[LiSi₄N₄O]:Ce³⁺, the lattice sites of Gd in Li₈Gd[LiSi₄N₄O₈]:Ce³⁺ are occupied by Ho.

FIG. 30 also shows that the powder sample of phosphor 1 with the molecular formula Li₃Ho[LiSi₄N₄O₈]:Ce³⁺ contains a small amount of a secondary phase. The reflexes associated with the secondary phase are marked with a cross. The secondary phase is HO₂O₃.

Furthermore, the composition of phosphor 1 with the molecular formula Li₈Ho[LiSi₄N₄O]:Ce³⁺ was confirmed by SEM-EDX analysis. The SEM-EDX analysis was performed at an accelerating voltage of 25 kV. Averaged over two measurements, the ratio (Ho+Ce):Si was 1:4.2(1), which within the measurement error confirms the composition of phosphor 1 with the molecular formula Li₈Ho[LiSi₄N₄O₈]:Ce³⁺.

Due to the presence of Ce³⁺ as activator element E, Li₈Ho[LiSi₄N₄O₈]:Ce³⁺ comprises phosphor properties. FIG. 31 shows an emission spectrum E4a of the phosphor 1 according to the exemplary embodiment with the molecular formula Li₈Ho[LiSi₄N₄O]:Ce³⁺. The emission spectrum E4a was recorded at an excitation wavelength of about 448 nanometers. It is shown in a wavelength range from 466 nanometers to about 800 nanometers. Compared to the phosphors 1 with the molecular formulas Li₈Gd[LiSi₄N₄O₈]:Ce³⁺ and Li₈Dy[LiSi₄N₄O₈]:Ce³⁺, in addition to a broad emission band, which can be attributed to the activator element Ce³⁺ and can be traced back to its 5d→4f transition, a line emission of the optically active Ho³⁺ is also present for Li₈Ho[LiSi₄N₄O₈]:Ce³⁺. The line emission can be attributed to 4f→4f transitions in the Ho³⁺. The dominant wavelength of the emission of phosphor 1 with the molecular formula Li₈Ho[LiSi₄N₄O₈]:Ce³⁺ is about 557 nanometers. Further selected optical data of Li₈Ho[LiSi₄N₄O₈]:Ce³⁺ are summarized in the following Table 45.

TABLE 45
Optical data of Li₈Ho[LiSi₄N₄O₈]:Ce³⁺.

| | Li₈Ho[LiSi₄N₄O₈]:Ce³⁺ |
|---|---|
| LER / lm W_{opt.}⁻¹ | 395 |
| λ_{dom} / nm | 556.8 |
| λ_{centroid} | 562.0 |
| CIE-x | 0.345(1) |
| CIE-y | 0.537(1) |

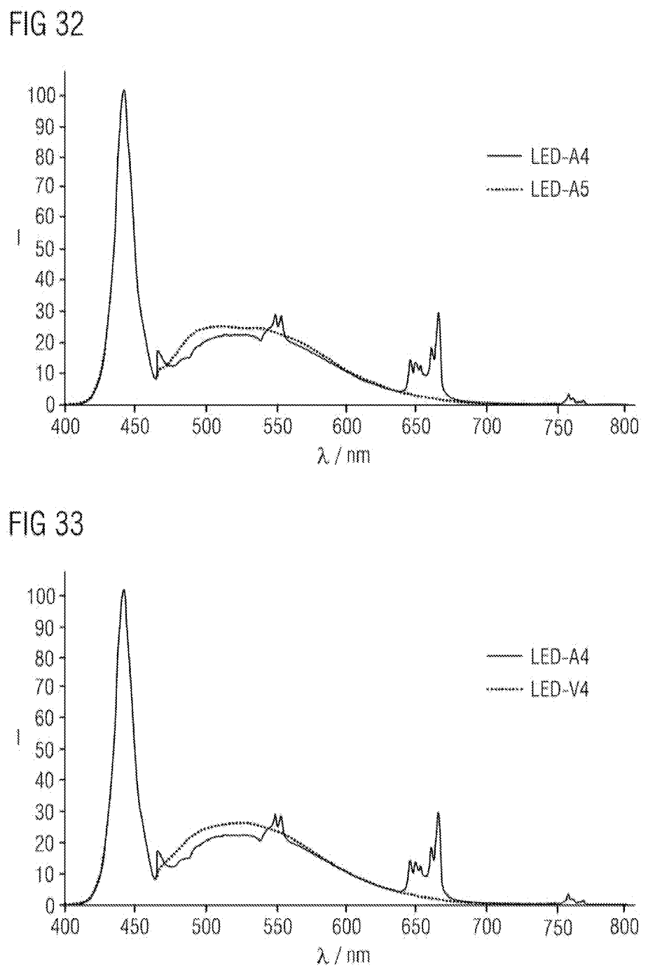

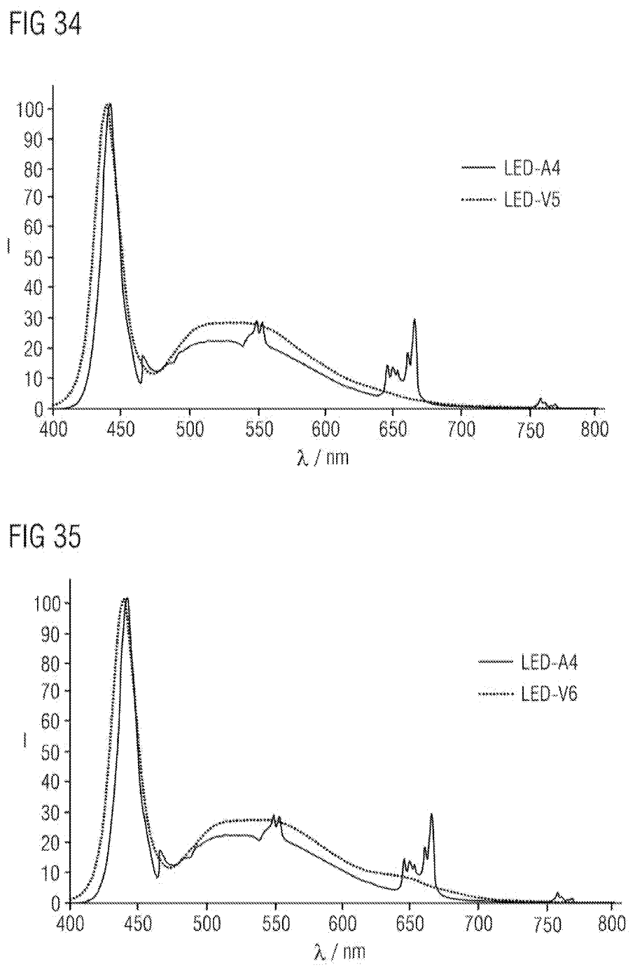

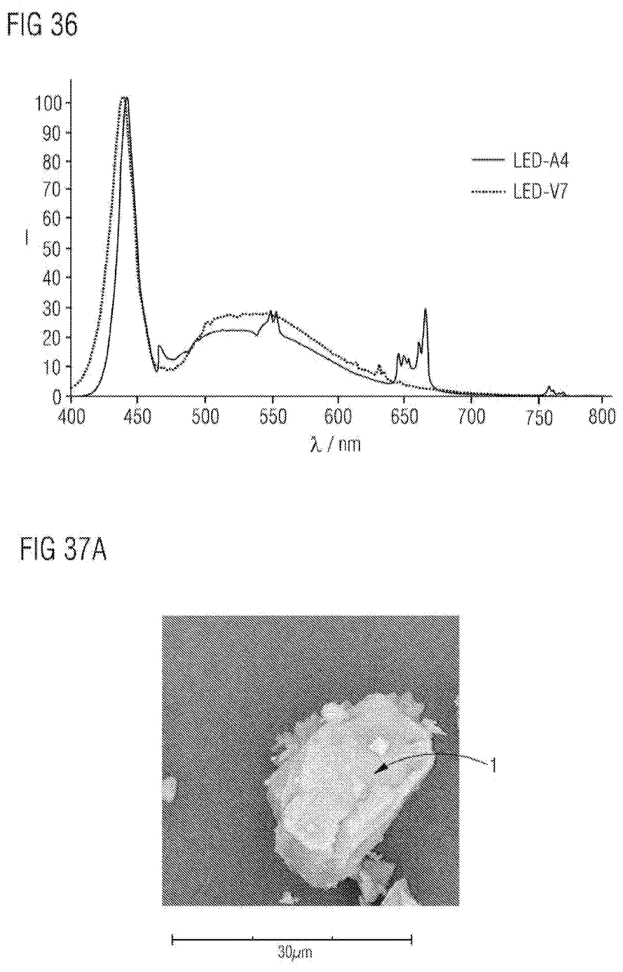

FIGS. 32 to 36 show simulated emission spectra LED-A4, LED-A5, LED-V4, LED-V5, LED-V6, and LED-V7 of optoelectronic components 10 according to various exemplary embodiments and comparative examples. In FIG. 32 the simulated emission spectra LED-A4 and LED-A5 are shown. In FIG. 33 the simulated emission spectra LED-A4 and LED-V4 are shown, in FIG. 34 the simulated emission spectra LED-A4 and LED-V5 are shown, in FIG. 35 the simulated emission spectra LED-A4 and LED-V6 are shown and in FIG. 36 the simulated emission spectra LED-A4 and LED-V7 are shown.

The corresponding optoelectronic components 10 each comprise a radiation-emitting semiconductor chip 11 and a conversion element 12. The conversion element 12 of the exemplary embodiments with the simulated emission spectra LED-A4 and LED-A5 each comprises a phosphor 1 with the molecular formula Li₈MC[LiSi₄N₄O₈]:Ce³⁺ with MC=Ho or Gd. The conversion element 12 of the comparative examples with the simulated emission spectra LED-V4, LED-V5, LED-V6, and LED-V7 comprises a phosphor LuAG with the empirical formula Lu₃Al₅O₁₂:Ce³⁺ or a phosphor LuAGaG with the empirical formula Lu₃(Al,Ga)₅O₁₂:Ce³⁺ with a Ga content of 25% relative to the sum of Al and Ga and with a Ce content of about 2% relative to Lu. Furthermore, the conversion elements 12 of the comparative examples with the simulated emission spectra LED-V5, LED-V6, and LED-V7 additionally comprise a red phosphor such as (Sr,Ca)AlSiN₃:Eu²⁺ ((S)CASN), SrLiAl₃N₄:Eu²⁺ (SLA), or K₂SiF₆:Mn⁴⁺ (KSF) as a further phosphor 14.

The radiation-emitting semiconductor chip 11 emits blue light. Furthermore, the ratios of phosphors 1 and 14 are adjusted to achieve a specific color locus. The results of the simulations and the composition of the optoelectronic components 10 are summarized in Table 46.

TABLE 46
Data on white Light LED simulations.

| Example | LED-A4 | LED-A5 | LED-V4 | LED-V5 | LED-V6 | LED-V7 |
|---|---|---|---|---|---|---|
| blue LED (λ_{dom}/nm) | 447 | 447 | 447 | 446 | 446 | 446 |
| green phosphor | Li₈Ho[LiSi₄N₄O₈]:Ce³⁺ | Li₈Gd[LiSi₄N₄O₈]:Ce³⁺ | LuAGaG | LuAG | LuAG | LuAG |
| red phosphor | — | — | — | (S)CASN | SLA | KSF |
| CIE x | 0.247 | 0.239 | 0.237 | 0.249 | 0.251 | 0.249 |
| CIE y | 0.261 | 0.268 | 0.270 | 0.259 | 0.258 | 0.262 |
| CRI | 72 | 68.5 | 67.9 | 70.2 | 71.6 | 65.5 |
| CRI comparison | 100 | 95(−5%) | 94(−6%) | 98(−2%) | 99(−1%) | 91(−9%) |
| in % | | | | | | |

The simulation results show that phosphor 1 with the molecular formula Li₈Ho[LiSi₄N₄O₈]:Ce³⁺ can achieve comparable chromaticity coordinates (CIE x and CIE y) and color temperatures to another phosphor system, wherein at the same time an increased color rendering index (CRI) is observed. The phosphor 1 with the molecular formula Li₈Ho[LiSi₄N₄O₈]:Ce³⁺ is therefore suitable for providing white light LEDs with a CRI of at least 70, wherein only the use of a single phosphor is necessary. Surprisingly, there was also a CRI advantage compared to optoelectronic components 10 with two different phosphors in the conversion element 12. The CRI advantage can be attributed to the f→f transitions and the resulting line emission in the red spectral range.

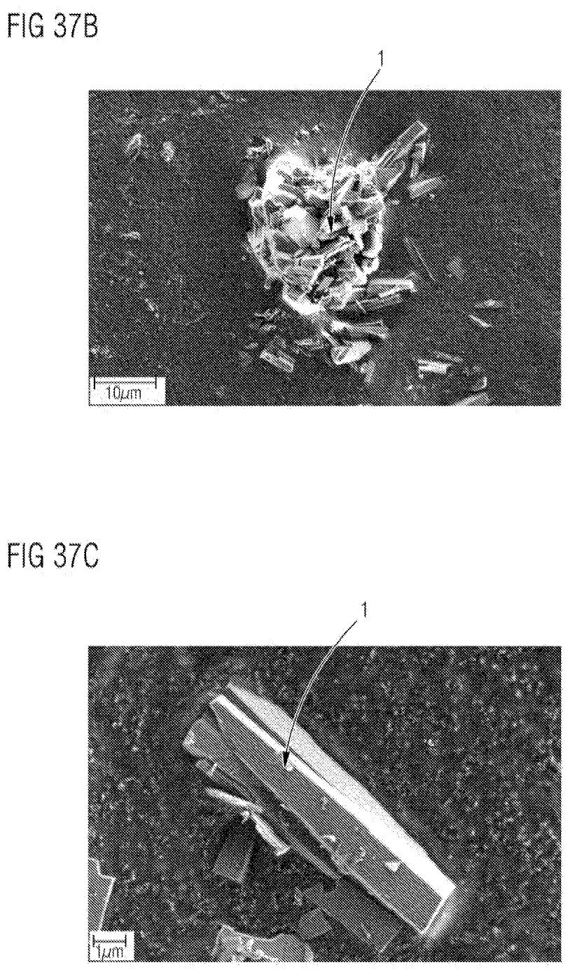

FIG. 37A shows a secondary electron image of crystals of the exemplary embodiment of phosphor 1 with the molecular formula Li₈Pr[LiSi₄N₄O]:Ce³⁺ as a result of an SEM examination at 15 kV accelerating voltage. Li₈Pr[LiSi₄N₄O₈]:Ce³⁺ is present in the form of isolated, cuboid crystals. FIGS. 37B and 37C also each show a secondary electron image of crystals of the exemplary embodiment of phosphor 1 with the molecular formula Li₈Pr[LiSi₄N₄O₈]:Ce³⁺ as a result of an SEM examination. However, these images were taken at an accelerating voltage of 3 kV.

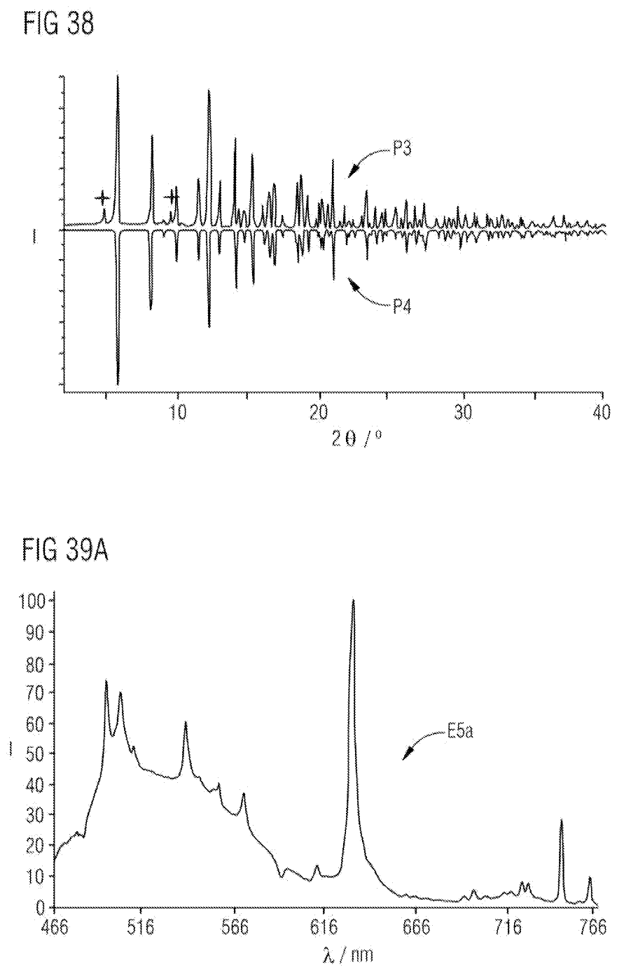

A measured powder diffractogram P3 and a calculated powder diffractogram P4 of a phosphor 1 are shown in FIG. 38. The measured powder diffractogram P3 is based on phosphor 1 with the molecular formula Li₈Pr[LiSi₄N₄O₈]:Ce³⁺. The calculated powder diffractogram P4 was calculated on the basis of the structural model of Li₈Nd[LiSi₄N₄O]:Ce³⁺. The agreement of the powder diffractograms P3 and P4 shows that the phosphor 1 with the molecular formula Li₈Pr[LiSi₄N₄O₈]:Ce³⁺ crystallizes isotypically to Li₈Nd[LiSi₄N₄O₈]:Ce³⁺. In Li₈Pr[LiSi₄N₄O₈]:Ce³⁺, the lattice sites of Nd are occupied with Pr compared to Li₈Nd[LiSi₄N₄O]:Ce³⁺. The powder diffractogram P3 also shows the presence of a secondary phase. Reflections that can be assigned to the secondary phase are marked with a cross.

The composition of phosphor 1 with the molecular formula Li₈Pr[LiSi₄N₄O₈]:Ce³⁺ was further confirmed by SEM-EDX analysis. The SEM-EDX analysis was carried out at an accelerating voltage of 15 kV. Averaged over two measurements, the Pr:Si ratio was 1:4.1(1), which within the measurement error confirms the composition of phosphor 1 with the molecular formula Li₃Pr[LiSi₄N₄O₈]:Ce³⁺. A further SEM-EDX analysis at an accelerating voltage of 25 kV showed an average ratio (Pr+Ce):Si of 1:4.0(1), which confirms the composition of phosphor 1 with the molecular formula Li₈Pr[LiSi₄N₄O₈]:Ce³⁺ within the measurement error.

By incorporating Ce³⁺ as an activator element, Li₈Pr[LiSi₄N₄O₈]:Ce³⁺ represents a compound with phosphor properties. FIG. 39A shows an emission spectrum E5a of a single grain of the phosphor 1 according to the exemplary embodiment with the molecular formula Li₈Pr[LiSi₄N₄O₈]:Ce³⁺. FIG. 39B shows the emission spectrum E5a and an emission spectrum E5b of a single crystal of the phosphor 1 according to the exemplary embodiment with the molecular formula Li₈Pr[LiSi₄N₄O₈]:Ce³⁺. The emission spectra E5a and E5b were recorded at an excitation wavelength of 448 nanometers. In addition to the broadband emission, which is due to the activator element Ce³⁺ and can be explained by a 5d→4f transition, Li₈Pr[LiSi₄N₄O]:Ce³⁺ also comprises a line emission of the optically active Pr³⁺. The line emission can be explained by a 4f→4f transition in Pr³⁺. A dominant wavelength λ_{dom} of the total emission of Li₈Pr[LiSi₄N₄O₈]:Ce³⁺ is about 550 nanometers and about 545 nanometers, respectively. Further optical data of Li₈Pr[LiSi₄N₄O₈]:Ce³⁺ are summarized in Table 47.

TABLE 47
Optical data of Li₈Pr[LiSi₄N₄O₈]:Ce³⁺.

| | Li₈Pr[LiSi₄N₄O₈]:Ce³⁺ | Li₈Pr[LiSi₄N₄O₈]:Ce³⁺ |
|---|---|---|
| | (single grain) | (single crystal) |
| LER / lm W_{opt.}⁻¹ | 375 | 351 |
| λ_{dom} / nm | 550.0 | 545.2 |
| λ_{centroid} / nm | 555.6 | 551.0 |
| CIE-x | 0.316(1) | 0.303(1) |
| CIE-y | 0.537(1) | 0.514(1) |

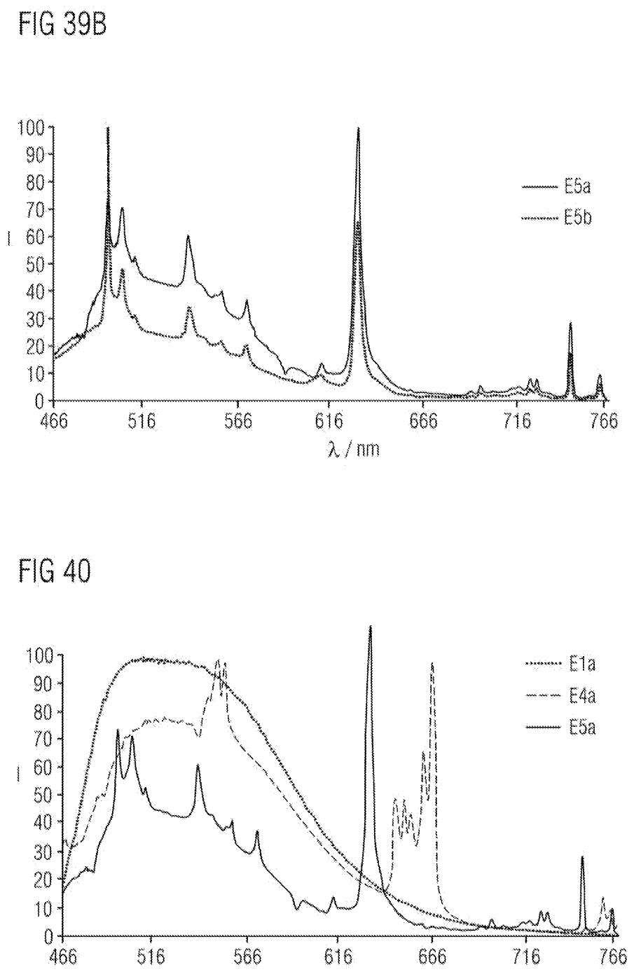

A comparison of the emission spectra Ela, E4a, and E5a is shown in FIG. 40. The emission spectrum Ela is based on phosphor 1 with the molecular formula Li₈Gd[LiSi₄N₄O₈]:Ce³⁺, the emission spectrum E4a is based on Li₈Ho[LiSi₄N₄O₈]:Ce³⁺ and the emission spectrum E5a is based on Li₈Pr[LiSi₄N₄O₈]:Ce³⁺. The emission spectra were each recorded at an excitation wavelength of 448 nanometers. FIG. 40 shows the difference between exclusive broadband emission (Li₈Gd[LiSi₄N₄O₈]:Ce³⁺) and the combined broadband emission and line emission (Li₈Ho[LiSi₄N₄O₈]:Ce³⁺ and Li₈Pr[LiSi₄N₄O₈]:Ce³⁺).

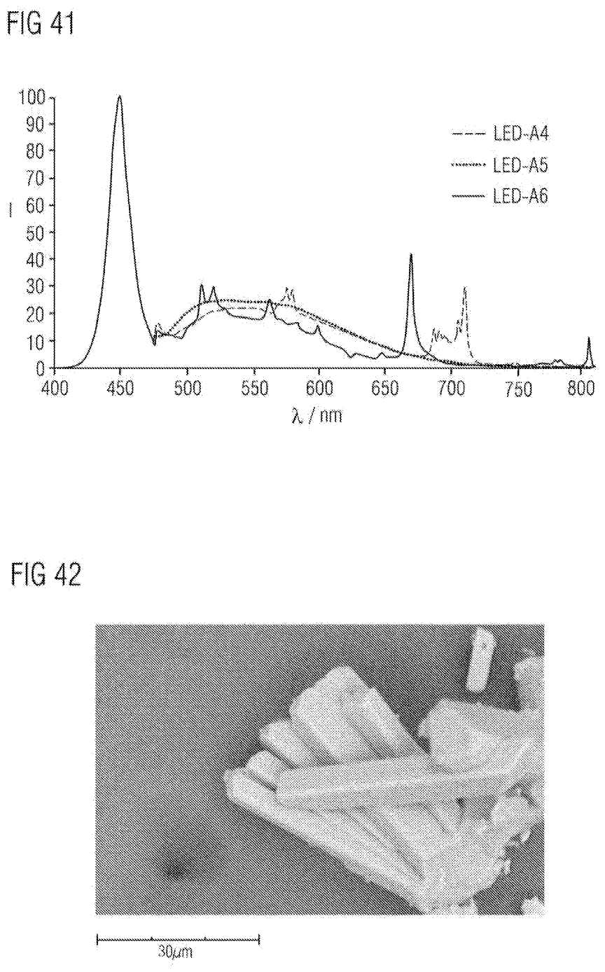

FIG. 41 shows simulated emission spectra of optoelectronic components 10 according to various exemplary embodiments. The optoelectronic components 10 each emit white light. The optoelectronic components each comprise a blue-emitting semiconductor chip 11. Presently, the radiation-emitting semiconductor chip 11 emits electromagnetic radiation with a dominant wavelength λ_{dom} of 447 nanometers. The optoelectronic components 10 each comprise a conversion element 12. The optoelectronic component 10, on which the LED-A4 emission spectrum is based, comprises a conversion element 12 with Li₈Ho[LiSi₄N₄O₈]:Ce³⁺. The optoelectronic component 10 on which the emission spectrum LED-A5 is based comprises a conversion element 12 with Li₈Gd[LiSi₄N₄O₈]:Ce³⁺. The optoelectronic component 10, on which the LED-A6 emission spectrum is based, comprises a conversion element 12 with Li₈Pr[LiSi₄N₄O₈]:Ce³⁺.

With the optoelectronic components 10, a CRI of about 70 can be achieved in each case. Thus, the phosphors 1 according to the exemplary embodiments with the molecular formula Li₈MC[LiSi₄N₄O]:Ce³⁺ with MC=Gd, Pr, Ho are suitable as phosphors for optoelectronic components 10 in whose conversion element 12 only one phosphor 1 is used. A mixture of phosphors is not necessary to achieve a CRI of around 70. However, the optoelectronic components 10 comprise different color temperatures. With Li₈Pr[LiSi₄N₄O₈]:Ce³⁺, high color temperatures, in particular greater than 25000 K, for example about 50000 K, can be achieved for the corresponding optoelectronic component 10.

FIG. 42 shows a secondary electron image of crystals of the exemplary embodiment of phosphor 1 with the molecular formula Li₈Nd[LiSi₄N₄O]:Ce³⁺ as a result of an SEM examination at 15 kV accelerating voltage. Li₈Nd[LiSi₄N₄O]:Ce³⁺ is present in the form of isolated, cuboid crystals.

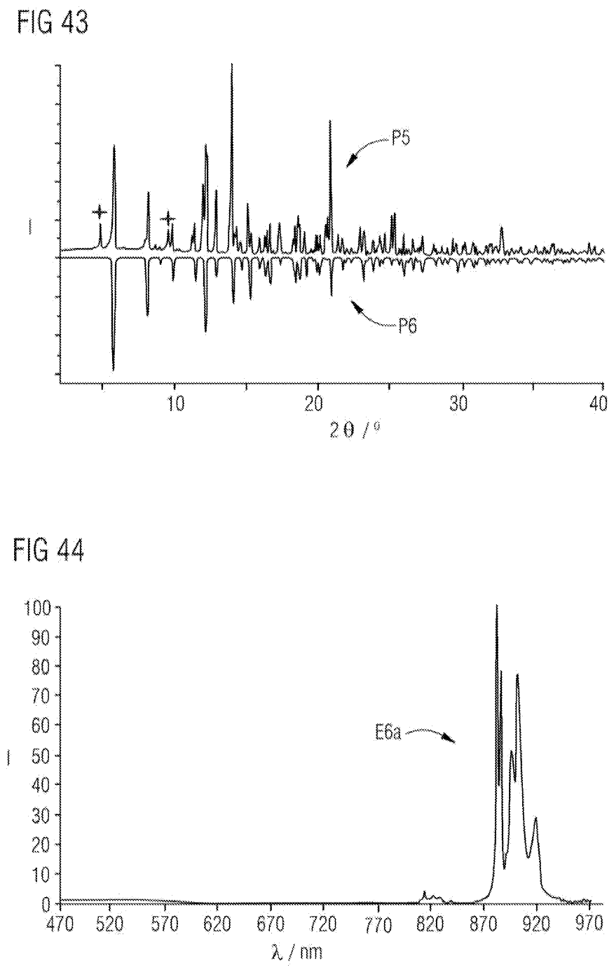

A measured powder diffractogram P5 and a calculated powder diffractogram P6 of a phosphor 1 are shown in FIG. 43. The measured powder diffractogram P5 is based on a powder sample of phosphor 1 with the molecular formula Li₈Nd[LiSi₄N₄O]:Ce³⁺. The calculated powder diffractogram was based on the structural model of single crystals of Li₈Nd[LiSi₄N₄O]:Ce³⁺. The agreement of the powder diffractograms P5 and P6 shows that the majority of the crystallites in the powder sample of Li₈Nd[LiSi₄N₄O]:Ce³⁺ comprise the same structure as the single crystal of Li₈Nd[LiSi₄N₄O₈]:Ce³⁺. The powder sample contains secondary phases in a minor amount. Reflections caused by the secondary phases are marked with a cross. The different intensities at some reflexes in comparison between the measured powder diffractogram P5 and the calculated powder diffractogram P6 could be the result of a preferential orientation of the cuboid crystals, according to which some surfaces are in the diffraction position more frequently than statistically expected.

The composition of phosphor 1 with the molecular formula Li₈Nd[LiSi₄N₄O]:Ce³⁺ was further confirmed by SEM-EDX analysis. The SEM-EDX analysis was performed at an accelerating voltage of 15 kV. The SEM-EDX analysis showed a ratio (Nd+Ce):Si of 1:4.3(1), which confirms the composition within the measurement error.

By incorporating Ce³⁺ as an activator element, Li₈Nd[LiSi₄N₄O]:Ce³⁺ represents a compound with phosphor properties. FIG. 44 shows an emission spectrum E6a of a single crystal of the phosphor 1 according to the exemplary embodiment with the molecular formula Li₈Nd[LiSi₄N₄O]:Ce³⁺. The emission spectrum E6a was recorded at an excitation wavelength of 448 nanometers and is shown in a wavelength range from 470 nanometers to 970 nanometers. In this range, the phosphor 1 with the molecular formula Li₈Nd[LiSi₄N₄O]:Ce³⁺ comprises an emission maximum at about 903 nanometers.

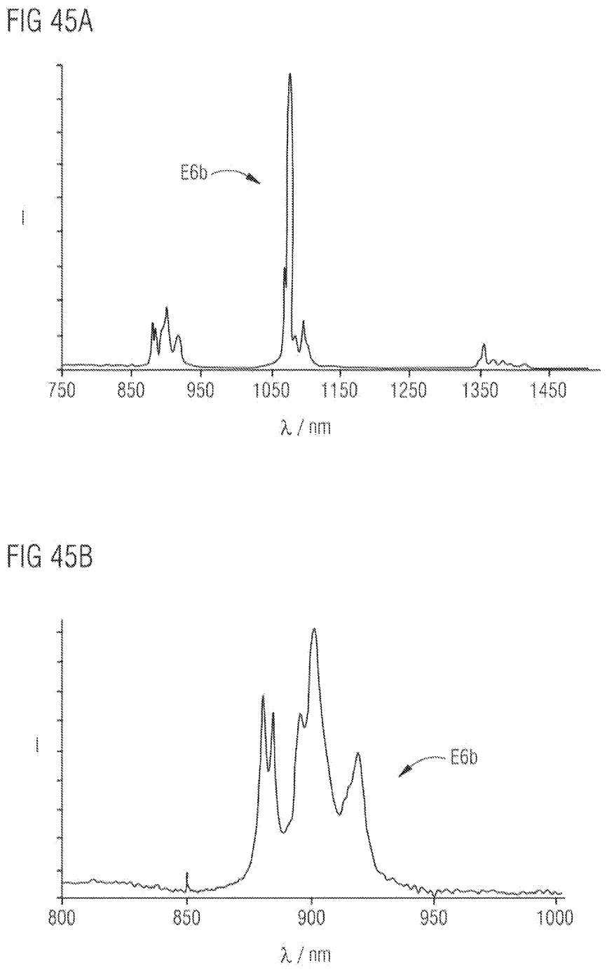

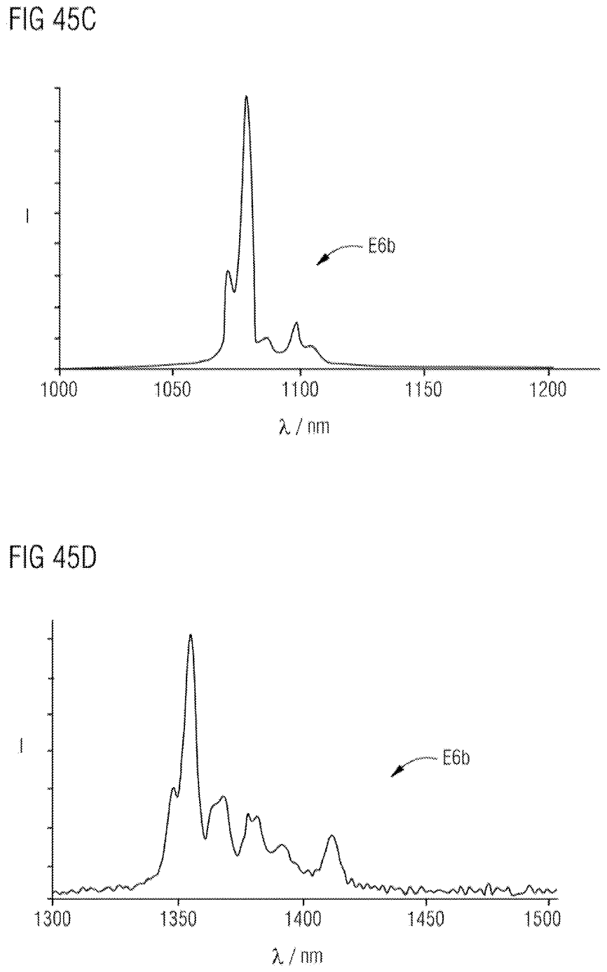

FIG. 45A shows an emission spectrum E6b of the powder sample of phosphor 1 with the molecular formula Li₈Nd[LiSi₄N₄O]:Ce³⁺. The excitation wavelength here is 450 nanometers and the emission spectrum E6b is shown in a wavelength range from 750 nanometers to 1500 nanometers. Detailed spectra of the emission spectrum E6b are shown in FIGS. 45B, 45C and 45D. In addition to an emission at about 901 nanometers, Li₈Nd[LiSi₄N₄O]:Ce³⁺ also comprises an emission peak at about 1076 nanometers and an emission peak at about 1355 nanometers. The phosphor 1 can therefore emit electromagnetic radiation in the near-infrared to infrared range of the electromagnetic spectrum.

In comparison to the phosphors 1 with the molecular formula Li₃Gd[LiSi₄N₄O]:Ce³⁺ and Li₈Dy[LiSi₄N₄O]:Ce³⁺, presently not the broadband emission of the activator element Ce³⁺ is dominating, which is caused by a 5d→4f transition, but a line emission of the optically active Nd³⁺. The line emission is caused by 4f→4f transitions in the Nd³⁺. Furthermore, the broadband emission of the activator element Ce³⁺ in Li₈Nd[LiSi₄N₄O₈]:Ce³⁺ is different from Li₈Ho[LiSi₄N₄O₈]:Ce³⁺ and Li₈Pr[LiSi₄N₄O₈]:Ce³⁺ are almost absent, which indicates that in the present case the activator element Ce³⁺ acts as a sensitizer and that there is an energy transfer from Ce³⁺ to Nd³⁺, in particular an effective one. The Ce³⁺ could presently therefore be excited and an energy transfer, in particular an efficient one, to Nd³⁺ could then take place. Accordingly, mainly the corresponding line emission of Nd³⁺ and only slightly the broadband emission of Ce³⁺ is observed.

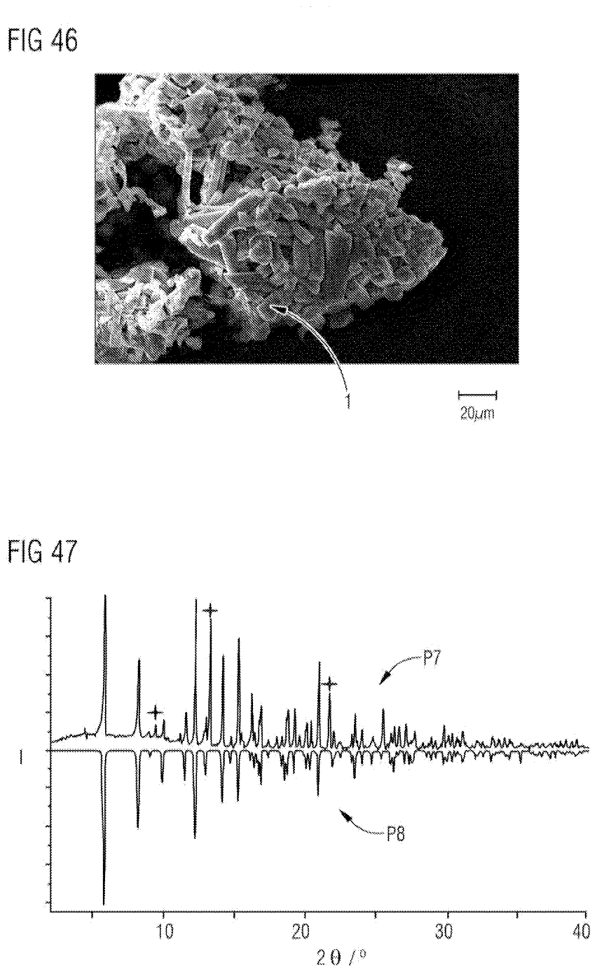

FIG. 46 shows a secondary electron image of crystals of the exemplary embodiment of phosphor 1 with the molecular formula Li₈Y[LiSi₄N₄O]:Ce³⁺ as a result of an SEM examination at 25 kV acceleration voltage. Li₈Y[LiSi₄N₄O₈]:Ce³⁺ is present in the form of isolated, cuboid crystals. The crystals form an agglomerate.

A measured powder diffractogram P7 and a calculated powder diffractogram P8 of a phosphor 1 are shown in FIG. 47. The measured powder diffractogram P7 is based on a powder sample of phosphor 1 with the molecular formula Li₈Y[LiSi₄N₄O₈]:Ce³⁺. The calculated powder diffractogram was calculated on the basis of the structural model of single crystals of Li₈Dy[LiSi₄N₄O₈]:Ce³⁺. By matching the powder diffractograms P7 and P8, it is shown that the majority of crystallites in the powder sample of Li₈Y[LiSi₄N₄O₈]:Ce³⁺ comprise the same structure as the single crystal of Li₈Dy[LiSi₄N₄O₈]:Ce³⁺. However, the positions of Dy are occupied by Y in the crystal structure of Li₈Y[LiSi₄N₄O₈]:Ce³⁺. The powder sample contains a minor amount of secondary phases. Reflections caused by the secondary phases are marked with a cross. In the present case, the secondary phase is Y₂O₃.

The composition of phosphor 1 with the molecular formula Li₈Y[LiSi₄N₄O₈]:Ce³⁺ was further confirmed by SEM-EDX analysis. The SEM-EDX analysis was performed at an accelerating voltage of 25 kV. Averaged over 2 measurements, the SEM-EDX analysis yielded a ratio (Y+Ce):Si of 1:4.1(4), which confirms the composition within the measurement error.

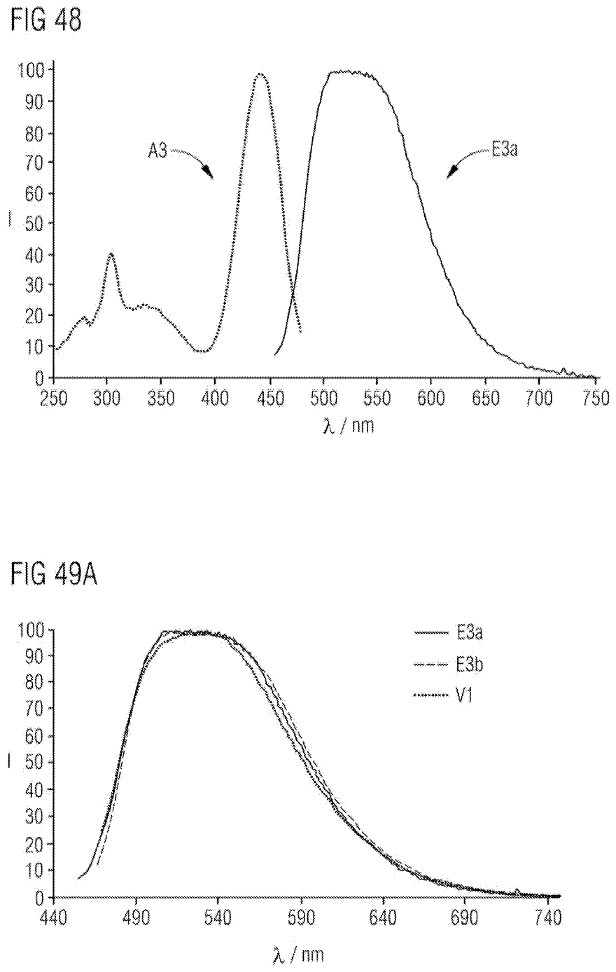

Due to the activator element E, the exemplary embodiment of the phosphor 1 with the molecular formula Li₈Y[LiSi₄N₄O₈]:Ce³⁺ comprises phosphor properties. An excitation spectrum A3 and an emission spectrum E3a of a powder sample of phosphor 1 with the molecular formula Li₈Y[LiSi₄N₄O₈]:Ce³⁺ are shown in FIG. 48. The excitation spectrum A3 is based on the raw data maximum of the emission curve, which is located at about 505 nanometers. The emission spectrum E3a was recorded at an excitation wavelength of 440 nanometers. The phosphor 1 with the molecular formula Li₈Y[LiSi₄N₄O₈]:Ce³⁺ comprises an emission maximum λₘₐₓ at about 519 nanometers. Further optical data of phosphor 1 with the molecular formula Li₈Y[LiSi₄N₄O₈]:Ce³⁺ are summarized in Table 48. Table 48 shows the optical data for a powder sample and a single crystal of phosphor 1 with the molecular formula Li₈Y[LiSi₄N₄O₈]:Ce³⁺.

TABLE 48
Optical data for Li₈Y[LiSi₄N₄O₈]:Ce³⁺.

| | Li₈Y[LiSi₄N₄O₈]:Ce³⁺ | Li₈Y[LiSi₄N₄O₈]:Ce³⁺ |
|---|---|---|
| | (powder sample) | (single crystal) |
| LER / lm W_{opt.}⁻¹ | 439 | 431 |
| λₘₐₓ / nm | 518.8 | 517.0 |
| λ_{dom} / nm | 554.1 | 553.4 |
| λ_{centroid} / nm | 546.9 | 546.8 |
| FWHM / nm | 115.7 | 118.3 |
| CIE-x | 0.332(1) | 0.329(1) |
| CIE-y | 0.545(1) | 0.547(1) |

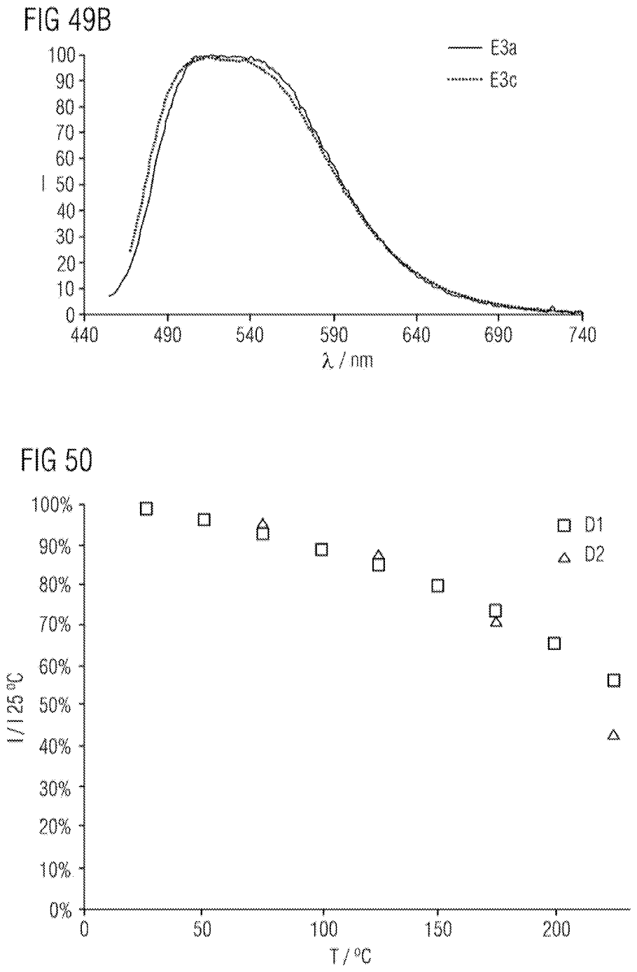

FIG. 49A shows emission spectra E3a, E3b, and V1 of phosphors 1. The emission spectrum E3a for the powder sample of the exemplary embodiment of the phosphor 1 with the molecular formula Li₈Y[LiSi₄N₄O₈]:Ce³⁺ was recorded at an excitation wavelength of 440 nanometers. The emission spectrum E3b for a single grain of the exemplary embodiment of the phosphor 1 with the molecular formula Li₈Y[LiSi₄N₄O₈]:Ce³⁺ was recorded at an excitation wavelength of 448 nanometers. The emission spectrum V1 of the comparative example of a phosphor 1 with the molecular formula Lu₃(Al/Ga)₅O₁₂:Ce³⁺ was recorded at an excitation wavelength of 460 nanometers. The emission spectra show that the emissions of Li₈Y[LiSi₄N₄O₈]:Ce³⁺ and Lu₃(Al/Ga)₅O₁₂:Ce³⁺ are spectrally comparable and comprise a similar profile. Due to the similar emission of Li₈Y[LiSi₄N₄O₈]:Ce³⁺ and Lu₃(Al/Ga)₅O₁₂:Ce³⁺, Lu₃(Al/Ga)₅O₁₂:Ce³⁺ can be replaced by Li₈Y[LiSi₄N₄O₈]:Ce³⁺ in conventional optoelectronic components. In particular, the color coordinates and the dominant wavelength λ_{dom} of the phosphor 1 of the exemplary embodiment and the comparative example are similar. Selected optical data of Li₈Y[LiSi₄N₄O₈]:Ce³⁺ and Lu₃(Al/Ga)₅O₁₂:Ce³⁺ are summarized in Table 49.

TABLE 49
Comparison of the optical data of Li₈Y[LiSi₄N₄O₈]:Ce³⁺ and Lu₃(Al/Ga)₅O₁₂:Ce³⁺.

| | Li₈Y[LiSi₄N₄O₈]:Ce³⁺ | Li₈Y[LiSi₄N₄O₈]:Ce³⁺ | Lu₃(Al/Ga)₅O₁₂:Ce³⁺ |
|---|---|---|---|
| | (powder) | (single grain) | (powder) |
| LER / lm W_{opt.}⁻¹ | 439 | 440 | 440 |
| λₘₐₓ / nm | 518.8 | 518.5 | 529 |
| λ_{dom} / nm | 554.1 | 556.3 | 554.2 |
| λ_{centroid} / nm | 546.9 | 550.2 | 548.6 |
| FWHM / nm | 115.7 | 117.6 | 112.3 |
| CIE-x | 0.332(1) | 0.343(1) | 0.332(1) |
| CIE-y | 0.545(1) | 0.553(1) | 0.559(1) |

FIG. 49B shows the emission spectrum E3a and an emission spectrum E3c. The emission spectrum E3c was measured on a single crystal of phosphor 1 with the molecular formula Li₈Y[LiSi₄N₄O₈]:Ce³⁺. The emission spectrum E3c was recorded at an excitation wavelength of 448 nanometers.

The temperature behavior of the exemplary embodiment of phosphor 1 with the molecular formula Li₈Y[LiSi₄N₄O₈]:Ce³⁺ and a comparative example of a phosphor 1 with the molecular formula Lu₃(Al,Ga)₅O₁₂:Ce³⁺ are shown in FIG. 50. The x-axis shows the temperature T in ° C. and the y-axis the quotient of the integral intensity of the emission at the current temperature and that at 25° C. The step size is 25° C. for Li₈Y [LiSi₄N₄O₈]:Ce³⁺ and 50° C. for Lu₃(Al,Ga)₅O₁₂:Ce³⁺. The maximum temperature is 225° C. The data points D1 of Li₈Y[LiSi₄N₄O₈]:Ce³⁺ are marked with a square in FIG. 50, the data points D2 of Lu₃(Al,Ga)₅O₁₂:Ce³⁺ with a triangle.

The phosphor 1 with the molecular formula Li₈Y[LiSi₄N₄O₈]:Ce³⁺ shows a decrease in emission intensity with increasing temperature. However, at a temperature of about 125° C., which corresponds to a typical operating temperature of optoelectronic components, the relative emission intensity is still about 85%. At about 175° C., the phosphor with the molecular formula Li₈Y[LiSi₄N₄O₈]:Ce³⁺ shows improved thermal behavior compared to the reference example with the molecular formula Lu₃(Al,Ga)₅O₁₂:Ce³⁺.

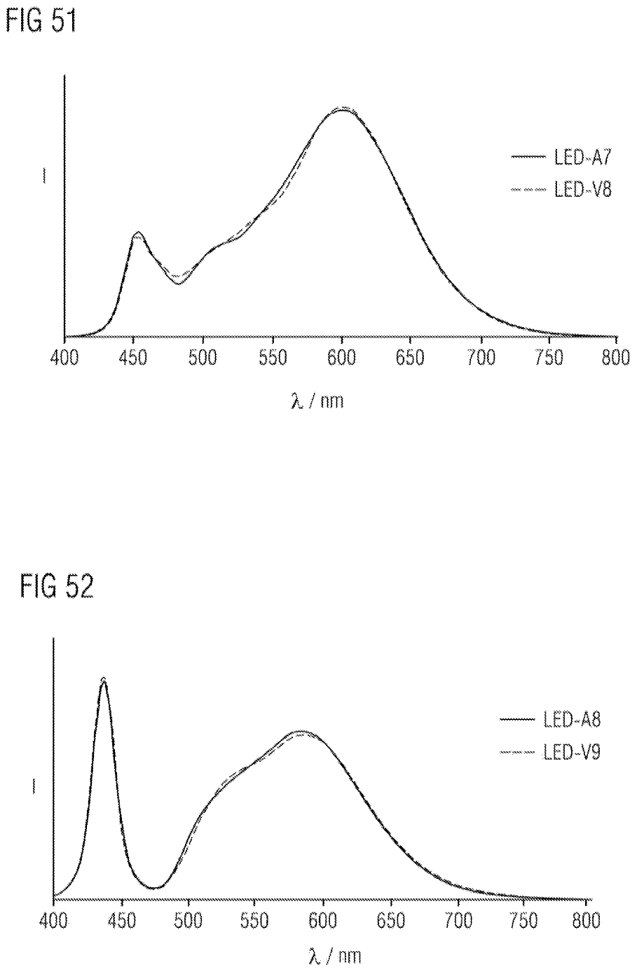

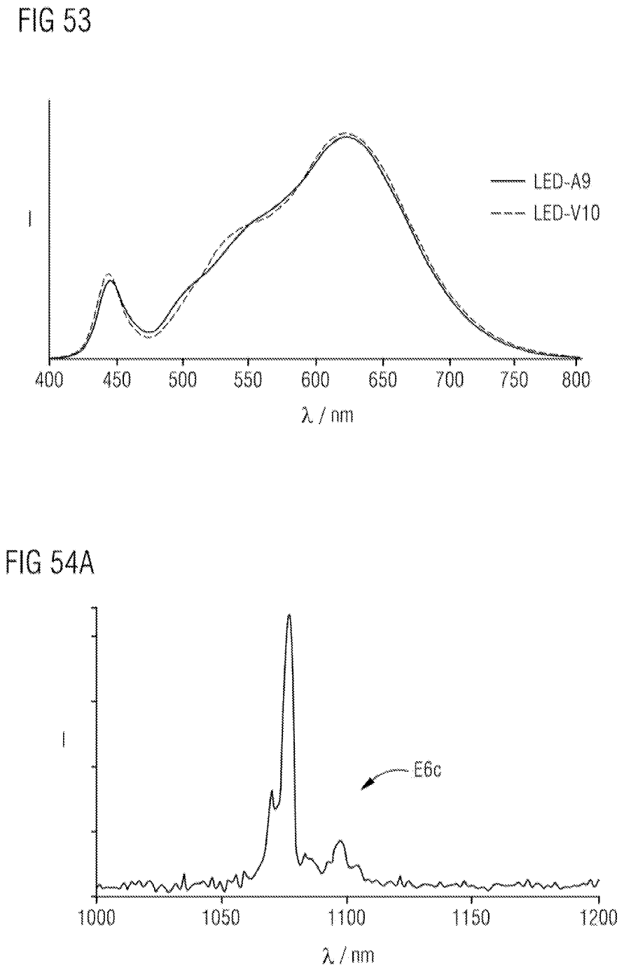

Simulated emission spectra LED-A7, LED-A8, LED-A9, LED-V8, LED-V9, LED-V10 of optoelectronic components 10 according to various exemplary embodiments and comparative examples are shown in FIGS. 51 to 53. The exemplary embodiments of the optoelectronic component 10 each comprise the phosphor 1 with the molecular formula Lu₃(Al,Ga)₅O₁₂:Ce³⁺ in their conversion element 12. The comparative examples the phosphor 1 with the molecular formula Lu₃(Al,Ga)₅O₁₂:Ce³⁺ (LuAGaG). Lu₃(Al,Ga)₅O₂:Ce³⁺ comprises a Ga content of 25% relative to the sum of Al and Ga and a Ce content of about 2% relative to Lu. The conversion elements 12 each comprise at least one further phosphor 14. The further phosphor 14 is (Sr,Ca)AlSiN₃:Eu²⁺ (SCASN). Furthermore, the conversion element can also additionally comprise Y₃Al₅O₁₂:Ce³⁺ (YAG) with a Ce content of 1.6% relative to Y as a further phosphor 14. The further phosphors 14 emit in the orange or red wavelength range of the electromagnetic spectrum.

The radiation-emitting semiconductor chips 11 of the optoelectronic components 10 each comprise an emission peak in the blue range of the electromagnetic spectrum. The optoelectronic components 10 can emit white light. The exact composition of the optoelectronic components 10 for the exemplary embodiments and comparative examples leading to the emission spectra shown in FIGS. 51 to 53, and spectral data of the optoelectronic components 10 are summarized in the following Table 50.

TABLE 50
Data on white Light LED simulations.

| Example | LED-A7 | LED-V8 | LED-A8 | LED-V9 | LED-A9 | LED-V10 |
|---|---|---|---|---|---|---|
| blue LED (λ_{dom}/nm) | 455 | 455 | 445 | 445 | 450 | 450 |
| green phosphor | Li₈Y[LiSi₄N₄O₈]:Ce³⁺ | LuAGaG | Li₈Y[LiSi₄N₄O₈]:Ce³⁺ | LuAGaG | Li₈Y[LiSi₄N₄O₈]:Ce³⁺ | LuAGaG |
| orange phosphor | SCASN1 | SCASN1 | YAG | YAG | — | YAG |
| red phosphor | SCASN2 | SCASN2 | SCASN1 | SCASN1 | SCASN4 | SCASN4 |
| CIE x | 0.437 | 0.437 | 0.380 | 0.380 | 0.460 | 0.460 |
| CIE y | 0.404 | 0.404 | 0.377 | 0.377 | 0.411 | 0.411 |
| CCT / K | 3003 | 3002 | 4000 | 4000 | 2700 | 2700 |
| CRI | 81 | 82 | 70 | 70 | 90 | 90 |
| R9 | 0 | 1 | −35 | −31 | 55 | 58 |
| LER / 1 m/W | 335 | 334 | 344 | 341 | 291 | 290 |

The optoelectronic components 10 were assembled in such a way that the highest possible color rendering quality was achieved at different color temperatures (CCT). The emission wavelength of the radiation-emitting semiconductor chip 11 and the phosphors 1, 14 were adapted so that a specific target color coordinates and a specific color rendering index (CRI) were achieved. It is shown that a CRI of about 70, about 80 and about 90 can be achieved with the phosphor 1 of the molecular formula Li₈Y[LiSi₄N₄O₈]:Ce³⁺ in the conversion element 12. Optoelectronic components 10 with a CRI of about 70 are suitable, for example, for street lighting, optoelectronic components 10 with a CRI of about 80 for general lighting and optoelectronic components 10 with a CRI of about 90 for special lighting, such as salesroom lighting.

The results show that the same or at least very similar color coordinates or color temperatures and the same or at least very similar color rendering values can be achieved with the phosphor 1 of the molecular formula Li₈Y[LiSi₄N₄O₈]:Ce³⁺ as with Lu₃(Al,Ga)₅O₁₂:Ce³⁺. Li₈Y[LiSi₄N₄O₈]:Ce³⁺ is therefore suitable for achieving optoelectronic components 10 with high color rendering at different color temperatures, different CRI target values, and different wavelengths of the radiation-emitting semiconductor chip 11. Surprisingly, the optoelectronic components 10 with Li₈Y[LiSi₄N₄O₈]:Ce³⁺ show higher LER values than the optoelectronic components 10 with Lu₃(Al,Ga)₅O₁₂:Ce³⁺. Li₈Y[LiSi₄N₄O₈]:Ce³⁺ therefore shows improved spectral efficiency in the application.

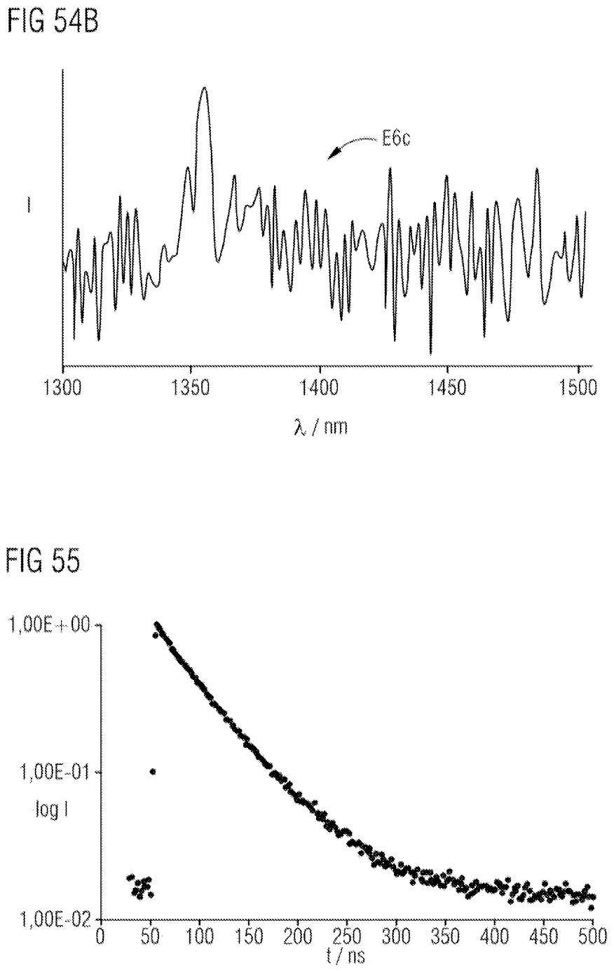

FIGS. 54A and 54B show sections of an emission spectrum E6c of a phosphor 1 with the molecular formula Li₈Nd[LiSi₄N₄O₈]:Ce³⁺. The emission spectrum E6c was recorded at an excitation wavelength of approximately 635 nanometers. The wavelength range from about 1000 nanometers to about 1200 nanometers is shown in FIG. 54A, and the wavelength range from about 1300 nanometers to about 1500 nanometers is shown in FIG. 54B. The emission spectrum E6c shows emission peaks at about 1076 nanometers and at about 1355 nanometers. The emission spectrum E6c therefore shows the same emission peaks in the near-infrared to infrared range as the emission spectra E6, E6a, and E6b. However, the emission peak at about 900 nanometers cannot be observed at an excitation wavelength of about 635 nanometers.

It is thus shown that the f→f transition of Nd³⁺ can also be excited directly, i.e. without a sensitizer. Presently, excitation was carried out with electromagnetic radiation from the red range of the electromagnetic spectrum.

In FIG. 55, the emission intensity of phosphor 1 with the molecular formula Li₈Gd[LiSi₄N₄O₈]:Ce³⁺ is plotted logarithmically against time in nanoseconds. This graph can be used to determine the decay time. The decay time T, also known as fluorescence decay time or fluorescence lifetime, indicates the average time that the activator element remains in an excited state during fluorescence before it emits a photon and thus returns to the ground state. Presently, the decay time T is approximately 46.7 nanoseconds and thus corresponds to the time at which half of the original integral photoluminescence intensity is present, i.e. half of the excited activator elements have already returned to the ground state by emitting a photon.

FIG. 56 shows the emission spectrum E6a of the phosphor 1 with the molecular formula Li₈Nd[LiSi₄N₄O]:Ce³⁺ in the range of between and including 470 nanometers and 970 nanometers. Furthermore, an emission spectrum E6d is shown in FIG. 56, which is also based on the phosphor 1 with the molecular formula Li₈Nd[LiSi₄N₄O₈]:Ce³⁺. The emission spectrum E6d was measured on single grains of phosphor 1 with the molecular formula Li₈Nd[LiSi₄N₄O]:Ce³⁺. Emission spectra E7 and E7a are also shown in FIG. 56. The emission spectra E7 and E7a are from phosphors 1 according to the exemplary embodiment with the molecular formula Li₈Gd[LiSi₄N₄O₈]:Ce³⁺,Nd³⁺. The emission spectra E6a, E6d, E7, and E7a were recorded at an excitation wavelength of 448 nanometers. The phosphors 1 each comprise 5 mol % of the activator elements Ce³⁺ or Ce³⁺ and Nd³⁺ relative to Gd.

Li₈Nd[LiSi₄N₄O₈] not doped with an activator element shows no emission when excited with a wavelength of 448 nanometers. In contrast, the emission spectra E6a and E6d can be obtained for Li₈Nd[LiSi₄N₄O]:Ce³⁺. The emission spectra E7 and E7a of Li₈Gd[LiSi₄N₄O₈]:Ce³⁺,Nd³⁺ show both the emission band characteristic of the Ce³⁺ in the range from about 470 nanometers to about 620 nanometers and the emission band characteristic of the Nd³⁺ in the range from about 870 nanometers to 930 nanometers, as can be seen in FIG. 56.

From this it can be concluded that an energy transfer from Ce³⁺ to the Nd³⁺ takes place. Because Ce³⁺ is only present as an activator element in Li₈Nd[LiSi₄N₄O]:Ce³⁺ and not in stoichiometric quantities like Nd, virtually no emission attributable to the Ce³⁺ is observed for Li₈Nd[LiSi₄N₄O₈]:Ce³⁺. However, if the concentration of Ce³⁺ and Nd³⁺ is approximately the same, as in Li₈Gd[LiSi₄N₄O₈]:Ce³⁺,Nd³⁺, the emission bands of Ce³⁺ and Nd³⁺ are observable.

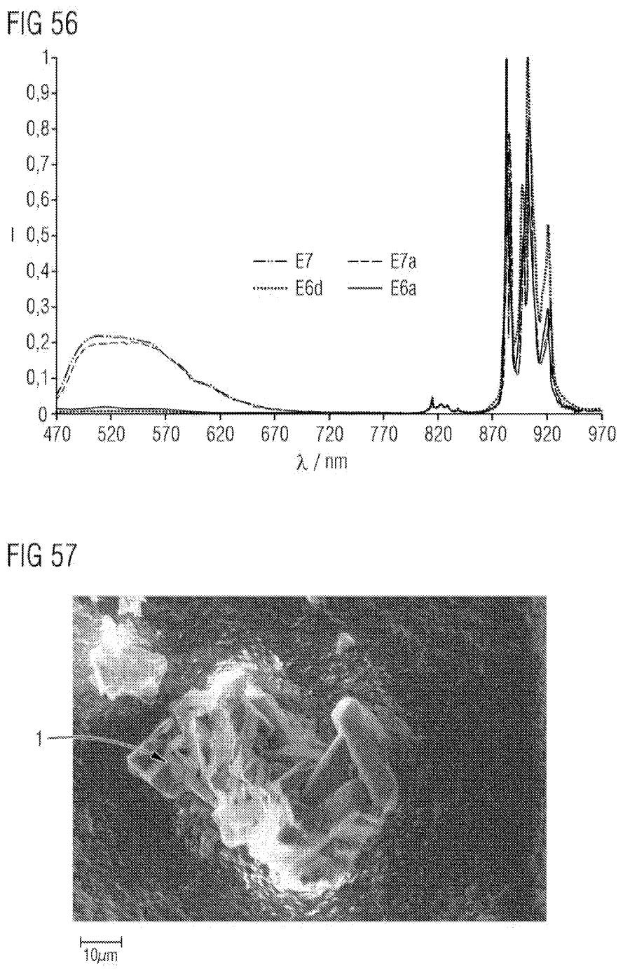

FIG. 57 shows an image of crystals of the phosphor 1 according to the exemplary embodiment with the molecular formula Li₈Tm[LiSi₄N₄O₈]:Ce³⁺. The figure was created using secondary electrons as a result of an SEM examination at an acceleration voltage of 3 kV. Li₈Tm[LiSi₄N₄O]:Ce³⁺ is present as isolated, cuboidal crystals.

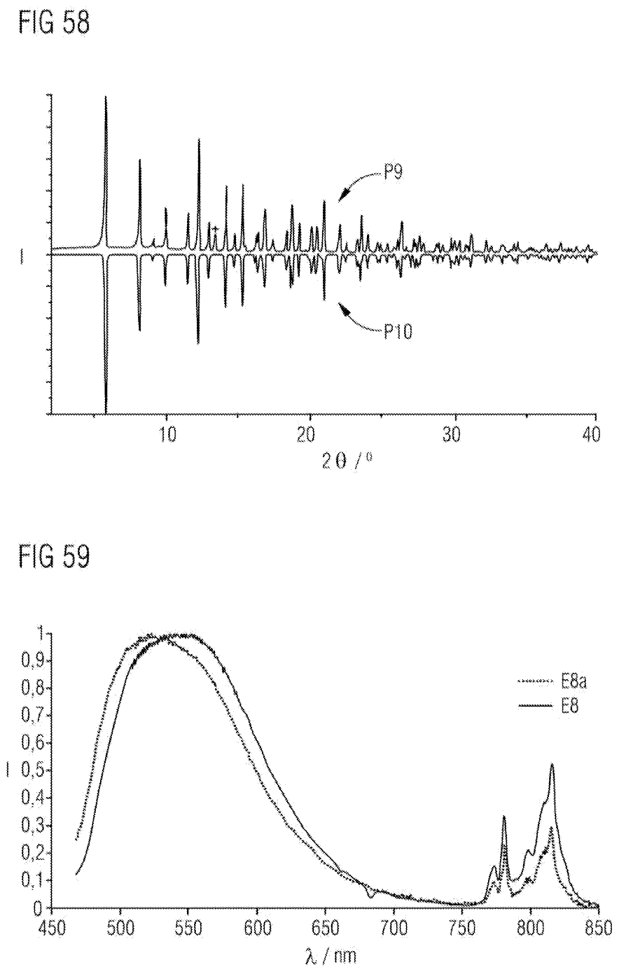

FIG. 58 shows a measured powder diffractogram P9 and a calculated powder diffractogram P10 of an exemplary embodiment of a phosphor 1 with the molecular formula Li₈Tm[LiSi₄N₄O₈]:Ce³⁺. The measured powder diffractogram P1 was recorded using Mo K-L₃ radiation. The calculated powder diffractogram P10 is based on the single crystal data of phosphor 1 with the molecular formula Li₈Tm[LiSi₄N₄O₈]:Ce³⁺. Based on the agreement of the measured powder diffractogram P9 with the calculated powder diffractogram P10, it can be confirmed that phosphor 1 with the molecular formula Li₈Tm[LiSi₄N₄O]:Ce³⁺ is the main phase of the powder sample. This shows that the phosphor 1 with the molecular formula Li₈Tm[LiSi₄N₄O₈]:Ce³⁺ can be specifically synthesized. Minor amounts of secondary phases such as Tm₂O₃ are present in the powder sample. Reflection positions that can be assigned to Tm₂O₃ are marked with a cross in FIG. 58.

Emission spectra E8 and E8a of the exemplary embodiment of the phosphor 1 with the molecular formula Li₈Tm[LiSi₄N₄O]:Ce³⁺ are shown in FIG. 59. The emission spectra E8 and E8a were recorded at an excitation wavelength of 448 nanometers and are shown in a wavelength range from 450 nanometers to 850 nanometers. The emission spectrum E8 is based on a powder sample of phosphor 1 with the molecular formula Li₈Tm[LiSi₄N₄O₈]:Ce³⁺, the emission spectrum E8a is based on a single crystal of phosphor 1 with the molecular formula Li₈Tm[LiSi₄N₄O₈]:Ce³⁺.

The phosphor properties of the compound Li₈Tm[LiSi₄N₄O₈]:Ce³⁺ can be explained by the presence of Ce³⁺ as an activator element. The slight shift in emission when comparing the emission spectra E8 and E8a can be explained by different concentrations of the activator element. The emission spectra E8 and E8a show the broadband emission characteristic of Ce³⁺ in the wavelength range from about 500 nanometers to about 650 nanometers. The broadband emission can be explained by 5d-4f transitions in Ce³⁺. In the emission spectra E8 and E8a, however, an additional line emission of the Tm³⁺ can be observed. This line emission occurs in the wavelength range from about 760 nanometers to about 830 nanometers. The line emission can be explained by a 4f-4f transition of the Tm³⁺. Selected optical data for the powder sample and the single crystal of Li₈Tm[LiSi₄N₄O₈]:Ce³⁺ are summarized in Table 51.

TABLE 51
Selected optical data of Li₈Tm[LiSi₄N₄O₈]:Ce³⁺

| | Li₈Tm[LiSi₄N₄O₈]:Ce³⁺ | Li₈Tm[LiSi₄N₄O₈]:Ce³⁺ |
|---|---|---|
| | (powder sample) | (single crystal) |
| Excitation | 448 | 448 |
| wavelength / nm | | |
| FWHM / nm | 122.1 | 119.5 |
| λ_{dom} / nm | 562 | 557 |
| λₘₐₓ / nm | 544.2 | 523.4 |
| λ_{centroid} / nm | 583.6 | 566.0 |
| CIE-x | 0.376(1) | 0.346(1) |
| CIE-y | 0.552(1) | 0.548(1) |
| LER / lm W_{opt.}⁻¹ | 404 | 407 |

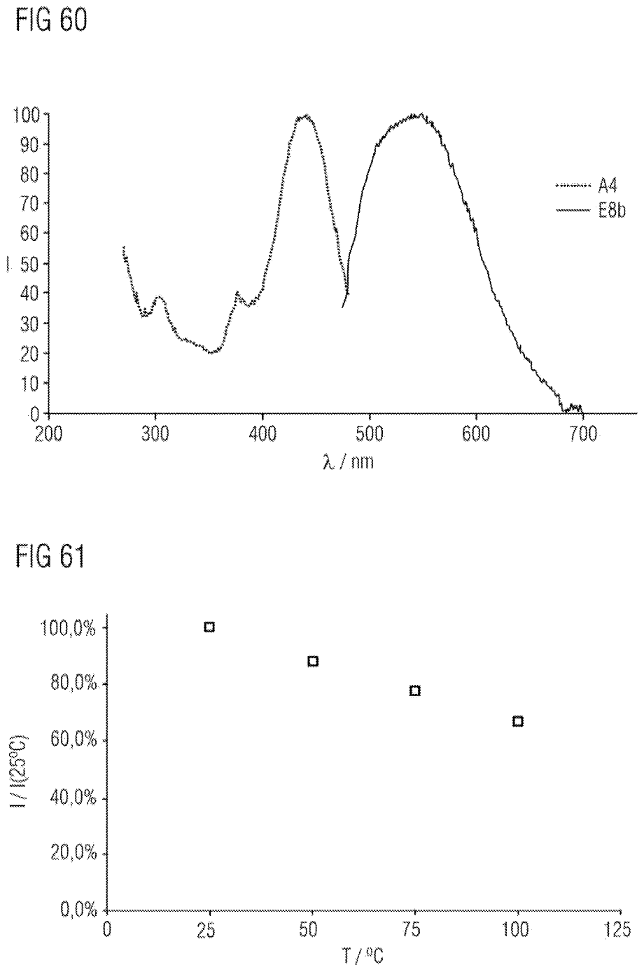

In addition to an emission spectrum E8b of the powder sample of phosphor 1 with the molecular formula Li₈Tm[LiSi₄N₄O₈]:Ce³⁺ in the wavelength range from about 500 nanometers to about 700 nanometers, FIG. 60 also shows an excitation spectrum A4. The emission spectrum E8b was recorded at an excitation wavelength of 440 nanometers, provided with an Xe lamp. The excitation spectrum is based on the raw data maximum of the emission spectrum E8b. This is presently at approximately 510 nanometers. Based on the emission spectrum E8b, an emission maximum λₘₐₓ at 543.7 nanometers was determined for phosphor 1 with the molecular formula Li₈Tm[LiSi₄N₄O₈]:Ce³⁺. The full width at half maximum (FWHM) is 125.8 nanometers and the dominant wavelength λ_{dom} is 560.7 nanometers.

The temperature behavior of the exemplary embodiment of phosphor 1 with the molecular formula Li₈Tm[LiSi₄N₄O₈]:Ce³⁺ is shown in FIG. 61. The x-axis shows the temperature T in ° C. and the y-axis shows the quotient of the integral intensity of the emission at the current temperature and that at 25° C. The step size is 25° C. The maximum temperature is 100° C. Phosphor 1 with the molecular formula Li₈Tm[LiSi₄N₄O₈]:Ce³⁺ shows a decrease in emission intensity with increasing temperature. At a temperature of about 100° C., which corresponds to a typical operating temperature of optoelectronic components, the relative emission intensity is about 67%.

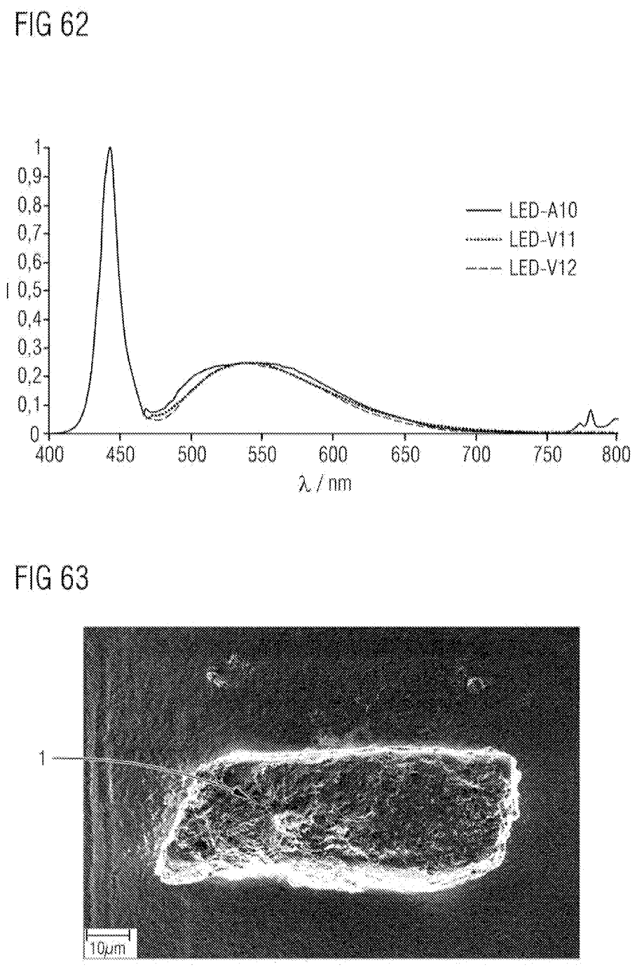

FIG. 62 shows simulated emission spectra LED-A10, LED-V11, and LED-V12 of optoelectronic components 10 according to one exemplary embodiment (LED-A10) and two comparative examples (LED-V11 and LED-V12). The emission spectra are each shown in a wavelength range from 400 nanometers to 800 nanometers. The optoelectronic components 10 each comprise a blue-emitting semiconductor chip 11 and a conversion element 12 with a phosphor 1. In the simulations, the concentration of the phosphor 1 was adjusted so that a specific color location on the Planckian curve was achieved. The comparative examples of the optoelectronic component 10 comprise Lu₃(Al,Ga)₅O₁₂:Ce³⁺ (LuAGaG) or Y₃(Al,Ga)₅O₁₂:Ce³⁺ (YAGaG) as phosphor 1. The results and the configuration of the optoelectronic components 10 of the simulations are summarized in Table 52.

TABLE 52
Data on white light LED simulations

| | LED-A10 | LED-V11 | LED V12 |
|---|---|---|---|
| blue LED (λ_{dom}/nm) | 447 | 447 | 447 |
| green phosphor | 562.0 | 562.2 | 561.9 |
| (λ_{dom}/nm) | | | |
| green phosphor | Li₈Tm[LiSi₄N₄O₈]:Ce³⁺ | LuAGaG | YAGaG |
| CIE x | 0.266 | 0.263 | 0.261 |
| CIE y | 0.280 | 0.273 | 0.271 |
| CCT / K | 12671 | 14168 | 14932 |
| CRI | 70 | 68 | 66 |
| CRI comparison in % | 100 | 97 (−3%) | 94 (−6%) |

The simulation results show that the exemplary embodiment of phosphor 1 with the molecular formula Li₈Tm[LiSi₄N₄O₈]:Ce³⁺ is very well suited for use in white-emitting optoelectronic components 10. Advantageously, only one phosphor is required to achieve a CRI of at least 70. The improved CRI compared to the optoelectronic components 10 with the garnet phosphors can be explained by emission of the Tm³⁺. A radiation-emitting component 10 with a CRI of at least 70 can be used for street lighting.

FIG. 63 shows a secondary electron image of a crystal of a phosphor 1 according to the exemplary embodiment with the molecular formula Li₈Tb[LiSi₄N₄O₈]:Ce³⁺. The secondary electron image is the result of an SEM examination at an acceleration voltage of 3 kV. The phosphor 1 with the molecular formula Li₈Tb[LiSi₄N₄O]:Ce³⁺ is present as a cuboid crystal.

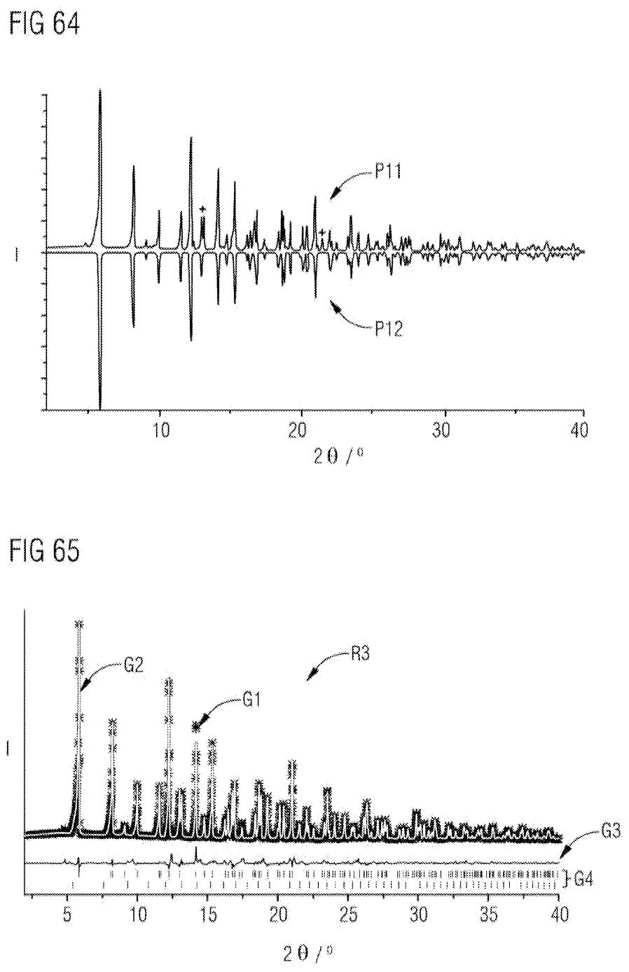

FIG. 64 shows a measured powder diffractogram P11 and a calculated powder diffractogram P12 of the exemplary embodiment of a phosphor 1 with the molecular formula Li₈Tb[LiSi₄N₄O₈]:Ce³⁺. The measured powder diffractogram P11 was recorded using Mo K-L₃ radiation. The calculated powder diffractogram P12 is based on the single crystal data of phosphor 1 with the molecular formula Li₈Tb[LiSi₄N₄O₈]:Ce³⁺. Based on the agreement of the measured powder diffractogram P11 with the calculated powder diffractogram P12, it can be confirmed that phosphor 1 with the molecular formula Li₈Tb[LiSi₄N₄O₈]:Ce³⁺ is the main phase of the powder sample. This shows that the phosphor 1 with the molecular formula Li₈Tb[LiSi₄N₄O₈]:Ce³⁺ can be specifically synthesized. Minor amounts of secondary phases such as Tb₂O₃ are present in the powder sample. Reflection positions that can be assigned to Tb₂O₃ are marked with a cross in FIG. 64.

FIG. 65 shows a Rietveld-refined powder diffractogram R3 of the phosphor 1 according to the exemplary embodiment with the molecular formula Li₈Tb[LiSi₄N₄O₈]:Ce³⁺. The powder diffractogram was recorded with Mo K-L₃ radiation. The relative intensity I is plotted in arbitrary units against the diffraction angle 2θ in degrees. The crosses of the powder diffractogram show the measured values G1. The white solid line with a black border shows a calculated powder diffractogram G2. The line G3 is the difference between the values of curve G1 and curve G2. In other words, it is a difference diagram G3. The black markings G4 correspond to the theoretical reflection positions for Li₈Tb[LiSi₄N₄O₈](top) and Tb₂O₃ (bottom). The theoretical reflection positions for Li₈Tb[LiSi₄N₄O₈] were calculated using the previously described crystal structure of host structure 2 of the phosphor with the molecular formula Li₈Tb[LiSi₄N₄O₈]:Ce³⁺. The Rietveld-refined powder diffractogram R3 shows that the structural model based on the measured single crystal is representative of the main phase of the powder sample. The crystallographic data of the Rietveld analysis of Li₈Tb[LiSi₄N₄O₈]:Ce³⁺ are summarized in Table 53.

TABLE 53
Results of the Rietveld refinement of a powder
sample of Li₈Tb[LiSi₄N₄O₈]:Ce³⁺.
Composition

| | |
|---|---|
| Li₈Tb[LiSi₄N₄O₈]/ wt % | 96.1(2) |
| Tb₂O₃/ wt % | 3.9(2) |

Crystallographic data

| | |
|---|---|
| Diffractometer | STOE STADI P |
| Radiation; wavelength /Å | Mo K-L₃; 0.7093 |
| a /Å | 9.9287(3) |
| c /Å | 5.0328(2) |
| Cell volume /Å³ | 496.13(3) |
| 2 θ Range / ° | 2-40.085 |
| 2 θ increment / ° | 0.015 |
| Rₑₓₚ /% | 1.32 |
| R_{wp} /% | 10.44 |
| Rₚ /% | 6.57 |
| R_{Bragg} /% | 3.817 |

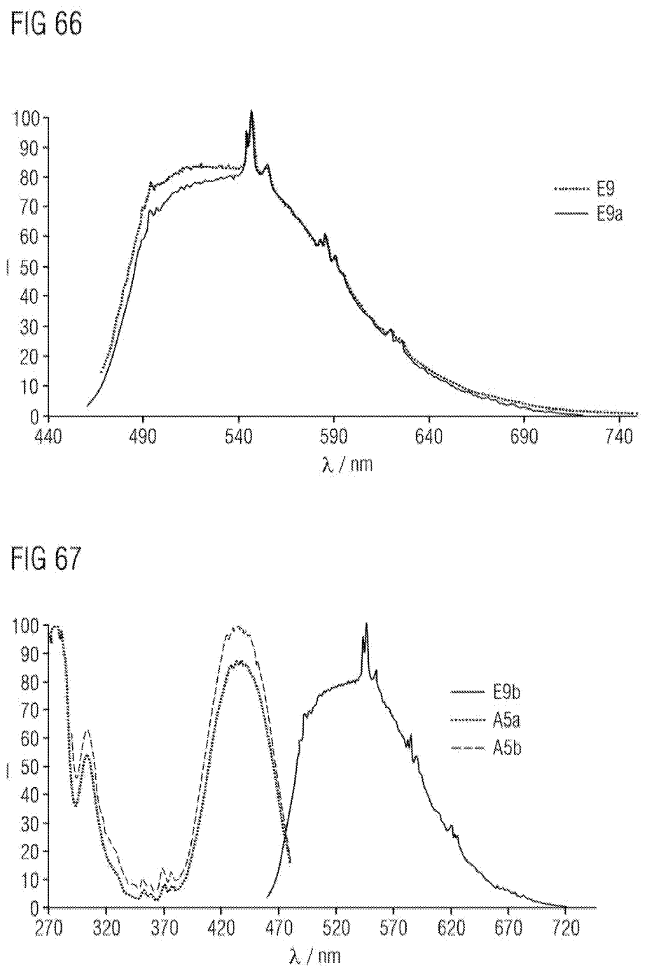

FIG. 66 shows emission spectra E9 and E9a of the exemplary embodiment of the phosphor 1 with the molecular formula Li₈Tb[LiSi₄N₄O₈]:Ce³⁺. The emission spectrum E9 results from a single crystal of Li₈Tb[LiSi₄N₄O₈]:Ce³⁺, whereas the emission spectrum E9a was recorded on a powder sample of Li₈Tb[LiSi₄N₄O₈]:Ce³⁺. The emission spectrum E9 was recorded at an excitation wavelength of 448 nanometers, the emission spectrum E9a at an excitation wavelength of 436 nanometers. The emission spectra E9 and E9a are each shown in a wavelength range from 440 nanometers to 740 nanometers.

The phosphor properties of Li₈Tb[LiSi₄N₄O₈]:Ce³⁺ can be explained by the presence of the activator element Ce³⁺. In the present case, the Ce³⁺ leads to broadband emission through 5d-4f transitions. In addition to the broadband emission, a line emission of Tb³⁺ is also recognizable. The line emission results from 4f-4f transitions in Tb³⁺. Selected optical data of Li₈Tb[LiSi₄N₄O₈]:Ce³⁺ are summarized in Table 54.

TABLE 54
Selected optical data of Li₈Tb[LiSi₄N₄O₈]:Ce³⁺

| | Li₈Tb[LiSi₄N₄O₈]:Ce³⁺ | Li₈Tb[LiSi₄N₄O₈]:Ce³⁺ |
|---|---|---|
| | (powder sample) | (single crystal) |
| LER / lm W_{opt.}⁻¹ | 450 | 437 |
| λ_{dom} / nm | 557.2 | 556.1 |
| λ_{centroid} / nm | 549.9 | 550.3 |
| λₘₐₓ / nm | 546.1 | 546.9 |
| CIE-x | 0.345(1) | 0.342(1) |
| CIE-y | 0.537(1) | 0.553(1) |

In FIG. 67 an emission spectrum E9b and two excitation spectra A5a and A5b of the phosphor 1 with the molecular formula Li₈Tb[LiSi₄N₄O₈]:Ce³⁺ are shown. The emission spectrum E9b was recorded with an excitation wavelength of 436 nanometers, which was provided with an Xe lamp. The excitation spectra A5a and A5b are based on the raw data maxima of the emission curve. The excitation spectrum A5a is based on the raw data maximum at about 506 nanometers, which is associated with Ce³⁺ emission, and the excitation spectrum A5b is based on the raw data maximum at about 546 nanometers, which is associated with Tb³⁺ emission. The emission maximum of Li₈Tb[LiSi₄N₄O]:Ce³⁺ calculated for the emission spectrum E6b is 546.1 nanometers. Furthermore, a full width at half maximum of 105.9 nanometers and a dominant wavelength of 557.2 nanometers were determined.

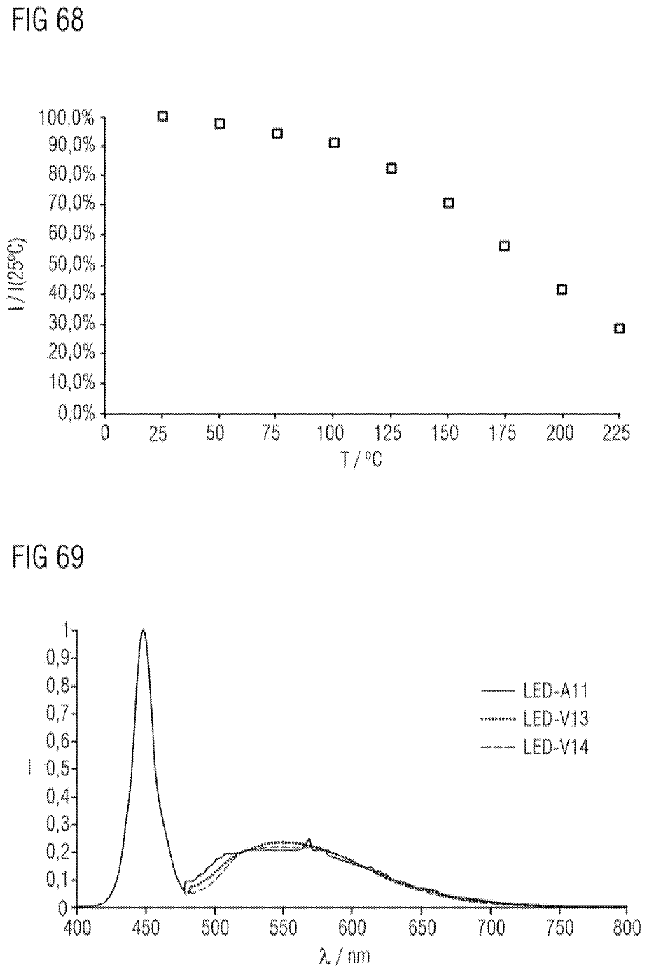

The temperature behavior of the exemplary embodiment of phosphor 1 with the molecular formula Li₈Tb[LiSi₄N₄O]:Ce³⁺ is shown in FIG. 68. The x-axis shows the temperature T in ° C. and the y-axis shows the quotient of the integral intensity of the emission at the current temperature and that at 25° C. The step size is 25° C. The maximum temperature is 225° C. The phosphor 1 with the molecular formula Li₈Tb[LiSi₄N₄O]:Ce³⁺ shows a decrease in emission intensity with increasing temperature. However, at a temperature of about 100° C., which corresponds to a typical operating temperature of optoelectronic components, the relative emission intensity is still greater than 90%.

FIG. 69 shows simulated emission spectra LED-A11, LED-V13, and LED-V14 of optoelectronic components 10 according to one exemplary embodiment (LED-A11) and two comparative examples (LED-V13 and LED-V14). The emission spectra are each shown in a wavelength range from 400 nanometers to 750 nanometers. The optoelectronic components 10 each comprise a blue-emitting semiconductor chip 11 and a conversion element 12 with a phosphor 1. In the simulations, the concentration of the phosphor 1 was adjusted so that a specific color location on the Planckian curve was achieved. The results and the configuration of the optoelectronic components 10 of the simulations are summarized in Table 55.

TABLE 55
Data on white light LED simulations

| | LED-A11 | LED-V13 | LED-V14 |
|---|---|---|---|
| blue LED (λ_{dom}/nm) | 447 | 447 | 447 |
| green phosphor | 556.1 | 556.2 | 557.0 |
| (λ_{dom}/nm) | | | |
| green phosphor | Li₈Tb[LiSi₄N₄O₈]:Ce³⁺ | LuAGaG | LuAG |
| CIE x | 0.240 | 0.240 | 0.240 |
| CIE y | 0.252 | 0.259 | 0.256 |
| CRI | 70 | 65 | 63 |
| CRI comparison in % | 100 | 93 (−7%) | 90 (−10%) |

The simulation results show that the exemplary embodiment of phosphor 1 with the molecular formula Li₈Tb[LiSi₄N₄O₈]:Ce³⁺ is very well suited for use in white emitting optoelectronic components 10. Advantageously, only one phosphor is required to achieve a CRI of at least 70. Such a radiation-emitting component 10 can be used for street lighting. The CRI advantage of the optoelectronic component 10 with the exemplary embodiment of the phosphor 1 with the molecular formula Li₈Tb[LiSi₄N₄O₈]:Ce³⁺ can be explained by the emission of the Tb³⁺, which is achieved by the energy transfer starting from Ce³⁺.

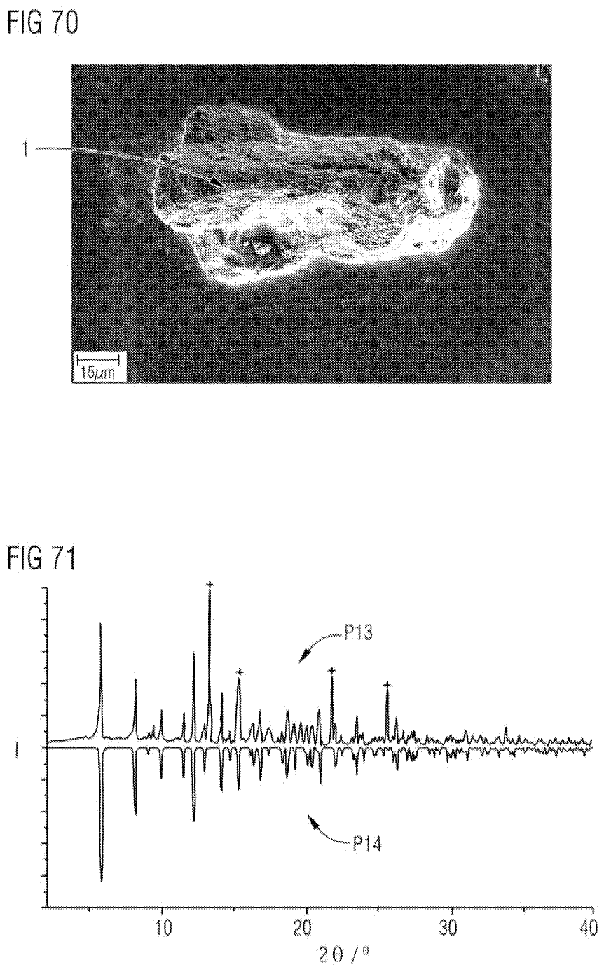

FIG. 70 shows a secondary electron image of a crystal of an exemplary embodiment of phosphor 1 with the molecular formula Li₈Er[LiSi₄N₄O₈]:Ce³⁺. The secondary electron image is the result of an SEM examination at an accelerating voltage of 3 kV. Li₈Er[LiSi₄N₄O₈]:Ce³⁺ is presently present as an almost cuboid crystal.

FIG. 71 shows a measured powder diffractogram P13 and a calculated powder diffractogram P14 of an exemplary embodiment of the phosphor 1 with the molecular formula Li₈Er[LiSi₄N₄O₈]:Ce³⁺. The measured powder diffractogram P13 was recorded using Mo K-L₃ radiation. The calculated powder diffractogram P14 is based on the crystal structure data of a single crystal of Li₈Er[LiSi₄N₄O₈]:Ce³⁺ described above. The measured powder sample contains Li₈Er[LiSi₄N₄O₈]:Ce³⁺, as can be seen in FIG. 71. The powder sample also contains the reactant Er₂O₃. The reflection positions that can be assigned to Er₂O₃ are marked with a cross in FIG. 71.

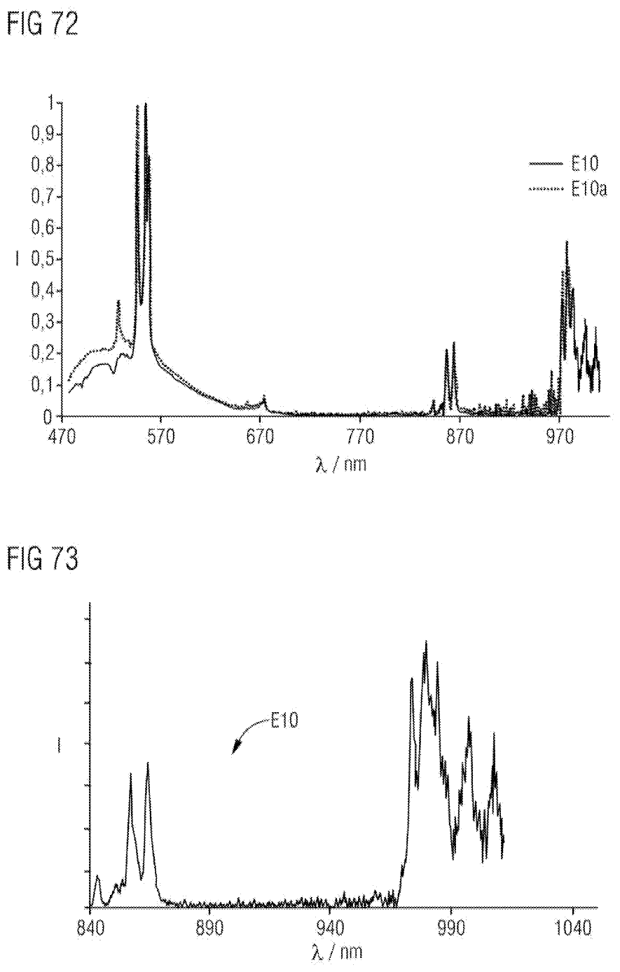

Emission spectra E10 and E10a of the exemplary embodiment of the phosphor 1 with the empirical formula Li₈Er[LiSi₄N₄O₈]:Ce³⁺ are shown in FIG. 72. The emission spectrum E10 results from the powder sample of phosphor 1 with the molecular formula Li₈Er[LiSi₄N₄O₈]:Ce³⁺, the emission spectrum E10a results from a single crystal of Li₈Er[LiSi₄N₄O]:Ce³⁺. The emission spectra E10 and E10a are shown in a wavelength range from 470 nanometers to 1000 nanometers. An excitation wavelength of 448 nanometers was used to record the emission spectra E10 and E10a.

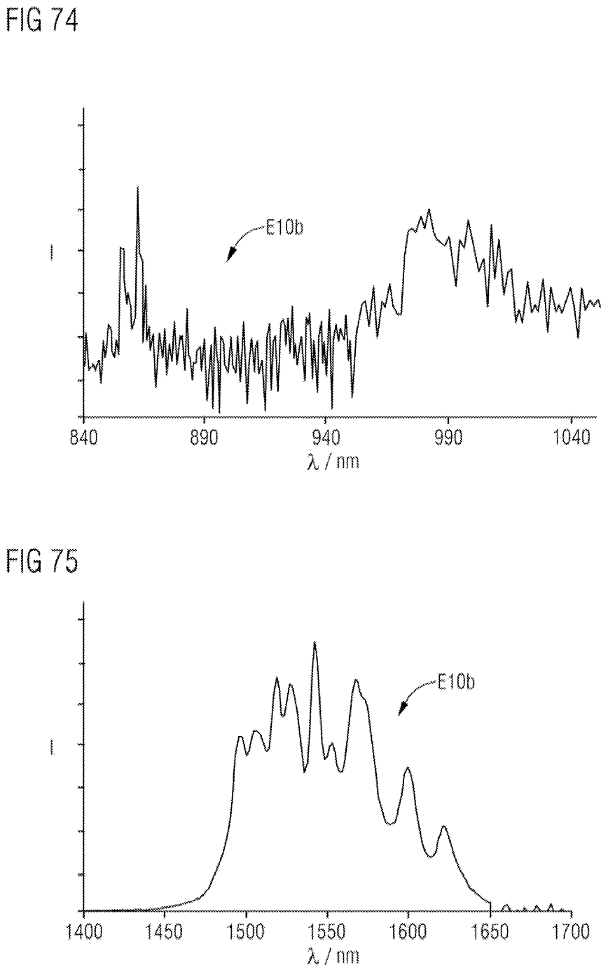

FIG. 73 shows a section of the emission spectrum E10 of phosphor 1 with the molecular formula Li₈Er[LiSi₄N₄O]:Ce³⁺ in the wavelength range from 840 nanometers to 1000 nanometers. FIG. 74 shows a section of an emission spectrum E10b of phosphor 1 with the molecular formula Li₈Er[LiSi₄N₄O]:Ce³⁺. The emission spectrum E10b was recorded with a different measurement setup than the emission spectra E10 and E10a and at an excitation wavelength of 450 nanometers. The emission spectrum E10b is shown in the wavelength range from 840 nanometers to 1040 nanometers. Another section of the emission spectrum E10b of phosphor 1 with the molecular formula Li₈Er[LiSi₄N₄O₈]:Ce³⁺ is shown in FIG. 75. FIG. 75 shows the wavelength range from 1400 nanometers to 1700 nanometers.

The phosphor 1 with the molecular formula Li₈Er[LiSi₄N₄O]:Ce³⁺ comprises a broadband emission of Ce³⁺ in the wavelength range from about 470 nanometers to about 600 nanometers as well as a line emission of Er³⁺. The broadband emission of Ce³⁺ is due to 5d-4f transitions. The line emission of Er³⁺ is due to 4f-4f transitions. Li₈Er[LiSi₄N₄O]:Ce³⁺ comprises the line emission at about 546.5 nanometers, about 554.5 nanometers, and in the wavelength ranges 840 nanometers to 870 nanometers, 970 nanometers to 1000 nanometers, and 1450 nanometers to 1650 nanometers. Li₈Er[LiSi₄N₄O]:Ce³⁺ therefore emits in the green to yellow wavelength range as well as in the near-infrared wavelength range of the electromagnetic spectrum.

However, for Li₈Er[LiSi₄N₄O]:Ce³⁺ the broadband emission of Ce³⁺ does not dominate, as for example for Li₈Gd[LiSi₄N₄O₈]:Ce³⁺ and Li₈Dy[LiSi₄N₄O₈]:Ce³⁺. Furthermore, compared to Li₈MC[LiSi₄N₄O₈]:Ce³⁺ with MC equal to Pr, Ho, Tb, or Tm, the intensity of the broadband emission of Ce³⁺ is significantly reduced. This indicates an energy transfer from Ce³⁺ to Er³⁺. Ce³⁺ therefore presently serves as a sensitizer.

Accordingly, the Ce³⁺ is excited first, whereupon an energy transfer to the Er³⁺ takes place. The observed line emission takes place from Er³⁺.

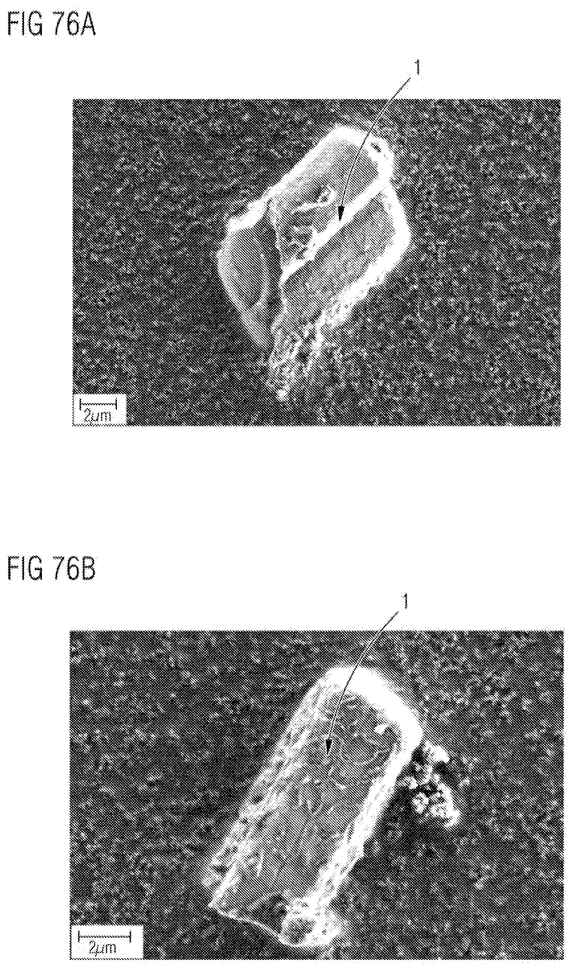

Secondary electron images of an exemplary embodiment of the phosphor 1 with the molecular formula Li₈Lu[LiSi₄N₄O]:Ce³⁺ are shown in FIGS. 76A and 76B. The secondary electron images are the result of an SEM examination at an acceleration voltage of 3 kV.

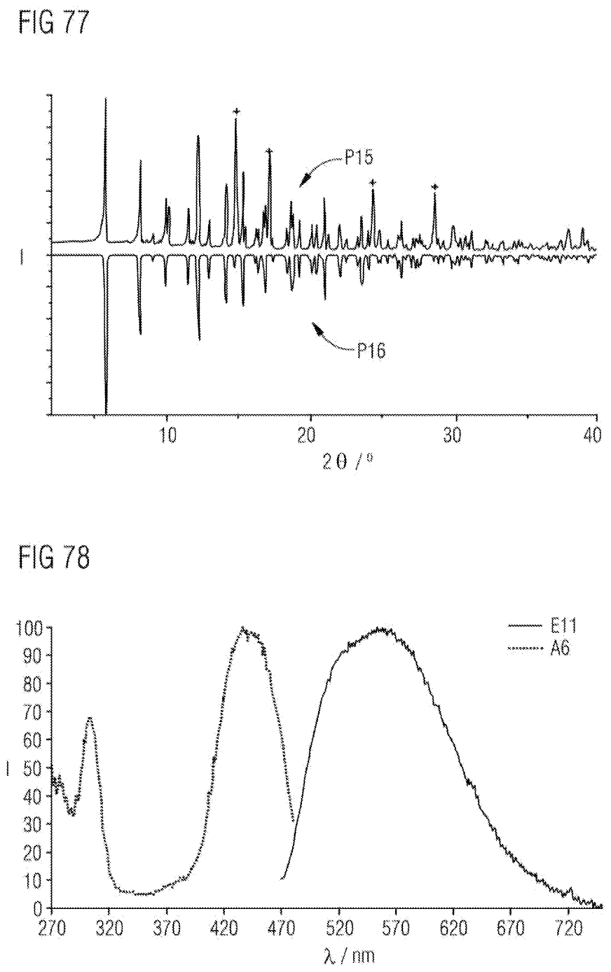

FIG. 77 shows a measured powder diffractogram P15 and a calculated powder diffractogram P16 of the exemplary embodiment of phosphor 1 with the molecular formula Li₈Lu[LiSi₄N₄O₈]:Ce³⁺. The measured powder diffractogram P15 was recorded using Mo K-L₃ radiation. The calculated powder diffractogram P16 is based on the crystal structure data of a single crystal of Li₈Lu[LiSi₄N₄O₈]:Ce³⁺ described above. The measured powder sample contains Li₈Lu[LiSi₄N₄O₈]:Ce³⁺ as the main phase, as can be seen in FIG. 77. The powder sample also contains LuN as a secondary phase. The reflection positions of LuN are marked with a cross in FIG. 77.

Due to the presence of the activator element Ce³⁺, Li₈Lu[LiSi₄N₄O₈]:Ce³⁺ has phosphor properties. In FIG. 78 an excitation spectrum A6 and an emission spectrum Eli of a powder sample of Li₈Lu[LiSi₄N₄O₈]:Ce³⁺ is shown. The excitation spectrum A6 and the emission spectrum Eli are shown in a wavelength range from 270 nanometers to 720 nanometers. The excitation spectrum A6 is based on the raw data maximum of the emission spectrum Eli, which is around 520 nanometers. The emission spectrum Eli was recorded at an excitation wavelength of 440 nanometers. Selected optical data of the powder sample and a single crystal of Li₈Lu[LiSi₄N₄O₈]:Ce³⁺ are summarized in Table 56.

TABLE 56
Selected optical data of Li₈Lu[LiSi₄N₄O₈]:Ce³⁺

| | Li₈Lu[LiSi₄N₄O₈]:Ce³⁺ | Li₈Lu[LiSi₄N₄O₈]:Ce³⁺ |
|---|---|---|
| | (powder sample) | (single crystal) |
| LER / lm W_{opt.}⁻¹ | 429 | 381 |
| λₘₐₓ / nm | 556.9 | 573.0 |
| λ_{dom} / nm | 566.9 | 571.7 |
| λ_{centroid} / nm | 569.1 | 589.1 |
| FWHM / nm | 135.1 | 144.9 |
| CIE-x | 0.406(1) | 0.438(1) |
| CIE-y | 0.530(1) | 0.512(1) |

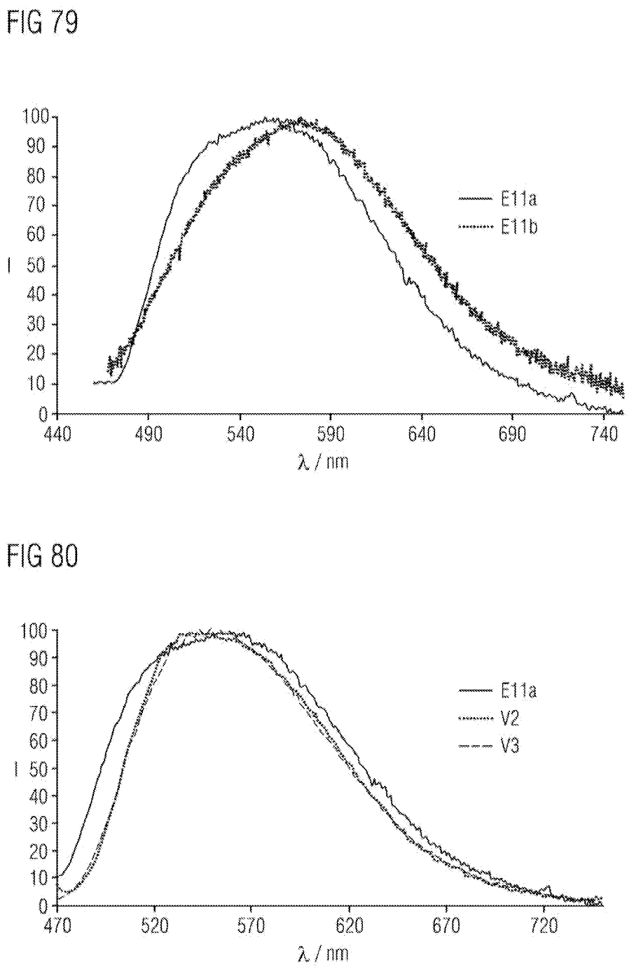

In FIG. 79 an emission spectrum Ella of a powder sample of phosphor 1 with the molecular formula Li₈Lu[LiSi₄N₄O₈]:Ce³⁺ and an emission spectrum E11b of a single crystal of Li₈Lu[LiSi₄N₄O₈]:Ce³⁺ is shown. The emission spectrum Ella was recorded at an excitation wavelength of 440 nanometers, the emission spectrum E11b at an excitation wavelength of 448 nanometers. The emission spectra Ella and E11b are shown in a wavelength range from 440 nanometers to 740 nanometers. The comparison of the emission spectra Ella and E11b shows that the emission of the single crystal is representative of the emission of the powder sample.

In addition to the emission spectrum Ella of the phosphor 1 with the molecular formula Li₈Lu[LiSi₄N₄O₈]:Ce³⁺, FIG. 80 also shows emission spectra V2 and V3 of comparative examples of a phosphor 1 in a wavelength range from 470 nanometers to 740 nanometers. The emission spectrum V2 results from a comparative example with the molecular formula Y₃Al₅O₁₂:Ce³⁺ (YAG). The emission spectrum V3 results from a comparative example with the molecular formula Y₃ (Al,Ga)₅O₁₂:Ce³⁺ (YAGaG). The emission spectra V2 and V3 were recorded at an excitation wavelength of 460 nanometers. Selected optical data of Li₈Lu[LiSi₄N₄O₈]:Ce³⁺, Y₃Al₅O₁₂:Ce³⁺, and Y₃ (Al,Ga)₅O₁₂:Ce³⁺ are summarized in Table 57.

TABLE 57
Selected optical data of Li₈Lu[LiSi₄N₄O₈]:Ce³⁺ and two comparative examples

| | Li₈Lu[LiSi₄N₄O₈]:Ce³⁺ | Y₃Al₅O₁₂:Ce³⁺ | Y₃(Al/Ga)₅O₁₂:Ce³⁺ |
|---|---|---|---|
| | (powder sample) | (powder) | (powder) |
| LER / lm W_{opt.}⁻¹ | 429 | 457 | 455 |
| λₘₐₓ / nm | 556.9 | 542.2 | 548.2 |
| λ_{dom} / nm | 566.9 | 567.2 | 567.1 |
| λ_{centroid} / nm | 569.1 | 573.1 | 573.0 |
| FWHM / nm | 135.1 | 117.1 | 116.0 |
| CIE-x | 0.406(1) | 0.415(1) | 0.415(1) |
| CIE-y | 0.530(1) | 0.550(1) | 0.551(1) |

The emission spectra Ella, V2, and V3 shown in FIG. 80 and the optical data from Table 57 show that the phosphor 1 with the molecular formula Li₈Lu[LiSi₄N₄O₈]:Ce³⁺ comprises optical properties comparable to those of the phosphors Y₃Al₅O₁₂:Ce³⁺ and Y₃(Al,Ga)₅O₁₂:Ce³⁺. For example, the emission spectra have a comparable profile and the emission spectra of the phosphors 1 comprise similar dominance wavelengths λ_{dom}. Thus, Li₈Lu[LiSi₄N₄O₈]:Ce³⁺ can serve as a substitute for Y₃Al₅O₁₂:Ce³⁺ and Y₃(Al,Ga)₅O₁₂:Ce³⁺ in conversion elements 12 of optoelectronic components 10.

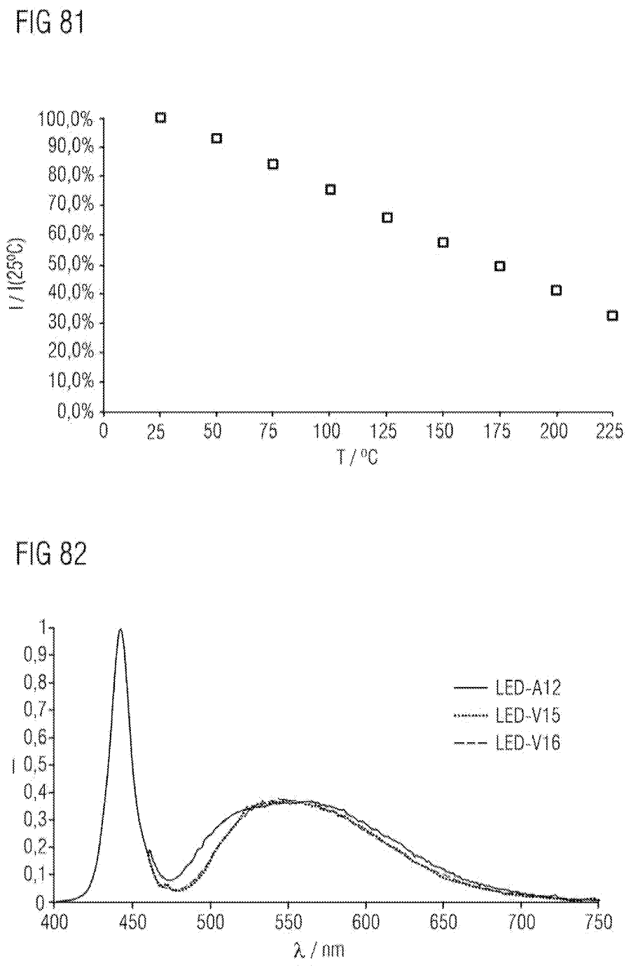

The temperature behavior of the exemplary embodiment of phosphor 1 with the molecular formula Li₈Lu[LiSi₄N₄O₈]:Ce³⁺ is shown in FIG. 81. The x-axis shows the temperature T in ° C. and the y-axis shows the quotient of the integral intensity of the emission at the current temperature and that at 25° C. The step size is 25° C. The maximum temperature is 225° C. The phosphor 1 with the molecular formula Li₈Lu[LiSi₄N₄O₈]:Ce³⁺ shows a decrease in emission intensity with increasing temperature. However, at a temperature of about 100° C., which corresponds to a typical operating temperature of optoelectronic components, the relative emission intensity is still greater than 75%.

FIG. 82 shows simulated emission spectra LED-A12, LED-V15, and LED-V16 of optoelectronic components 10 according to one exemplary embodiment (LED-A12) and two comparative examples (LED-V15 and LED-V16). The emission spectra are each shown in a wavelength range from 400 nanometers to 750 nanometers. The optoelectronic components 10 each comprise a blue-emitting semiconductor chip 11 and a conversion element 12 with a phosphor 1. In the simulations, the concentration of the phosphor 1 was adjusted so that a specific color location on the Planckian curve was achieved. The results and the configuration of the optoelectronic components 10 of the simulations are summarized in Table 58.

TABLE 58
Data on white light LED simulations.

| | LED-A12 | LED-V15 | LED-V16 |
|---|---|---|---|
| blue LED (λ_{dom}/nm) | 447 | 447 | 447 |
| green phosphor (λ_{dom}/nm) | 566.9 | 567.2 | 567.1 |
| green phosphor | Li₈Lu[LiSi₄N₄O₈]:Ce³⁺ | YAG | YAGaG |
| CIE x | 0.310(1) | 0.310(1) | 0.309(1) |
| CIE y | 0.330(1) | 0.330(1) | 0.330(1) |
| CCT / K | 6668 | 6679 | 6680 |
| CRI | 74 | 66 | 66 |
| CRI comparison in % | 100 | 89 (−11%) | 89 (−11%) |

The simulation results show that an optoelectronic component 10 with the phosphor 1 with the molecular formula Li₈Lu[LiSi₄N₄O₈]:Ce³⁺ comprises an improved CRI compared to optoelectronic components with the phosphors 1 YAG and YAGaG. The optoelectronic component 10 with the phosphor 1 of the molecular formula Li₈Lu[LiSi₄N₄O₈]:Ce³⁺ comprises a CRI of over 70 even without a further phosphor 14. Such an optoelectronic component 10 can therefore be used for street lighting.

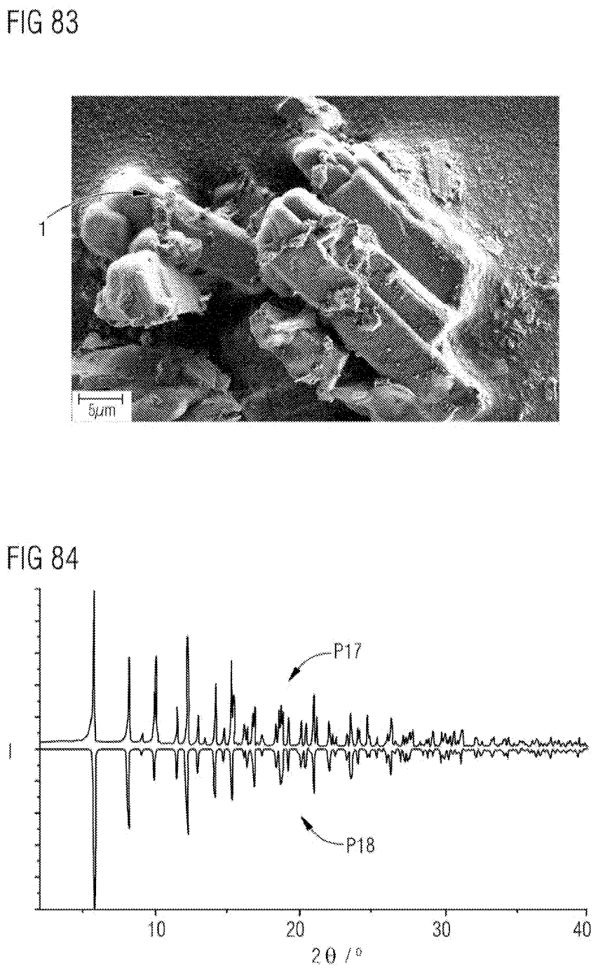

A secondary electron image of an exemplary embodiment of phosphor 1 with the molecular formula Li₈Yb[LiSi₄N₄O₈]:Ce³⁺ is shown in FIG. 83. The figure is the result of an SEM examination at an accelerating voltage of 3 kV. Li₈Yb[LiSi₄N₄O₈]:Ce³⁺ has presently the form of cuboid crystals.

FIG. 84 shows a measured powder diffractogram P17 and a calculated powder diffractogram P18 of phosphor 1 with the molecular formula Li₈Yb[LiSi₄N₄O₈]:Ce³⁺. The measured powder diffractogram P17 was measured on a powder sample of Li₈Yb[LiSi₄N₄O₈]:Ce³⁺ with Mo K-L₃ radiation. The calculated powder diffractogram P18 is based on the crystal structure data of Li₈Yb[LiSi₄N₄O₈]:Ce³⁺ described above. The measured powder diffractogram P17 and the calculated powder diffractogram P18 of Li₈Yb[LiSi₄N₄O₈]:Ce³⁺ are in good agreement, as can be seen in FIG. 84. The main phase of the powder sample is therefore Li₈Yb[LiSi₄N₄O₈]:Ce³⁺. This shows that Li₈Yb[LiSi₄N₄O₈]:Ce³⁺ can be synthesized in a targeted manner.

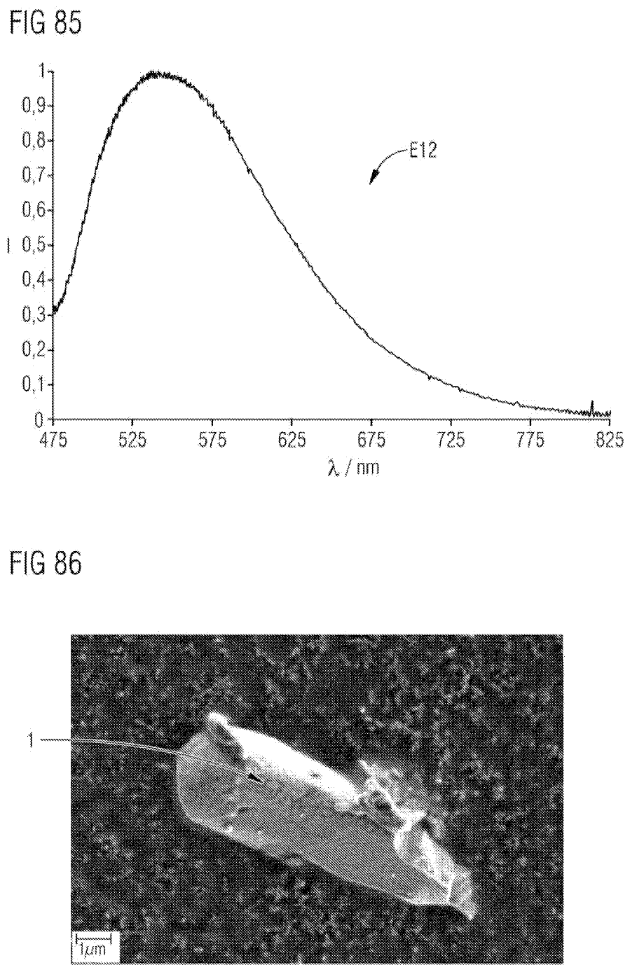

Due to the presence of the activator element Ce³⁺, the phosphor 1 with the molecular formula Li₈Yb[LiSi₄N₄O₈]:Ce³⁺ comprises phosphor properties. These can be seen, for example, in the emission spectrum E12 emitted by the phosphor 1 with the molecular formula Li₈Yb[LiSi₄N₄O₈]:Ce³⁺, which is shown in FIG. 85. The emission spectrum E12 was recorded on the powder sample of Li₈Yb[LiSi₄N₄O₈]:Ce³⁺ and at an excitation wavelength of 448 nanometers. Selected optical data of phosphor 1 with the molecular formula Li₈Yb[LiSi₄N₄O₈]:Ce³⁺ and of two comparative examples are shown in Table 59.

TABLE 59
Selected optical data of Li₈Yb[LiSi₄N₄O₈]:Ce³⁺
and two comparative examples

| | Li₈Yb[LiSi₄N₄O₈]:Ce³⁺ | LuAG:Ce³⁺ | YAGaG:Ce³⁺ |
|---|---|---|---|
| LER / lm | 402 | 454 | 461 |
| W_{opt.}⁻¹ | | | |
| λₘₐₓ / nm | 543 | 549 | 542 |
| λ_{dom} / nm | 565.9 | 565.6 | 565.4 |
| λ_{centroid} / nm | 577.9 | 570.5 | 568.4 |
| FWHM / nm | 137.8 | 111.7 | 114.4 |
| CIE-x | 0.401(1) | 0.404(1) | 0.402(1) |
| CIE-y | 0.539(1) | 0.555(1) | 0.556(1) |

The selected optical data show that Li₈Yb[LiSi₄N₄O₈]:Ce³⁺ comprises an emission comparable to that of the comparative examples of phosphor 1. In an optoelectronic component 10, a phosphor 1 according to one of the comparative embodiments can advantageously be replaced by the exemplary embodiment of the phosphor 1 with the molecular formula Li₈Yb[LiSi₄N₄O]:Ce³⁺.

A secondary electron image of a crystal of an exemplary embodiment of the phosphor 1 with the molecular formula Li₈Sm[LiSi₄N₄O₈]:Ce³⁺ is shown in FIG. 86. The secondary electron image is the result of an SEM examination at an accelerating voltage of 3 kV. The crystal was isolated from a powder sample of Li₈Sm[LiSi₄N₄O₈]:Ce³⁺.

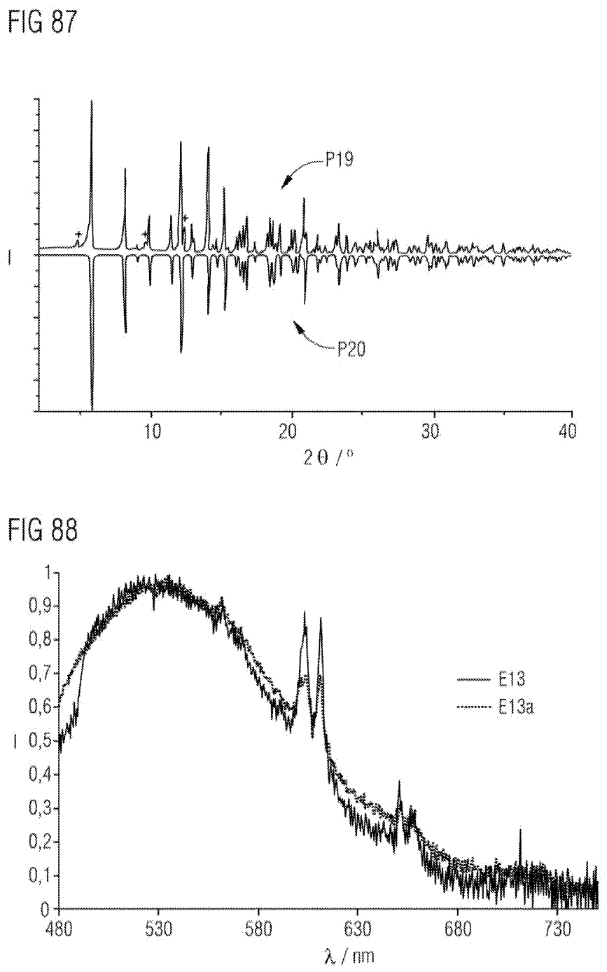

FIG. 87 shows a measured powder diffractogram P19 and a calculated powder diffractogram P20 of phosphor 1 with the molecular formula Li₈Sm[LiSi₄N₄O₈]:Ce³⁺. The measured powder diffractogram P19 was measured on a powder sample of Li₈Sm[LiSi₄N₄O₈]:Ce³⁺ with Mo K-L₃ radiation. The calculated powder diffractogram P20 is based on the crystal structure data of Li₈Sm[LiSi₄N₄O₈]:Ce³⁺, which were described above. As can be seen from the comparison of the measured powder diffractogram P19 with the calculated powder diffractogram P20, the main phase of the powder sample is the phosphor 1 with the molecular formula Li₈Sm[LiSi₄N₄O₈]:Ce³⁺. Thus, it is shown that the phosphor 1 with the molecular formula Li₈Sm[LiSi₄N₄O₈]:Ce³⁺ can be specifically synthesized. However, the powder sample of phosphor 1 with the molecular formula Li₃Sm[LiSi₄N₄O₈]:Ce³⁺ contains unidentified secondary phases. The reflection positions caused by the secondary phases are marked with a cross in FIG. 87.

Emission spectra E13 and E13a of phosphor 1 with the molecular formula Li₈Sm[LiSi₄N₄O₈]:Ce³⁺ are shown in FIG. 88. The emission spectrum E13 results from the powder sample of Li₈Sm[LiSi₄N₄O₈]:Ce³⁺. The emission spectrum E13a results from a single crystal of Li₈Sm[LiSi₄N₄O₈]:Ce³⁺. The emission spectra are shown in a wavelength range from 480 nanometers to 750 nanometers. An excitation wavelength of 448 nanometers was used to record the emission spectra E13 and E13a.

In addition to the broadband emission of Ce³⁺, which is caused by 5d-4f transitions in Ce³⁺, the line emission of Sm³⁺ can also be seen in the emission spectra E13 and E13a. The line emission is caused by 4f-4f transitions in the Sm³⁺. The activator element Ce³⁺ thus acts as a sensitizer and transfers part of its energy to the Sm³⁺. Selected optical data of phosphor 1 with the molecular formula Li₈Sm[LiSi₄N₄O₈]:Ce³⁺ are summarized in Table 60.

TABLE 60
Selected optical data of Li₈Sm[LiSi₄N₄O₈]:Ce³⁺.

| | Li₈Sm[LiSi₄N₄O₈]:Ce³⁺ | Li₈Sm[LiSi₄N₄O₈]:Ce³⁺ |
|---|---|---|
| | (powder sample) | (single crystal) |
| LER / lm W_{opt.}⁻¹ | 416 | 407 |
| λ_{dom} / nm | 560.5 | 561.3 |
| λ_{centroid} / nm | 558.7 | 562.8 |
| CIE-x | 0.364(1) | 0.369(1) |
| CIE-y | 0.535(1) | 0.536(1) |

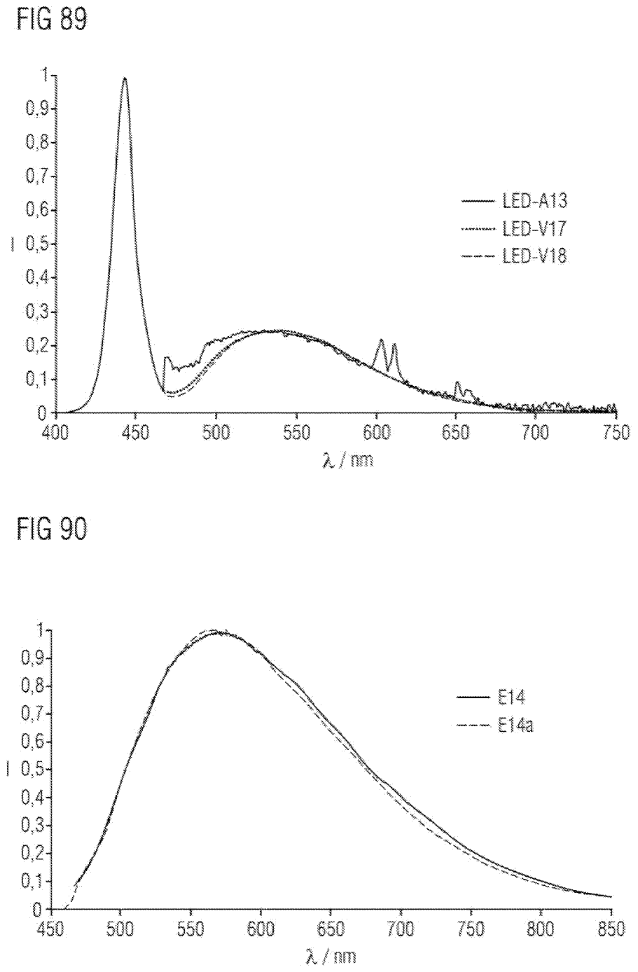

Due to its optical properties, the phosphor 1 with the molecular formula Li₈Sm[LiSi₄N₄O₈]:Ce³⁺ is advantageously used in a conversion element 12 of an optoelectronic component 10. A simulated emission spectrum LED-A13 of such an optoelectronic component 10 is shown in FIG. 89. FIG. 89 also shows simulated emission spectra LED-V17 and LED-V18 of comparative examples of optoelectronic components 10. In the comparative examples, Lu₃(Al,Ga)₅O₁₂:Ce³⁺ (LuAGaG) or Y₃ (Al,Ga)₅O₁₂:Ce³⁺ (YAGaG) was used as phosphor 1.

The composition of the optoelectronic component 10 with the phosphor 1 with the formula Li₈Sm[LiSi₄N₄O₈]:Ce³⁺ and the comparative examples of the optoelectronic components 10 was adapted so that a specific color location on the Planckian curve was achieved. The optoelectronic components 10 thus emit white light. Details of the optoelectronic components 10 are summarized in Table 61.

TABLE 61
Data on white light LED simulations

| | LED-A13 | LED-V17 | LED-V18 |
|---|---|---|---|
| blue LED (λ_{dom}/nm) | 447 | 447 | 447 |
| green phosphor (λ_{dom}/nm) | 560.5 | 560.5 | 561.0 |
| green phosphor | Li₈Sm[LiSi₄N₄O₈]:Ce³⁺ | LuAGaG | YAGaG |
| CIE x | 0.259(1) | 0.257(1) | 0.257(1) |
| CIE y | 0.269(1) | 0.272(1) | 0.270(1) |
| CCT / K | 15866 | 15757 | 15943 |
| CRI | 77 | 66 | 66 |
| CRI comparison in % | 100 | 86 (−14%) | 86 (−14%) |

The results show that the phosphor 1 with the molecular formula Li₈Sm[LiSi₄N₄O₈]:Ce³⁺ is very well suited to providing an optoelectronic component 10 with a CRI of greater than 70. Only Li₈Sm[LiSi₄N₄O₈]:Ce³⁺ is required as phosphor 1 in the conversion element 12 and no further phosphor 14. Such an optoelectronic component 10 can be used in street lighting. With the comparative examples, a CRI of 70 is not achieved. FIG. 90 shows emission spectra E14 and E14a of a phosphor 1 according to an exemplary embodiment. The phosphor 1 comprises the molecular formula Li₈Y[LiSi₄N₄O₈]:Eu²⁺. The emission spectra are shown in a wavelength range from 450 nanometers to 850 nanometers and were recorded at an excitation wavelength of approximately 448 nanometers. The emission spectrum E14 results from a powder sample of phosphor 1 with the molecular formula Li₈Y[LiSi₄N₄O₈]:Eu²⁺. The emission spectrum E14a of a single crystal of Li₈Y[LiSi₄N₄O₈]:Eu²⁺. Selected optical data of the single crystal of Li₈Y[LiSi₄N₄O₈]:Eu²⁺ are summarized in Table 62.

TABLE 62
Optical data of Li₈Y[LiSi₄N₄O₈]:Eu²⁺

| | Li₈Y[LiSi₄N₄O₈]:Eu²⁺ |
|---|---|
| LER / lm W_{opt.}⁻¹ | 330 |
| λₘₐₓ / nm | 568.3 |
| λ_{dom} / nm | 573.2 |
| λ_{centroid} / nm | 610.6 |
| FWHM / nm | 170.4 |
| CIE-x | 0.450(1) |
| CIE-y | 0.508(1) |

Compared to Li₈Y[LiSi₄N₄O₈]:Ce³⁺, Li₈Y[LiSi₄N₄O₈]:Eu²⁺ emits at longer wavelengths. The emission of Li₈Y[LiSi₄N₄O₈]:Eu²⁺ is therefore shifted towards lower energies compared to the corresponding Ce³⁺-doped compound.

The single crystal of Li₈Y[LiSi₄N₄O₈]:Eu²⁺ was isolated from the powder sample of Li₈Y[LiSi₄N₄O₈]:Eu²⁺. The single crystal comprises a yellow-orange luminescent appearance. A 180° phi scan for cell determination yielded the lattice parameters a=9.91(1), c=5.01(1) and V=492(1) Å³. The values of this fast cell determination agree very well with those of the corresponding, more accurate single crystal measurement of Li₈Y[LiSi₄N₄O₈]:Ce³⁺ (a=9.9152 (6), c=5.0240(5), V=493.92(6) Å³). Based on the agreement in terms of metrics (tetragonal) and lattice parameters, it is shown that Li₈Y[LiSi₄N₄O₈]:Eu²⁺ comprises the same structure as Li₈Y[LiSi₄N₄O₈]:Ce³⁺. Averaged over three measuring points on the single crystal of Li₈Y[LiSi₄N₄O₈]:Eu²⁺, an SEM-EDX analysis at an accelerating voltage of 25 kV shows a ratio (Y+Eu):Si of 1:4.3(1), which confirms the composition of the target phase, namely Li₈Y[LiSi₄N₄O₈]:Eu²⁺, within the measurement error.

The phosphor 1 according to the exemplary embodiment with the molecular formula Li₈Y[LiSi₄N₄O]:Eu²⁺ can be produced as follows:

The phosphor 1 with the molecular formula Li₈Y[LiSi₄N₄O]:Eu²⁺ is produced from the reactants Si₃N₄, SiO₂, Li₂O, and Y₂O₃ in the molar ratio 2:2:10.5:0.8, possibly a flux such as LiF or Li with up to 5 wt. % and with EuF₂ as a reactant for the activator element Eu²⁺. The activator element Eu²⁺ comprises a content in the range of between and including 0.01 mol % and 15 mol %, in particular in the range of between and including 0.1 mol % and 5 mol % with respect to Lu. The exact weights for producing Li₈Y[LiSi₄N₄O₈]:Eu²⁺ are summarized in Table 63.

Prior to synthesis, the reactants are intimately mixed in a glovebox under a protective gas atmosphere and reacted in a Ta-tube in a tube furnace. After being filled with the reactants, the Ta-tube is welded tightly with an arc under an Ar atmosphere. The material is synthesized at a first temperature of around 940° C., and this temperature is maintained for around 12 hours. It is then cooled to a second temperature of about 500° C. with a cooling rate of about 2 ° C./h. In a second cooling step, it is cooled with a cooling rate of about 18° C./h to a third temperature of about 150° C. and the furnace is then switched off.

TABLE 63
Weights for the synthesis of Li₈Y[LiSi₄N₄O₈]:Eu²⁺.

| Reactant | Quantity |
|---|---|
| Si₃N₄ | 29.84 mg (0.213 mmol) |
| SiO₂ | 12.78 mg (0.213 mmol) |
| Li₂O | 33.37 mg (1.117 mmol) |
| Y₂O₃ | 19.98 mg (0.085 mmol) |
| EuF₂ | 4.04 mg (0.021 mmol) |

The features and exemplary embodiments described in connection with the figures can be combined with one another in accordance with further exemplary embodiments, even if not all combinations are explicitly described. Furthermore, the exemplary embodiments described in connection with the figures may alternatively or additionally comprise further features as described in the general part.

The present disclosure is not limited to the exemplary embodiments by the description thereof. Rather, the present disclosure includes any new feature as well as any combination of features, which includes in particular any combination of features in the patent claims, even if this feature or combination itself is not explicitly stated in the patent claims or exemplary embodiments.

### LIST OF REFERENCE SIGNS

1 phosphor
2 host structure
3 first layer
31 SiO₂N₂ tetrahedron
32 LiO₄ tetrahedron
4 MC atom
41 square antiprism
5 four-rings
6 channel
7 O atom
8 N atom
9 second layer
91 LiO₄N bipyramid
92 LiO₃N₂ bipyramid
10 optoelectronic component
11 radiation-emitting semiconductor chip
111 active region
12 conversion element
121 matrix material
13 housing
14 further phosphor
15 intermediate layer
16 converting casting
17 non-converting casting
CCT color temperature
CRI color rendering index
FWHM full width at half maximum
I intensity
LER luminous efficacy of radiation
T temperature
D1, D2 data points
R1 Rietveld refinement of Li₈Gd[LiSi₄N₄O₈]:Ce³⁺
R2 Rietveld refinement of Li₈Dy[LiSi₄N₄O₈]:Ce³⁺
R3 Rietveld refinement of Li₈Tb[LiSi₄N₄O₈]:Ce³⁺
G1 measured diffractogram
G2 calculated diffractogram
G3 difference diagram
G4 calculated reflex positions
P1, P3, P5, P7, P9, P11, P13, P15, P17, P19 measured powder diffractogram
P2, P4, P6, P8, P10, P12, P14, P16, P18, P20 calculated powder diffractogram
A1, A2, A3, A4, A5a, A5b, A6 excitation spectrum
E1, E1a emission spectrum of Li₈Gd[LiSi₄N₄O₈]:Ce³⁺
E2, E2a, emission spectrum of Li₈Dy[LiSi₄N₄O₈]:Ce³⁺
E3, E3a, E3b, emission spectrum of Li₈Y[LiSi₄N₄O]:Ce³⁺
E4, E4a emission spectrum of Li₈Ho[LiSi₄N₄O₈]:Ce³⁺
E5, E5a, emission spectrum of Li₈Pr[LiSi₄N₄O₈]:Ce³⁺
E6, E6a, E6b, E6c, E6d emission spectrum of Li₈Nd[LiSi₄N₄O₈]:Ce³⁺
E7, E7a emission spectrum of Li₈Gd[LiSi₄N₄O₈]:Ce³⁺,Nd³⁺
E8, E8a, E8b emission spectrum of Li₈Tm[LiSi₄N₄O₈]:Ce³⁺
E9, E9a, E9b emission spectrum of Li₈Tb[LiSi₄N₄O₈]:Ce³⁺
E10, E10a, E10b emission spectrum of Li₈Er[LiSi₄N₄O₈]:Ce³⁺
E11, E11a, E11b emission spectrum of Li₈Lu[LiSi₄N₄O₈]:Ce³⁺
E12 emission spectrum of Li₈Yb[LiSi₄N₄O₈]:Ce³⁺
E13, E13a emission spectrum of Li₈Sm[LiSi₄N₄O]:Ce³⁺
E14, E14a emission spectrum of Li₈Y[LiSi₄N₄O₈]:Eu²⁺
V1 emission spectrum of Lu₃(Al,Ga)₅O₁₂:Ce³⁺
V2 emission spectrum of Y₃Al₅O₁₂:Ce³⁺
V3 emission spectrum of Y₃(Al,Ga)₅O₁₂:Ce³⁺
S1, S2, S3 method steps
LED-A1 to LED-A13 simulated emission spectrum
LED-V1 to LED-V18 simulated emission spectrum

1. A phosphor with the molecular formula Li₈₋₂ₓ₋ₐMB_{x+c}MFₐMC_{1-c}[MAMD_{4-z-b}ME_{z}MG_{b}N_{4-z+b+c}O_{8+z-b+c}]:E, wherein
0≤x≤4.0≤c≤1, 0≤z≤4.0≤a≤8.0≤b≤4,
0≤2x+a≤8, 0≤z+b≤4, −4≤−z+b−c≤4,
MB is an element or a combination of elements selected from the group of divalent elements,
MC is an element or a combination of elements selected from the group of trivalent elements,
MA is Li and/or Na,
MD is an element or a combination of elements selected from the group of tetravalent elements,
ME is an element or a combination of elements selected from the group of trivalent elements,
MF is an element or a combination of elements selected from the group of monovalent elements,
MG is an element or a combination of elements selected from the group of pentavalent elements, and
E is an activator element.

2. The phosphor according to claim 1, wherein
MB is an element or a combination of elements selected from the following group: Be, Mg, Ca, Sr, Ba, Zn,
MC is an element or a combination of elements selected from the following group: Sc, Y, La, Ce, Pr, Nd, Pm, Sm, Eu, Gd, Tb, Dy, Ho, Er, Tm, Yb, Lu,
MD is an element or a combination of elements selected from the following group: S1, Ge, Sn, Pb, Ti, Zr, Hf,
ME is an element or a combination of elements selected from the following group: B, Al, Ga, In, Sc, Cr,
MF is an element or a combination of elements selected from the following group: Na, K, Rb, Cs, Au, Cu, Pt, Ag,
MG is an element or a combination of elements selected from the following group: V, Nb, Ta, P, As, Sb, and/or
E is an element or a combination of elements selected from the following group: Eu, Ce, Pr, Nd, Sm, Tb, Dy, Ho, Er, Tm, Yb, Mn, Cr, Ni, Bi, Cu, Ag, Ti, U.

3. The phosphor according to claim 1, wherein the phosphor comprises the molecular formula Li₈MC[LiSi₄N₄O₈]:E.

4. The phosphor according to claim 1, wherein a crystal structure of a host structure of the phosphor comprises at least one structural element selected from the following group: MA(N,O)₄ tetrahedron, MD(N,O)₄ tetrahedron, ME(N,O)₄ tetrahedron, MG(N,O)₄ tetrahedron.

5. The phosphor according to claim 1, wherein MC and/or E are eightfold coordinated in the crystal structure of the host structure of the phosphor.

6. The phosphor according to claim 1,
wherein MC is an element or a combination of elements selected from the group consisting of Gd, Dy, Ho, Pr, Nd, Y, Tb, Er, Tm, Lu, Sm, and Yb.

7. The phosphor according to claim 1, further comprising
an element or a combination of elements selected from the group of monovalent elements,
an element or a combination of elements selected from the group of trivalent elements,
an element or a combination of elements selected from the group of tetravalent elements,
oxygen and/or nitrogen, and
an activator element E.

8. The phosphor according to claim 1, wherein the phosphor comprises an emission spectrum with an emission maximum in the green to yellow range of the electromagnetic spectrum.

9. The phosphor according to claim 1, wherein the phosphor comprises an emission spectrum with an emission maximum in the near infrared to infrared range of the electromagnetic spectrum.

10. The phosphor according to claim 1, wherein the phosphor comprises an emission spectrum with an emission maximum in the green to yellow region of the electromagnetic spectrum and with an emission maximum in the orange to red region and/or near-infrared to infrared region of the electromagnetic spectrum.

11. A method for producing a phosphor with the molecular formula
Li₈₋₂ₓ₋ₐMB_{x+c}MFₐMC_{1-c}[MAMD_{4-z-b}ME_{z}MG_{b}N_{4-z+b-c}O_{8+z-b+c}]:E, wherein
0≤x≤4.0≤c≤1, 0≤z≤4, 0≤a≤8, 0≤b≤4,
0≤2x+a≤8, 0≤z+b≤4, −4≤−z+b−c≤4,
MB is an element or a combination of elements selected from the group of divalent elements,
MC is an element or a combination of elements selected from the group of trivalent elements,
MA is Li and/or Na,
MD is an element or a combination of elements selected from the group of tetravalent elements,
ME is an element or a combination of elements selected from the group of trivalent elements,
MF is an element or a combination of elements selected from the group of monovalent elements,
MG is an element or a combination of elements selected from the group of pentavalent elements, and
E is an activator element, the method comprising:
providing reactants,
mixing the reactants to form a reactant mixture,
heating the reactant mixture.

12. The method for producing a phosphor according to claim 11, wherein
heating is carried out to a first temperature in the range between and including 700° C. and 1600° C.

13. (canceled)

14. An optoelectronic component comprising:
a radiation-emitting semiconductor chip and
a conversion element with a phosphor with the molecular formula Li₈₋₂ₓ₋ₐMB_{x+c}MFₐMC_{1-c}[MAMD_{4-z-b}ME_{z}MG_{b}N_{4-z+b-c}O_{8+z-b+c}]:E, wherein
0≤x≤4, 0≤c≤1, 0≤z≤4, 0≤a≤8, 0≤b≤4,
0≤2x+a≤8, 0≤z+b≤4, −4≤−z+b−c≤4,
MB is an element or a combination of elements selected from the group of divalent elements,
MC is an element or a combination of elements selected from the group of trivalent elements,
MA is Li and/or Na,
MD is an element or a combination of elements selected from the group of tetravalent elements,
ME is an element or a combination of elements selected from the group of trivalent elements,
MF is an element or a combination of elements selected from the group of monovalent elements,
MG is an element or a combination of elements selected from the group of pentavalent elements, and
E is an activator element.

15. The optoelectronic component according to claim 14, wherein the conversion element comprises at least one further phosphor.
